(19) United States
(12) Patent Application Publication
(10) Pub. No.: US 2026/0107464 A1
(43) Pub. Date: Apr. 16, 2026

(54) THREE-DIMENSIONAL MEMORY DEVICE WITH TOP-CONTACT THROUGH-STACK CONTACT VIA STRUCTURES AND METHODS FOR FORMING THE SAME

(71) Applicant: Sandisk Technologies, Inc., Milpitas, CA (US)

(72) Inventors: Shogo TOMITA, Yokkaichi (JP); Takashi INOMATA, Yokkaichi (JP)

(21) Appl. No.: 18/917,675

(22) Filed: Oct. 16, 2024

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H10B 41/27; H10B 80/00; H10W 90/00; H10W 80/312; H10W 80/327; H10W 90/792

(57) ABSTRACT

A device structure includes an alternating stack of insulating layers and electrically conductive layers, a retro-stepped dielectric material portion, a memory stack structure vertically extending through the alternating stack and including a vertical semiconductor channel vertical stack of memory elements, and a layer contact via structure. The layer contact via structure may be a tubular layer contact via structure contacting an annular top surface segment of a first electrically conductive layer of the electrically conductive layers. Alternatively, a first electrically conductive layer may include a horizontally-extending portion that is located outside a volume of the contact via opening and a vertically-extending tubular portion located in a peripheral region of the contact via opening, and the layer contact via structure may contact an inner sidewall of the vertically-extending tubular portion.

### FIELD

The present disclosure relates generally to the field of semiconductor devices, and particularly to a three-dimensional memory device including top-contact through-stack contact via structures and methods for forming the same.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an embodiment of the present disclosure, a device structure comprises: an alternating stack of insulating layers and electrically conductive layers; a retro-stepped dielectric material portion having a stepped bottom surface and overlying a region of the alternating stack in which the electrically conductive layers have variable lateral extents; a memory stack structure vertically extending through the alternating stack and comprising a vertical stack of memory elements; and a tubular layer contact via structure vertically extending through the retro-stepped dielectric material portion and contacting an annular top surface segment of a first electrically conductive layer of the electrically conductive layers.

According to another aspect of the present disclosure, a method of forming a device structure is provided, which comprises: forming an alternating stack of insulating layers and sacrificial material layers over a substrate; forming stepped surfaces by patterning the alternating stack in a staircase region; forming a retro-stepped dielectric material portion over the stepped surfaces; forming memory stack structures through the alternating stack, wherein each of the memory stack structures comprises a respective vertical semiconductor channel and a vertical stack of memory elements; forming a contact via opening through the retro-stepped dielectric material portion, a subset of the sacrificial material layers within the alternating stack, and a subset of the insulating layers within the alternating stack, wherein a topmost layer within the subset of the sacrificial material layers comprises a first sacrificial material layer; laterally recessing a sidewall of the retro-stepped dielectric material portion around the contact via opening by performing an etch back process; forming a sacrificial tubular structure in a peripheral region of the contact via opening on the laterally recessed sidewall of the retro-stepped dielectric material portion; forming a dielectric pillar in a center region of the contact via opening; replacing the sacrificial material layers with at least electrically conductive layers, wherein the first sacrificial material layer is replaced with a first electrically conductive layer; and replacing the sacrificial tubular structure with a tubular layer contact via structure, wherein the tubular layer contact via structure contacts an annular top surface segment of the first electrically conductive layer.

According to an embodiment of the present disclosure, a device structure comprises: an alternating stack of insulating layers and electrically conductive layers; a memory stack structure vertically extending through the alternating stack and comprising a vertical semiconductor channel and a vertical stack of memory elements; a contact via opening vertically extending through a subset of the electrically conductive layers and a subset of the insulating layers, wherein a topmost layer within the subset of the electrically conductive layers comprises a first electrically conductive layer, and the first electrically conductive layer comprises a horizontally-extending portion that is located outside a volume of the contact via opening and further comprises a vertically-extending tubular portion located in a peripheral region of the contact via opening and adjoined to the horizontally-extending portion; and a layer contact via structure located in a center region of the contact via opening and contacting an inner sidewall of the vertically-extending tubular portion.

According to another aspect of the present disclosure, a method of forming a device structure comprises: forming an alternating stack of insulating layers and sacrificial material layers over a substrate; forming stepped surfaces by patterning the alternating stack in a staircase region; forming a retro-stepped dielectric material portion over the stepped surfaces; forming memory stack structures through the alternating stack, wherein each of the memory stack structures comprises a respective vertical semiconductor channel and a vertical stack of memory elements l; forming a contact via opening through the retro-stepped dielectric material portion, a subset of the sacrificial material layers within the alternating stack, and a subset of the insulating layers within the alternating stack, wherein a topmost layer within the subset of the sacrificial material layers comprises a first sacrificial material layer; laterally recessing a sidewall of the retro-stepped dielectric material portion around the contact via opening by performing an etch back process; forming a sacrificial tubular structure in a peripheral region of the contact via opening on the laterally recessed sidewall of the retro-stepped dielectric material portion; replacing the sacrificial material layers and the sacrificial tubular structure with at least electrically conductive layers, wherein a combination of the first sacrificial material layer and the sacrificial tubular structure is replaced with material portions comprising a first electrically conductive layer; and forming a layer contact via structure on an inner-sidewall of a vertically-extending tubular portion of the first electrically conductive layer.

### BRIEF DESCRIPTION OF THE DRAWINGS

FIG. 1A is a plan view of a configuration of an exemplary semiconductor die including multiple three-dimensional memory array regions according to an embodiment of the present disclosure. FIG. 1B is a schematic see-through top-down view of region M1 of FIG. 1A. FIG. 1C is a schematic vertical cross-sectional view of a region of the exemplary semiconductor die along the vertical plane C-C′ of FIG. 1B. The vertical plane E-E′ is the cut plane of the schematic vertical cross-sectional view of FIG. 1E. FIG. 1D is a schematic vertical cross-sectional view of a region of the exemplary semiconductor die along the vertical plane D-D′ of FIG. 1B. FIG. 1E is a schematic vertical cross-sectional view of a region of the exemplary semiconductor die along the vertical plane E-E′ of FIG. 1B. The vertical plane C-C′ is the cut plane of the schematic vertical cross-sectional view of FIG. 1C.

FIG. 2A is a schematic vertical cross-sectional view of a first exemplary structure for forming a semiconductor die after formation of a vertically alternating sequence of first-tier continuous insulating layers and first-tier continuous sacrificial material layers, and a first-tier stepped cavity according to a first embodiment of the present disclosure. FIG. 2B is a schematic vertical cross-sectional view of the first exemplary structure along the vertical plane B-B′ of FIG. 2A. The vertical plane A-A′ is the cut plane of the vertical cross-sectional view of FIG. 2A.

FIG. 3A is a schematic vertical cross-sectional view of the first exemplary structure after formation of a first-tier retro-stepped dielectric material portion according to the first embodiment of the present disclosure. FIG. 3B is a schematic vertical cross-sectional view of the first exemplary structure along the vertical plane B-B′ of FIG. 3A. The vertical plane A-A′ is the cut plane of the vertical cross-sectional view of FIG. 3A.

FIG. 4A is a schematic vertical cross-sectional view of the first exemplary structure after formation of various first-tier openings and various first-tier sacrificial opening fill structures according to the first embodiment of the present disclosure. FIG. 4B is a schematic vertical cross-sectional view of the first exemplary structure along the vertical plane B-B′ of FIG. 4A. The vertical plane A-A′ is the cut plane of the vertical cross-sectional view of FIG. 4A.

FIG. 5A is a schematic vertical cross-sectional view of the first exemplary structure after formation of a vertically alternating sequence of second-tier continuous insulating layers and second-tier continuous sacrificial material layers, a second-tier stepped cavity, and a second-tier retro-stepped dielectric material portion according to the first embodiment of the present disclosure. FIG. 5B is a schematic vertical cross-sectional view of the first exemplary structure along the vertical plane B-B′ of FIG. 5A. The vertical plane A-A′ is the cut plane of the vertical cross-sectional view of FIG. 5A.

FIG. 6A is a schematic vertical cross-sectional view of the first exemplary structure after formation of various second-tier openings and various second-tier sacrificial opening fill structures according to the first embodiment of the present disclosure. FIG. 6B is a schematic vertical cross-sectional view of the first exemplary structure along the vertical plane B-B′ of FIG. 6A. The vertical plane A-A′ is the cut plane of the vertical cross-sectional view of FIG. 6A.

FIG. 7A is a schematic vertical cross-sectional view of the first exemplary structure after formation of a vertically alternating sequence of third-tier continuous insulating layers and third-tier continuous sacrificial material layers, a third-tier stepped cavity, and a third-tier retro-stepped dielectric material portion according to the first embodiment of the present disclosure. FIG. 7B is a schematic vertical cross-sectional view of the first exemplary structure along the vertical plane B-B′ of FIG. 7A. The vertical plane A-A′ is the cut plane of the vertical cross-sectional view of FIG. 7A.

FIG. 8A is a schematic vertical cross-sectional view of the first exemplary structure after formation of various third-tier openings and various third-tier sacrificial opening fill structures according to the first embodiment of the present disclosure. FIG. 8B is a schematic vertical cross-sectional view of the first exemplary structure along the vertical plane B-B′ of FIG. 8A. The vertical plane A-A′ is the cut plane of the vertical cross-sectional view of FIG. 8A.

FIG. 9A is a schematic vertical cross-sectional view of the first exemplary structure after replacement of sacrificial support opening fill structures with support pillar structures according to the first embodiment of the present disclosure. FIG. 9B is a schematic vertical cross-sectional view of the first exemplary structure along the vertical plane B-B′ of FIG. 9A. The vertical plane A-A′ is the cut plane of the vertical cross-sectional view of FIG. 9A.

FIG. 10 is a schematic vertical cross-sectional view of the first exemplary structure after formation of memory opening according to the first embodiment of the present disclosure.

FIGS. 11A-11F illustrate sequential vertical cross-sectional views of a memory opening during formation of a memory opening fill structure according to the first embodiment of the present disclosure.

FIG. 12A is a schematic vertical cross-sectional view of the first exemplary structure after formation of memory opening fill structures according to the first embodiment of the present disclosure. FIG. 12B is a schematic vertical cross-sectional view of the first exemplary structure along the vertical plane B-B′ of FIG. 12A. The vertical plane A-A′ is the cut plane of the vertical cross-sectional view of FIG. 12A.

FIG. 13A is a schematic vertical cross-sectional view of the first exemplary structure after formation of a contact-level dielectric layer and connection via cavities according to the first embodiment of the present disclosure. FIG. 13B is a schematic vertical cross-sectional view of the first exemplary structure along the vertical plane B-B′ of FIG. 13A. The vertical plane A-A′ is the cut plane of the vertical cross-sectional view of FIG. 13A. FIG. 13C is a magnified view of a region of the first exemplary structure around a bottom corner of a sacrificial first-tier contact opening fill structure in FIG. 13B.

FIG. 14A is a schematic vertical cross-sectional view of the first exemplary structure after formation of contact via openings according to the first embodiment of the present disclosure. FIG. 14B is a schematic vertical cross-sectional view of the first exemplary structure along the vertical plane B-B′ of FIG. 14A. The vertical plane A-A′ is the cut plane of the vertical cross-sectional view of FIG. 14A. FIG. 14C is a magnified view of a region of the first exemplary structure around a portion of the contact via opening in FIG. 14B.

FIGS. 15A-15G are sequential vertical cross-sectional views of a region around a contact via opening in the first exemplary structure during a sequence of processing steps for formation of various structural elements therein according to the first embodiment of the present disclosure.

FIG. 16A is a schematic vertical cross-sectional view of the first exemplary structure after removal of sacrificial fill material portions from bottom regions of the contact via openings according to the first embodiment of the present disclosure. FIG. 16B is a schematic vertical cross-sectional view of the first exemplary structure along the vertical plane B-B′ of FIG. 16A. The vertical plane A-A′ is the cut plane of the vertical cross-sectional view of FIG. 16A. FIG. 16C is a magnified view of a region of the first exemplary structure around a contact via opening in FIG. 16B.

FIG. 17A is a schematic vertical cross-sectional view of the first exemplary structure after formation of dielectric pillars according to the first embodiment of the present disclosure. FIG. 17B is a schematic vertical cross-sectional view of the first exemplary structure along the vertical plane B-B′ of FIG. 17A. The vertical plane A-A′ is the cut plane of the vertical cross-sectional view of FIG. 17A. FIG. 17C is a magnified view of a region of the first exemplary structure around an in-process contact-via-region assembly in FIG. 17B.

FIG. 18A is a schematic vertical cross-sectional view of the first exemplary structure after formation of lateral isolation trenches according to the first embodiment of the present disclosure. FIG. 18B is a schematic vertical cross-sectional view of the first exemplary structure along the vertical plane B-B′ of FIG. 18A. The vertical plane A-A′ is the cut plane of the vertical cross-sectional view of FIG. 18A. FIG. 18C is a magnified view of a region of the first exemplary structure around an in-process contact-via-region assembly in FIG. 18B.

FIG. 19A is a schematic vertical cross-sectional view of the first exemplary structure after formation of semiconductor oxide spacer liners and lateral recesses according to the first embodiment of the present disclosure. FIG. 19B is a schematic vertical cross-sectional view of the first exemplary structure along the vertical plane B-B′ of FIG. 19A. The vertical plane A-A′ is the cut plane of the vertical cross-sectional view of FIG. 19A. FIG. 19C is a magnified view of a region of the first exemplary structure around an in-process contact-via-region assembly in FIG. 19B.

FIG. 20A is a schematic vertical cross-sectional view of the first exemplary structure after formation of electrically conductive layers according to the first embodiment of the present disclosure. FIG. 20B is a schematic vertical cross-sectional view of the first exemplary structure along the vertical plane B-B′ of FIG. 20A. The vertical plane A-A′ is the cut plane of the vertical cross-sectional view of FIG. 20A. FIG. 20C is a magnified view of a region of the first exemplary structure around an in-process contact-via-region assembly in FIG. 20B.

FIG. 21A is a schematic vertical cross-sectional view of the first exemplary structure after formation of lateral isolation trench fill structures according to the first embodiment of the present disclosure. FIG. 21B is a schematic vertical cross-sectional view of the first exemplary structure along the vertical plane B-B′ of FIG. 21A. The vertical plane A-A′ is the cut plane of the vertical cross-sectional view of FIG. 21A. FIG. 21C is a magnified view of a region of the first exemplary structure around an in-process contact-via-region assembly in FIG. 21B.

FIG. 22A is a schematic vertical cross-sectional view of the first exemplary structure after removal of the sacrificial tubular structures according to the first embodiment of the present disclosure. FIG. 22B is a schematic vertical cross-sectional view of the first exemplary structure along the vertical plane B-B′ of FIG. 22A. The vertical plane A-A′ is the cut plane of the vertical cross-sectional view of FIG. 22A. FIG. 22C is a magnified view of a region of the first exemplary structure around a contact via opening in FIG. 22B.

FIG. 23A is a schematic vertical cross-sectional view of the first exemplary structure after formation of layer contact via structures according to the first embodiment of the present disclosure. FIG. 23B is a schematic vertical cross-sectional view of the first exemplary structure along the vertical plane B-B′ of FIG. 23A. The vertical plane A-A′ is the cut plane of the vertical cross-sectional view of FIG. 23A. FIG. 23C is a magnified view of a region of the first exemplary structure around a layer contact via structure in FIG. 23B.

FIG. 24 is a schematic vertical cross-sectional view of the first exemplary structure after formation of a memory die according to the first embodiment of the present disclosure.

FIG. 25 is a schematic vertical cross-sectional view of the first exemplary structure after bonding of the memory die to a logic die according to the first embodiment of the present disclosure.

FIG. 26 is a schematic vertical cross-sectional view of the first exemplary structure after removal of the carrier substrate and formation of source-side structures according to the first embodiment of the present disclosure.

FIG. 27A is a schematic vertical cross-sectional view of a second exemplary structure after formation of various third-tier openings and various third-tier sacrificial opening fill structures according to the second embodiment of the present disclosure. FIG. 27B is a schematic vertical cross-sectional view of the second exemplary structure along the vertical plane B-B′ of FIG. 27A. The vertical plane A-A′ is the cut plane of the vertical cross-sectional view of FIG. 17A.

FIG. 28A is a schematic vertical cross-sectional view of the second exemplary structure after formation of support pillar structures, memory opening fill structures, a contact-level dielectric layer, and contact via openings according to the second embodiment of the present disclosure. FIG. 28B is a schematic vertical cross-sectional view of the second exemplary structure along the vertical plane B-B′ of FIG. 28A. The vertical plane A-A′ is the cut plane of the vertical cross-sectional view of FIG. 28A. FIG. 28C is a magnified view of a region of the second exemplary structure around a portion of the contact via opening in FIG. 28B.

FIGS. 29A-29I are sequential vertical cross-sectional views of a region around a contact via opening in the second exemplary structure during a sequence of processing steps for formation of various structural elements therein according to the second embodiment of the present disclosure.

FIG. 30A is a schematic vertical cross-sectional view of the second exemplary structure after formation of in-process contact-via-region assemblies according to the second embodiment of the present disclosure. FIG. 30B is a schematic vertical cross-sectional view of the second exemplary structure along the vertical plane B-B′ of FIG. 30A. The vertical plane A-A′ is the cut plane of the vertical cross-sectional view of FIG. 30A. FIG. 30C is a magnified view of a region of the second exemplary structure around a contact via opening in FIG. 30B.

FIG. 31A is a schematic vertical cross-sectional view of the second exemplary structure after formation of lateral isolation trenches according to the second embodiment of the present disclosure. FIG. 31B is a schematic vertical cross-sectional view of the second exemplary structure along the vertical plane B-B′ of FIG. 31A. The vertical plane A-A′ is the cut plane of the vertical cross-sectional view of FIG. 31A. FIG. 31C is a magnified view of a region of the second exemplary structure around a contact via opening in FIG. 31B.

FIG. 32A is a schematic vertical cross-sectional view of the second exemplary structure after formation of semiconductor oxide spacer liners and lateral recesses according to the second embodiment of the present disclosure. FIG. 32B is a schematic vertical cross-sectional view of the second exemplary structure along the vertical plane B-B′ of FIG. 32A. The vertical plane A-A′ is the cut plane of the vertical cross-sectional view of FIG. 32A. FIG. 32C is a magnified view of a region of the second exemplary structure around a contact via opening in FIG. 32B.

FIG. 33 is a schematic vertical cross-sectional view of a region of the second exemplary structure after conversion of surface portions of a conformal silicon layer into silicon oxide liners according to the second embodiment of the present disclosure.

FIG. 34A is a schematic vertical cross-sectional view of the second exemplary structure after formation of electrically conductive layers according to the second embodiment of the present disclosure. FIG. 34B is a schematic vertical cross-sectional view of the second exemplary structure along the vertical plane B-B′ of FIG. 34A. The vertical plane A-A′ is the cut plane of the vertical cross-sectional view of FIG. 34A. FIG. 34C is a magnified view of a region of the second exemplary structure around a contact via opening in FIG. 34B.

FIG. 35A is a schematic vertical cross-sectional view of the second exemplary structure after formation of lateral isolation trench fill structures according to the second embodiment of the present disclosure. FIG. 35B is a schematic vertical cross-sectional view of the second exemplary structure along the vertical plane B-B′ of FIG. 35A. The vertical plane A-A′ is the cut plane of the vertical cross-sectional view of FIG. 35A. FIG. 35C is a magnified view of a region of the second exemplary structure around a contact via opening in FIG. 35B.

FIG. 36A is a schematic vertical cross-sectional view of the second exemplary structure after removal of the sacrificial fill structures according to the second embodiment of the present disclosure. FIG. 36B is a schematic vertical cross-sectional view of the second exemplary structure along the vertical plane B-B′ of FIG. 36A. The vertical plane A-A′ is the cut plane of the vertical cross-sectional view of FIG. 36A. FIG. 36C is a magnified view of a region of the second exemplary structure around a contact via opening in FIG. 36B.

FIG. 37 is a schematic vertical cross-sectional view of a region of the second exemplary structure after removal of physically exposed portions of outer blocking dielectric layers according to the second embodiment of the present disclosure.

FIG. 38A is a schematic vertical cross-sectional view of the second exemplary structure after formation of layer contact via structures according to the second embodiment of the present disclosure. FIG. 38B is a schematic vertical cross-sectional view of the second exemplary structure along the vertical plane B-B′ of FIG. 38A. The vertical plane A-A′ is the cut plane of the vertical cross-sectional view of FIG. 38A. FIG. 38C is a magnified view of a region of the second exemplary structure around a layer contact via structure in FIG. 38B. FIG. 38D is a magnified view of a region in FIG. 38C.

FIG. 39 is a schematic vertical cross-sectional view of the second exemplary structure after formation of a memory die according to the second embodiment of the present disclosure.

FIG. 40 is a schematic vertical cross-sectional view of the second exemplary structure after bonding of the memory die to a logic die according to the second embodiment of the present disclosure.

FIG. 41 is a schematic vertical cross-sectional view of the second exemplary structure after removal of the carrier substrate and formation of source-side structures according to the second embodiment of the present disclosure.

### DETAILED DESCRIPTION

As discussed above, embodiments of the present disclosure are directed to a three-dimensional memory device including top-contact through-stack contact via structures and methods for forming the same, the various aspects of which are now described in detail. The embodiment top-contact through-stack contact via structures are more compact than prior art contact structures, are simpler to manufacture, and reduce a likelihood of causing short circuits and/or leaking current between vertically separated word lines.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a surface of a structural element has a “convex profile” in a cross-sectional view if the surface is contoured such that a center of curvature of a curved segment of the surface is located on a side of the structural element relative to the surface of the structural element in the cross-sectional view. As used herein, a surface of a structural element has a “concave profile” in a cross-sectional view if the surface is contoured such that a center of curvature of a curved segment of the surface is located on an opposite side of the structural element relative to the surface of the structural element in the cross-sectional view. As used herein, a surface of a structural element is a “convex surface” if the surface has a convex profile in a cross-sectional view. A surface is a “vertically-convex surface” if the surface has a convex profile in a vertical cross-sectional view. A surface is a “vertically-concave surface” if the surface has a convex profile in a vertical cross-sectional view. A surface is a “vertically-straight surface” if the surface has no curvature in a vertical cross-sectional view. A surface is a “horizontally-convex surface” if the surface has a convex profile in a horizontal cross-sectional view. A surface is a “horizontally-concave surface” if the surface has a concave profile in a vertical cross-sectional view. A surface is a “horizontally-straight surface” if the surface has no curvature in a horizontal cross-sectional view. Generally, convexity or concavity in a vertical cross-sectional view is independent of convexity or concavity in a horizontal cross-sectional view.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

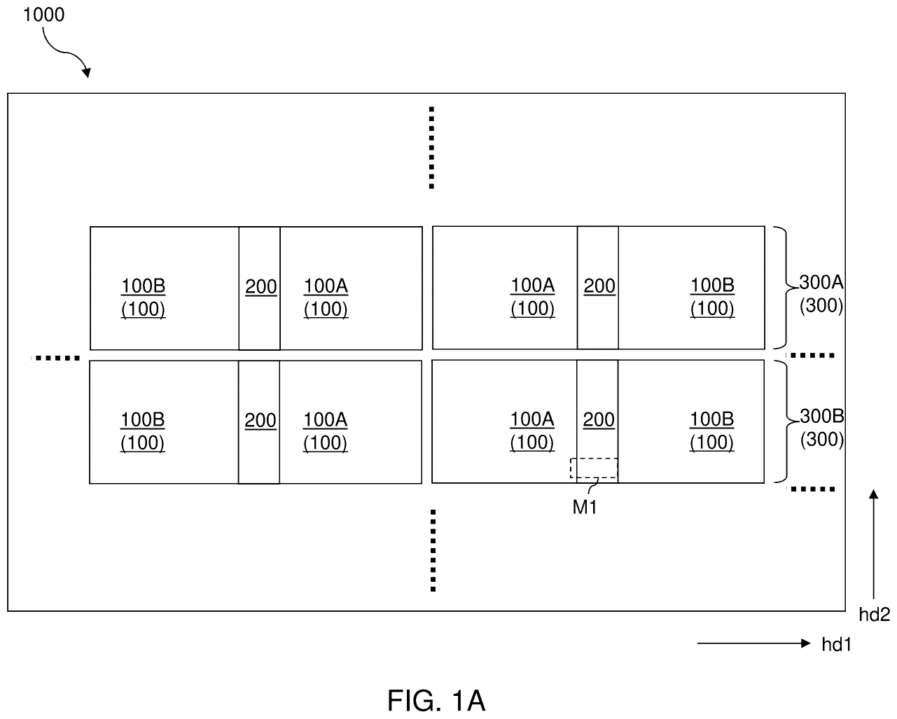

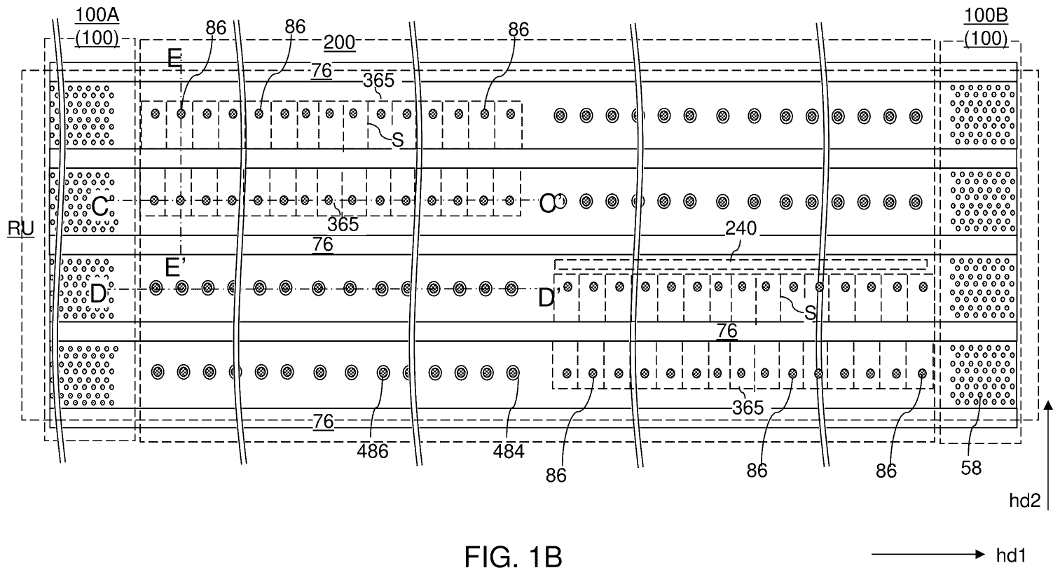

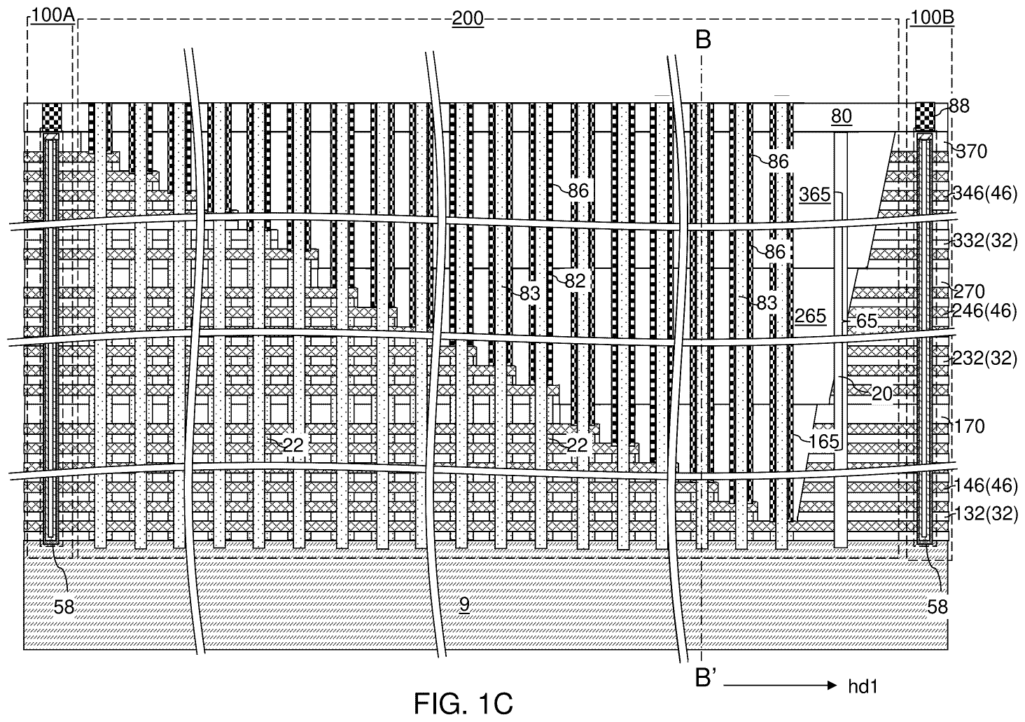

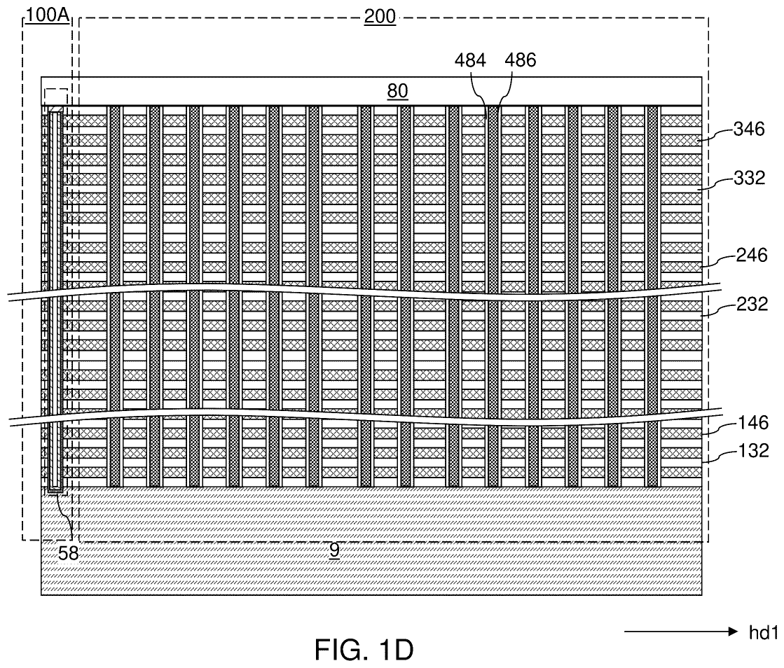

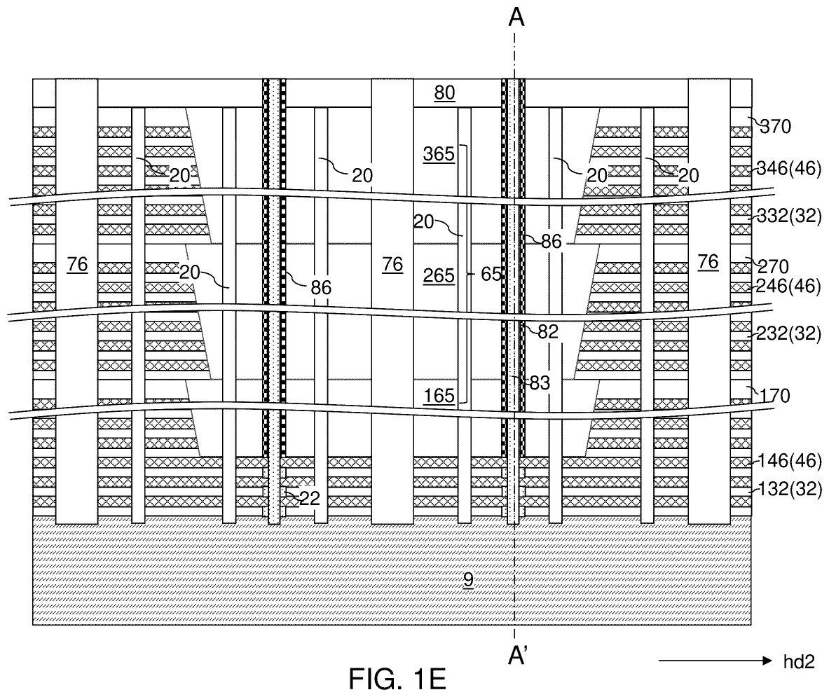

Referring to FIGS. 1A-1E, an exemplary semiconductor die 1000 according to an embodiment of the present disclosure is illustrated. The exemplary semiconductor die 1000 comprises a substrate 9, which may be a semiconductor substrate and/or a carrier substrate. For example, the substrate 9 may comprise a commercially available silicon wafer. If the substrate 9 comprises a carrier substrate, the substrate 9 may comprise any material that may be removed selectively to the materials of overlying structures to be subsequently formed. The exemplary semiconductor die 1000 is illustrated after a set of processing steps that forms various contact via structures (86, 88), which include tubular layer contact via structures 86 and drain contact via structures 88. The exemplary semiconductor die 1000 illustrates an exemplary layout and configuration of the various device structures of the present disclosure that are subsequently described. However, the layout and the configuration of the exemplary semiconductor die 1000 in FIGS. 1A-1E are only illustrative, and do not limit the general layout and/or configurations of embodiments of the present disclosure.

The exemplary semiconductor die 1000 includes multiple three-dimensional memory array regions and multiple inter-array regions. The exemplary semiconductor die 1000 can include multiple planes 300 (e.g., 300A, 300B), each of which includes two memory array regions 100, such as a first memory array region 100A and a second memory array region 100B that are laterally spaced apart by a respective inter-array region 200. Generally, a semiconductor die 1000 may include a single plane 300 or multiple planes. The total number of planes in the semiconductor die 1000 may be selected based on performance requirements on the semiconductor die 1000. A pair of memory array regions 100 in a plane 300 may be laterally spaced apart along a first horizontal direction hd1 (which may be the word line direction). A second horizontal direction hd2 (which may be the bit line direction) can be perpendicular to the first horizontal direction hd1.

The size of the first memory array region 100A may be the same as, or may differ from, the size of the second memory array region 100B within a given plane. In one embodiment, each of the first memory array region 100A and the second memory array region 100B may have a respective rectangular area having a same width along the second horizontal direction hd2. In one embodiment, the inter-array region 200 within each plane 300 can be located off-center of the respective plane 300 along the first horizontal direction hd1 (i.e., the inter-array region 200 is located closer to one end than to another end of the respective plane 300). For example, the inter-array region 200 in the left plane 300A may be shifted toward the left edge of the die 1000, while the inter-array region 200 in the right plane 300B may be shifted toward the right edge of the die 1000. Alternatively, the inter-array region 200 within each plane 300 can be centered in the respective plane 300 along the first horizontal direction hd1 (i.e., the inter-array region 200 is located the same distance from both ends of the respective plane 300).

Each memory array region 100 includes first-tier alternating stacks of first-tier insulating layers 132 and first-tier electrically conductive layers 146 (which function as first word lines), optional second-tier alternating stacks of second-tier insulating layers 232 and second-tier electrically conductive layers 246 (which function as second word lines), and optional third-tier alternating stacks of third-tier insulating layers 332 and third-tier electrically conductive layers 346 (which function as third word lines). Each second-tier alternating stack (232, 246) overlies a respective first-tier alternating stack (132, 146), and each third-tier alternating stack (332, 346), if present, overlies a respective second-tier alternating stack (232, 246). Each combination of a first-tier alternating stack (132, 146), an overlying second-tier alternating stack (232, 246), and an optional overlying third-tier alternating stack (332, 346) may be laterally spaced apart from neighboring combinations of a respective first-tier alternating stack (132, 146), an overlying respective second-tier alternating stack (232, 246), and an overlying optional third-tier alternating stack (332, 346) by lateral isolation trench fill structures 76 that laterally extend along the first horizontal direction hd1 (which may be a word line direction). The first-tier insulating layers 132, the second-tier insulating layers 232, and the third-tier insulating layers 332 are collectively referred to as insulating layers 32. The first-tier electrically conductive layers 146, the second-tier electrically conductive layers 246, and the third-tier electrically conductive layers 346 are collectively referred to as electrically conductive layers 46.

As used herein, a “first-tier level” refers to the tier level that is most proximal to a substrate, a “second-tier level” refers to the tier level that is most proximal to the substrate among tier levels that overlie the first-tier level, and a “third-tier level” refers to the tier level that is most proximal to the substrate among tier levels that overlie the second-tier level, etc. A “first-tier” element refers to an element that is located within the first-tier level; a “second-tier” element refers to an element that is located within the second-tier level; a “third-tier” element refers to an element that is located within the second-tier level; etc. Individual tier levels within a structure including multiple tier levels may be labeled as a first tier level, a second tier level, a third tier level, etc. In this case, the first tier level may be any of the multiple tier levels, the second tier level may be a tier level that is different from the first tier level, etc.

A first-tier alternating stack of first-tier insulating layers 132 and first-tier electrically conductive layers 146 is located over the substrate 9 between each neighboring pair of lateral isolation trench fill structures 76. A first-tier retro-stepped dielectric material portion 165 overlies, and contacts, first stepped surfaces of the first-tier alternating stack (132, 146). A second-tier alternating stack of second-tier insulating layers 232 and second-tier electrically conductive layers 246 overlies the first-tier alternating stack (132, 146), and overlies a horizontal plane including a planar top surface of the first-tier retro-stepped dielectric material portion 165 between each neighboring pair of lateral isolation trench fill structures 76. A second-tier retro-stepped dielectric material portion 265 overlies, and contacts, second stepped surfaces of the second-tier alternating stack (232, 246). A third-tier alternating stack of third-tier insulating layers 332 and third-tier electrically conductive layers 346, if present, overlies the second-tier alternating stack (232, 246), and overlies a horizontal plane including a planar top surface of the second-tier retro-stepped dielectric material portion 265 between each neighboring pair of lateral isolation trench fill structures 76. A third-tier retro-stepped dielectric material portion 365 overlies, and contacts, third stepped surfaces of the third-tier alternating stack (332, 346), if present. Vertical steps S of the first stepped surfaces and the second stepped surfaces laterally extend along the second horizontal direction hd2 (which may be a bit line direction). The first-tier retro-stepped dielectric material portion 165, the second-tier retro-stepped dielectric material portion 265, and the third-tier retro-stepped dielectric material portion 365 are collectively referred to as retro-stepped dielectric material portions 65.

Memory opening fill structures 58 can be located within each memory array region 100 (which includes a first memory array region 100A and a second memory array region 100B) between each neighboring pair of lateral isolation trench fill structures 76. The memory opening fill structures 58 can be located within memory openings that vertically extend through each layer within the first-tier alternating stack (132, 146), the second-tier alternating stack (232, 246), and the optional third-tier alternating stack (332, 346), if present, which are located between a respective neighboring pair of lateral isolation trench fill structures 76.

In one embodiment, each of the memory opening fill structures 58 comprises a vertical stack of memory elements (e.g., portions of a memory film or vertically separated, discrete memory elements) located at levels of the electrically conductive layers 46 and a vertical semiconductor channel 60 that is electrically connected to a respective overlying metal interconnect structure (such as a bit line). In one embodiment, the inter-array region 200 is free of any memory stack structure that is electrically contacted by any metal interconnect structure (such as a bit line).

Each memory opening fill structure 58 includes a respective memory stack structure, which includes a respective memory film and a respective vertical semiconductor channel. The memory openings and the memory opening fill structures 58 are formed in a region in which each layer of a first-tier alternating stack and each layer of the second-tier alternating stack are present. For each area within which a continuous combination of a first-tier alternating stack (132, 146), a second-tier alternating stack (232, 246), and an optional third-tier alternating stack (332, 346) continuously laterally extends, first memory stack structures can be located within a respective first memory array region 100A and second memory stack structures can be located within a respective second memory array region 100B. The second memory array region 100B can be connected to the first memory array region 100A through a respective inter-array region 200, in which a first-tier retro-stepped dielectric material portion 165, a second-tier retro-stepped dielectric material portion 265, and an optional third-tier retro-stepped dielectric material portion 365 are located.

A first-tier retro-stepped dielectric material portion 165 can be located between each neighboring pair of lateral isolation trench fill structures 76. Each first-tier retro-stepped dielectric material portion 165 overlies first stepped surfaces of a respective first-tier alternating stack (132, 146). Each first-tier retro-stepped dielectric material portion 165 can have a sidewall that laterally extends along the first horizontal direction hd1 and contacts a respective lateral isolation trench fill structure 76. The first stepped surfaces comprise vertical steps of the first-tier alternating stack (132, 146) that are laterally spaced apart along the first horizontal direction hd1 and vertically offset from each other.

A second-tier retro-stepped dielectric material portion 265 can be located between each neighboring pair of lateral isolation trench fill structures 76. Each second-tier retro-stepped dielectric material portion 265 overlies second stepped surfaces of a respective second-tier alternating stack (232, 246). Each second-tier retro-stepped dielectric material portion 265 can have a sidewall that laterally extends along the second horizontal direction hd1 and contacts a respective lateral isolation trench fill structure 76. The second stepped surfaces comprise vertical steps of the second-tier alternating stack (232, 246) that are laterally spaced apart along the first horizontal direction hd1 and vertically offset from each other. In one embodiment, each second-tier retro-stepped dielectric material portion 265 overlies, and contacts, a respective one of the first-tier retro-stepped dielectric material portions 165.

A third-tier retro-stepped dielectric material portion 365 can be located between each neighboring pair of lateral isolation trench fill structures 76. Each third-tier retro-stepped dielectric material portion 365 overlies third stepped surfaces of a respective third-tier alternating stack (332, 346). Each third-tier retro-stepped dielectric material portion 365 can have a sidewall that laterally extends along the second horizontal direction hd2 and contacts a respective lateral isolation trench fill structure 76. The third stepped surfaces comprise vertical steps of the third-tier alternating stack (332, 346) that are laterally spaced apart along the second horizontal direction hd2 and vertically offset from each other. In one embodiment, each third-tier retro-stepped dielectric material portion 365 overlies, and contacts, a respective one of the second-tier retro-stepped dielectric material portions 265.

Lateral isolation trenches can laterally extend along the first horizontal direction hd1. Each lateral isolation trench can be filled with a lateral isolation trench fill structure 76, which may include a combination of a backside contact via structure and an insulating spacer that laterally surround the backside contact via structure. Alternatively, each lateral isolation trench fill structure 76 may consist of an insulating fill structure. Each vertical stack of a first-tier alternating stack (132, 146), a second-tier alternating stack (232, 246), and an optional third-tier alternating stack (332, 346) can be located between a neighboring pair of lateral isolation trench fill structure 76.

Generally, at least the first-tier alternating stack (132, 146) can be located over the substrate 9. A second-tier alternating stack (232, 246) and/or a third-tier alternating stack (332, 346) may be located above the first-tier alternating stack (132, 146). The set of all alternating stack(s) in the first exemplary structure may be referred to as at least one alternating stack (32, 46).

A contact-level dielectric layer 80 can be formed over the at least one alternating stack (32, 46). In one embodiment, tubular layer contact via structures 86 vertically extend through at least one retro-stepped dielectric material portion 65 (which may comprise a plurality of retro-stepped dielectric material portions 65) and through respective underlying electrically conductive layers 46. Each such tubular layer contact via structure 86 can be electrically connected to respective topmost electrically conductive layer 46 (which is herein referred to as a respective first electrically conductive layer) of a horizontal step in a staircase region, and can be electrically isolated from any other underlying electrically conductive layers 46 by dielectric isolation structures, such as annular dielectric spacers 22, a tubular dielectric spacer 82 and/or a dielectric pillar 83. Formation of the annular dielectric spacers 22 and formation of the tubular layer contact via structures 86 are described in detail in subsequent sections of the present disclosure. Alternatively, each electrically conductive layer 46 may be formed with a respective tubular vertically-extending portion (not illustrated) in areas that do not underlie any other electrically conductive layer 46. In this case, a layer contact via structure (not illustrated) may contact an inner cylindrical sidewall of a respective one of the tubular vertically-extending portion of the electrically conductive layers 46. Formation of such electrically conductive layers 46 with tubular vertically-extending portions and such layer contact via structures is also described in subsequent sections of the present disclosure.

The inter-array region 200 includes strips of the first-tier insulating layers 132, the first-tier electrically conductive layers 146, the second-tier insulating layers 232, the second-tier electrically conductive layers 246, the third-tier insulating layers 332, and the third-tier electrically conductive layers 346 located between each laterally neighboring pair of lateral isolation trench fill structures 76. Such strips are located in a respective strip-shaped connection region 240 (i.e., bridge regions) of the inter-array regions 200, which are located adjacent to a respective first-tier retro-stepped dielectric material portion 165, a respective second-tier retro-stepped dielectric material portion 265, or a respective third-tier retro-stepped dielectric material portions 365. The strips have a narrower width along the second horizontal direction hd2 than portions of the alternating stacks (132, 146, 232, 246, 332, 346) located in the memory array regions 100, and portions of the strips located in the remaining portions of the inter-array regions 200 outside of the respective strip-shaped connection regions 240.

For each vertical stack of a first-tier alternating stack (132, 146), a second-tier alternating stack (232, 246), and an optional third-tier alternating stack (332, 346), first memory opening fill structures 58 can be located within a first memory array region 100A in which each layer of the first-tier alternating stack (132, 146), the second-tier alternating stack (232, 246), and the optional third-tier alternating stack (332, 346) is present. Further, second memory opening fill structures 58 can be located within a second memory array region 100B that is laterally offset along the first horizontal direction hd1 from the first memory array region 100A by the first-tier retro-stepped dielectric material portion 165, the second-tier retro-stepped dielectric material portion 265, and the optional third-tier retro-stepped dielectric material portion 365. Each layer of the first-tier alternating stack (132, 146), the second-tier alternating stack (232, 246), and the optional third-tier alternating stack (332, 346) is present within the second memory array region 100B. Each of the electrically conductive layers 46 within the vertical stack may continuously extend from the first memory array region 100A to the second memory array region 100B through a strip-shaped connection region 240 (which is also referred to as a bridge region). Each strip-shaped connection region 240 is located within an inter-array region 200, and may be located between the lateral isolation trench fill structure 76 and the first-tier retro-stepped dielectric material portion 165 at the level of the first-tier alternating stack (132, 146), or between a lateral isolation trench fill structures 76 and the second-tier retro-stepped dielectric material portion 265 at the level of the second-tier alternating stack (232, 246), or between a lateral isolation trench fill structures 76 and the third-tier retro-stepped dielectric material portion 365 at the level of the third-tier alternating stack (332, 346).

Staircases including first stepped surfaces of a first-tier alternating stack (132, 146), optionally second stepped surfaces of a second-tier alternating stack (232, 246), and optionally third stepped surfaces of a third-tier alternating stack (332, 346) can ascend (i.e., rise) from the substrate along the first horizontal direction hd1, or along the opposite direction of the first horizontal direction hd1. Each region including the staircases is herein referred to as a staircase region. In one embodiment, the direction of rise of the staircases can change for every other pair of vertical stacks of a respective first-tier alternating stack (132, 146), a respective second-tier alternating stack (232, 246), and a respective third-tier alternating stack (332, 346). In other words, the direction of rise is staggered in adjacent alternating stacks that are separated along the second horizontal direction

Optional laterally-isolated vertical interconnection structures (484, 486) can be formed through the inter-array region 200. Each laterally-isolated vertical interconnection structure (484, 486) can include a through-memory-level conductive via structure 486 and a tubular insulating spacer 484 that laterally surrounds the conductive via structure 486. The laterally-isolated vertical interconnection structures (484, 486) vertically extend through the strip portions of the first-tier alternating stack (132, 146), the second-tier alternating stack (232, 246), and the third-tier alternating stack (332, 346), and can contact the substrate 9. Alternatively, the laterally-isolated vertical interconnection structures (484 and/or 486) may be omitted.

Drain contact via structures 88 can contact an upper portion of a respective memory opening fill structure 58 (such as a drain region within the respective memory opening fill structure 58). Bit lines (not illustrated) can laterally extend along the second horizontal direction hd2, and can contact top surfaces of a respective subset of the drain contact via structures. Additional metal interconnect structures embedded in overlying dielectric material layers (not shown) may be employed to provide electrical connection among the various nodes of the three-dimensional memory device located in the semiconductor die 1000.

Each lateral isolation trench fill structure 76 includes an insulating material portion. In one embodiment, each insulating material portion may comprise an insulating spacer that laterally surrounds a layer contact via structure such as a backside contact via structure (not expressly shown). In another embodiment, each insulating material portion may comprise a dielectric wall structure which takes up the entire volume of the respective lateral isolation trench fill structure 76. In one embodiment, each sidewall of the first alternating stacks (132, 146) can be contacted by a sidewall of an insulating material portion of a respective one of the lateral isolation trench fill structures 76.

In one embodiment, each plane 300 within the exemplary semiconductor die 1000 includes a three-dimensional memory device, which includes alternating stacks of insulating layers 32 and electrically conductive layers 46. Each of the alternating stacks {(132, 146), (232, 246), (332, 346)} laterally extends along a first horizontal direction hd1 through a first memory array region 100A and a second memory array region 100B that are laterally spaced apart by an inter-array region 200. Each of the alternating stacks {(132, 146), (232, 246), (332, 346)} includes a set of stepped surfaces (i.e., a staircase) in the inter-array region 200. Each plane 300 within the exemplary semiconductor die 1000 includes retro-stepped dielectric material portions (165, 265, 365) overlying a respective set of stepped surfaces of the alternating stacks {(132, 146), (232, 246), (332, 346)}. Each plane 300 within the exemplary semiconductor die 1000 includes clusters of memory stack structures located within memory opening fill structures 58. Each of the memory stack structures vertically extends through a respective one of the alternating stacks {(132, 146), (232, 246), (332, 346)} and is located within the first memory array region 100A or the second memory array region 100B. Each memory stack structure can include a respective vertical semiconductor channel and a vertical stack of memory elements (e.g., a memory film) located at levels of the electrically conductive layers 46.

Each of the retro-stepped dielectric material portions 65 comprises a respective stepped bottom surface. Each region of the alternating stacks (32, 46) that underlies a respective retro-stepped dielectric material portion 65 constitutes a staircase region. A strip-shaped connection region 240 including each layer within an alternating stack (32, 46) is provided adjacent to each staircase region, and is herein referred to as a bridge region. Each strip-shaped connection region 240 laterally extends along the first horizontal direction hd1, and provides electrically conductive paths between a respective portion located in the first memory array region 100A and a respective portion located in the second memory array region 100B for each electrically conductive layer 46. The strip region has a lesser width (i.e., narrower width along the second horizontal direction hd2) than the portions of the electrically conductive layer 46 located in the first memory array region 100A or in the second memory array region 100B. The portions of the electrically conductive layer 46 located in the first memory array region 100A or in the second memory array region 100B have a width along the second horizontal direction hd2 that is the same as a lateral distance between a neighboring pair of lateral isolation trench fill structures 76.

In contrast, each strip portion of the electrically conductive layer 46 in the strip-shaped connection region 240 has a width along the second horizontal direction hd2 that is the same as the difference between the lateral distance between a neighboring pair of lateral isolation trench fill structures 76 and the width of an adjoining retro-stepped dielectric material portion (165 or 265) along the second horizontal direction hd2. Each electrical connection between a tubular layer contact via structure 86 and a most proximal portion of the second memory array region 100B includes a narrow strip portion of an electrically conductive layer 46 in the strip-shaped connection region 240, while electrical connection between the tubular layer contact via structure 86 and a most proximal portion of the first memory array region 100A does not include any narrow strip portion of the electrically conductive layer 46 because the first memory array region 100A is not separated from the tubular layer contact via structures 86 by the strip-shaped connection region 240.

In one embodiment, the alternating stacks {(132, 146), (232, 246), (332, 346)} are laterally spaced apart along the second horizontal direction hd2 by line trenches (such as lateral isolation trenches) that laterally extend along the first horizontal direction hd1. The line trenches are filled with lateral isolation trench fill structures 76 having dielectric surfaces (such as surfaces of insulating spacers or dielectric wall structures) that contact sidewalls of the alternating stacks {(132, 146), (232, 246), (332, 346)}. In one embodiment, upon sequentially numbering the lateral isolation trench fill structures 76 with positive integers along the second horizontal direction hd2, odd-numbered lateral isolation trench fill structures 76 (e.g., 761) may contact a respective pair of retro-stepped dielectric material portions (165, 265, 365) (which are located on either side of a respective odd-numbered lateral isolation trench fill structure 76), and even-numbered lateral isolation trench fill structures 76 (e.g., 762) do not contact any retro-stepped dielectric material portion (165, 265, 365), or alternatively, even-numbered lateral isolation trench fill structures 76 (e.g., 762) may contact a respective pair of retro-stepped dielectric material portions (165, 265, 365) and odd-numbered lateral isolation trench fill structures 76 (e.g., 761) do not contact any retro-stepped dielectric material portion (165, 265, 365).

In one embodiment, strip widths of the first-tier electrically conductive layers 146 decrease with a respective vertical distance from the substrate 9. Strip widths of the second-tier electrically conductive layers 246 decrease with a respective vertical distance from the substrate 9. Strip widths of the third-tier electrically conductive layers 346 decrease with a respective vertical distance from the substrate 9. A bottommost second electrically conductive layer 246 within the second-tier alternating stack (232, 246) has a greater strip width than a topmost first electrically conductive layer 146 within the first-tier alternating stack (132, 146). A bottommost third electrically conductive layer 346 within the third-tier alternating stack (332, 346) has a greater strip width than a topmost second electrically conductive layer 246 within the second-tier alternating stack (232, 246).

According to an aspect of the present disclosure shown in FIG. 1E, a set of a first-tier retro-stepped dielectric material portion 165, a second-tier retro-stepped dielectric material portion 265, and a third-tier retro-stepped dielectric material portion 365 can be formed between a neighboring pair of lateral isolation trench fill structures 76, which are herein referred to as a first lateral isolation trench fill structure 761 and a second lateral isolation trench fill structure 762. The width of each strip of an electrically conductive layer 46 along the second horizontal direction in the strip-shaped connection region 240 is herein referred to as a strip width or a bridge width. Generally, embedding of the retro-stepped dielectric material portions (165, 265, 365) in the alternating stacks of insulating layers 32 and electrically conductive layers 46 may induce cracking due to voids formed in the retro-stepped dielectric material portions (165, 265, 365) and/or due to incline of the alternating stacks into the lateral isolation trenches due to unbalanced electrically conductive layer material filling. While the illustrated configuration of the first exemplary structure illustrated in FIGS. 1A-1E includes three tier levels, embodiments are expressly contemplated herein in which one tier level, two tier levels, or four or more tier levels are used in an alternative configuration.

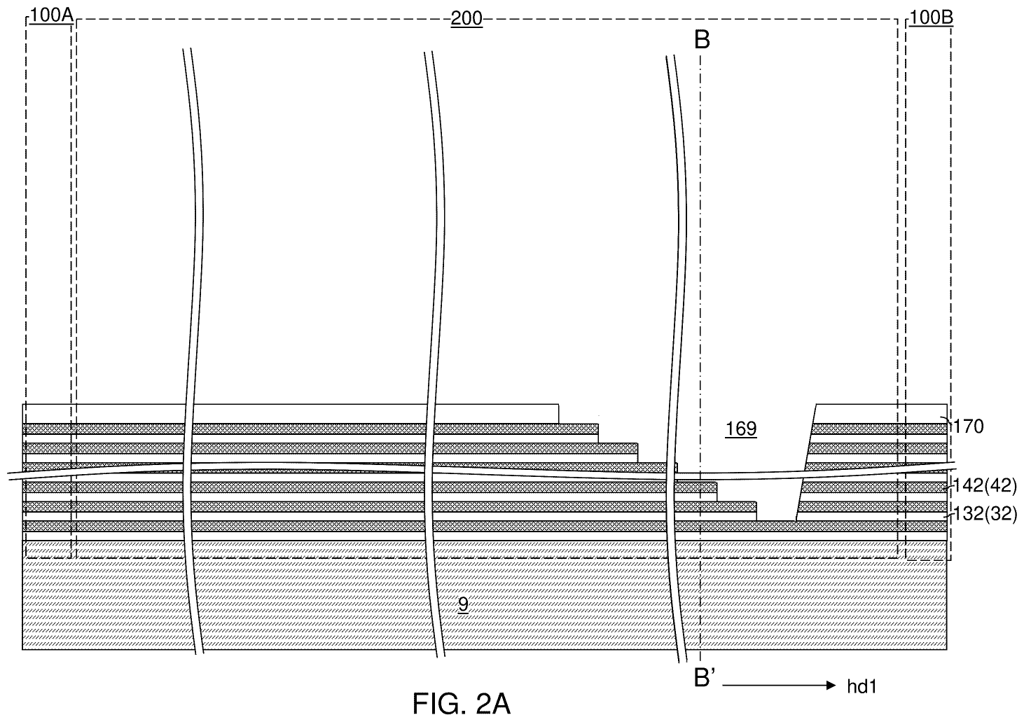

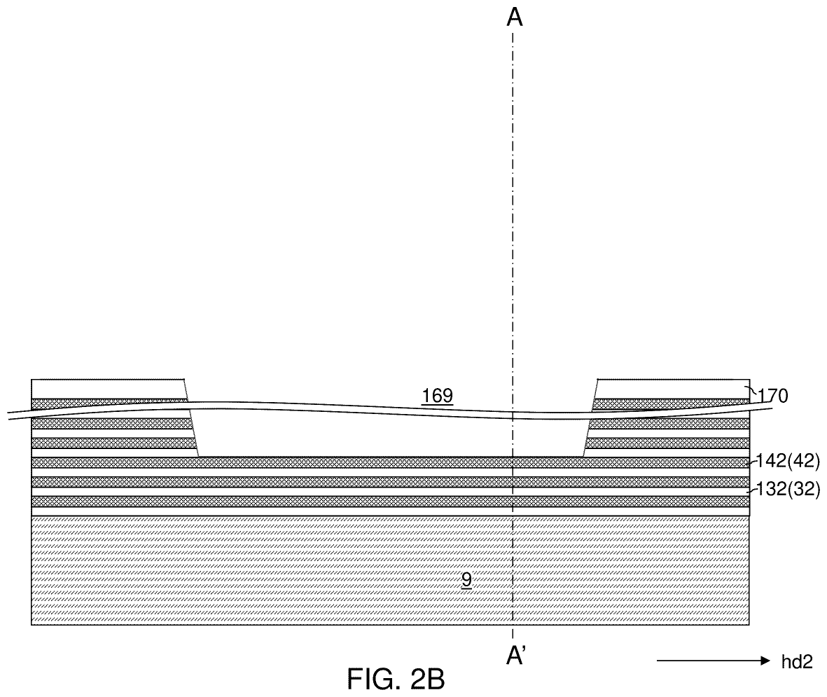

Referring to FIGS. 2A and 2B, a first exemplary structure according to an embodiment of the present disclosure is illustrated, which can be employed to form a semiconductor die such as the semiconductor die 1000 illustrated in FIGS. 1A-1E.

A first vertically alternating sequence of first-tier insulating layers 132 and first-tier sacrificial material layers 142 can be formed over a substrate 9. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The first-tier insulating layers 132 can be composed of the first material, and the first-tier sacrificial material layers 142 can be composed of the second material, which is different from the first material. Each of the first-tier insulating layers 132 is an insulating layer that continuously extends over the entire area of the substrate 9, and may have a uniform thickness throughout. Each of the first-tier sacrificial material layers 142 may be a sacrificial material layer, which includes a dielectric material and continuously extends over the entire area of the substrate 9, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide.

The second material of the first-tier sacrificial material layers 142 is a dielectric material, which is a sacrificial material that may be removed selectively to the first material of the first-tier insulating layers 132. As used herein, removal of a first material is “selectively to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier sacrificial material layer 142 may be in a range from 15 nm to 50 nm, such as from 20 nm to 30 nm, although lesser and greater thicknesses may also be employed. The second material of the first-tier sacrificial material layers 142 may be subsequently replaced with electrically conductive electrodes which may function, for example, as control gate electrodes of a vertical NAND device. In one embodiment, the first-tier sacrificial material layers 142 may comprise silicon nitride.

Generally, a vertically alternating sequence of unit layer stacks is formed over a substrate. Each of the unit layer stacks comprises a first insulating layer (such as a first insulating layer 132) and a first spacer material layer (such as a first-tier sacrificial material layer 142). Generally, the first spacer material layers are formed as, or are subsequently replaced with, first-tier electrically conductive layers. While the present disclosure is described employing an embodiment in which the first spacer material layers are formed as first-tier sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted.

A first-tier insulating cap layer 170 can be formed over the first vertically alternating sequence (132, 142). The first-tier insulating cap layer 170 comprises an insulating material, which may be the same material as the material of the first-tier insulating layers 132. First stepped surfaces can be formed within the staircase regions of the inter-array region 200 by patterning the first-tier insulating cap layer 170 and the first vertically alternating sequence (132, 142). For example, a combination of a sacrificial hard mask layer and a trimming mask layer may be employed to form the first stepped surfaces. In one embodiment, a row of multiple first staircase regions can be formed within each area that corresponds to a combination of the area of a laterally-neighboring pair of first-tier retro-stepped dielectric material portions 165 and an intervening area. In this case, the multiple first staircase regions can be vertically offset by different depths by subsequently performing area recess etch processes. The region including the first stepped surfaces is herein referred to as a first staircase region.

A first-tier stepped cavity 169 can be formed over each contiguous set of first stepped surfaces of the first vertically alternating sequence (132, 142). The lateral extents of the first-tier sacrificial material layers 142 vary with a vertical distance from the substrate 9. Generally, an alternating stack (32, 42) of insulating layers 32 and sacrificial material layers 42 may be formed over a substrate 9, and first stepped surfaces can be formed by patterning the alternating stack (32, 42) such that lateral extents of the sacrificial material layers 42 vary with a vertical distance from the substrate 9 in a staircase region.

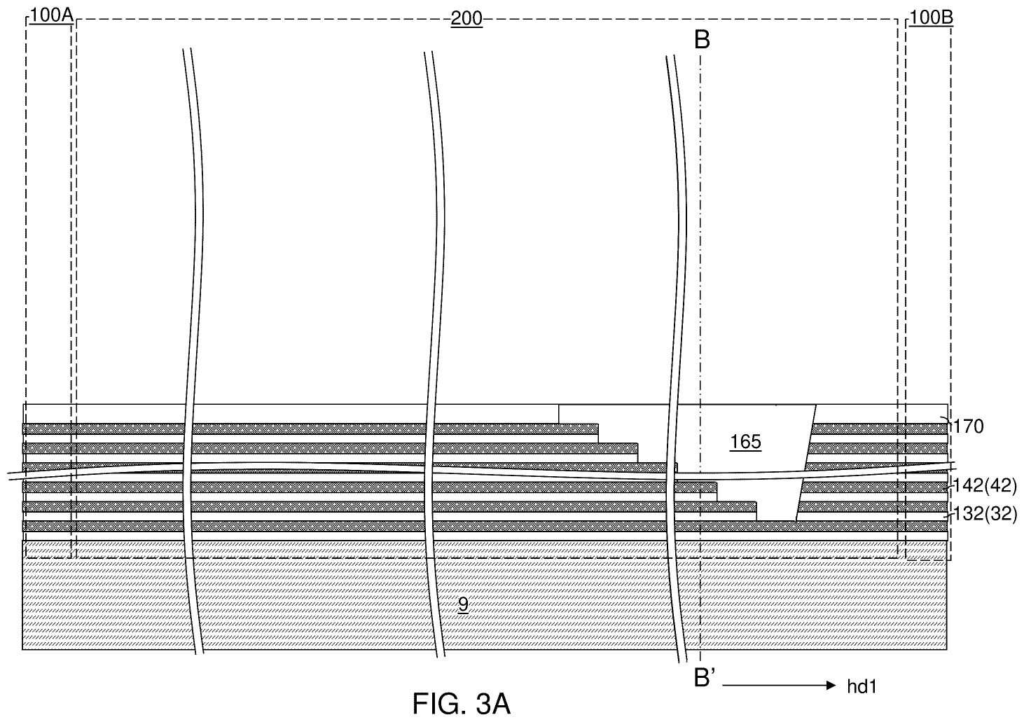

Referring to FIGS. 3A and 3B, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity 169 constitutes a first-tier retro-stepped dielectric material portion 165. Generally, the first-tier retro-stepped dielectric material portions 165 can be formed in inter-array regions 200 located between a respective first memory array region 100A and a respective second memory array region 100B that are laterally spaced apart along the first horizontal direction hd1. The planar top surface of each first-tier retro-stepped dielectric material portion 165 can be located within a horizontal plane including the top surface of the first-tier insulating cap layer 170.

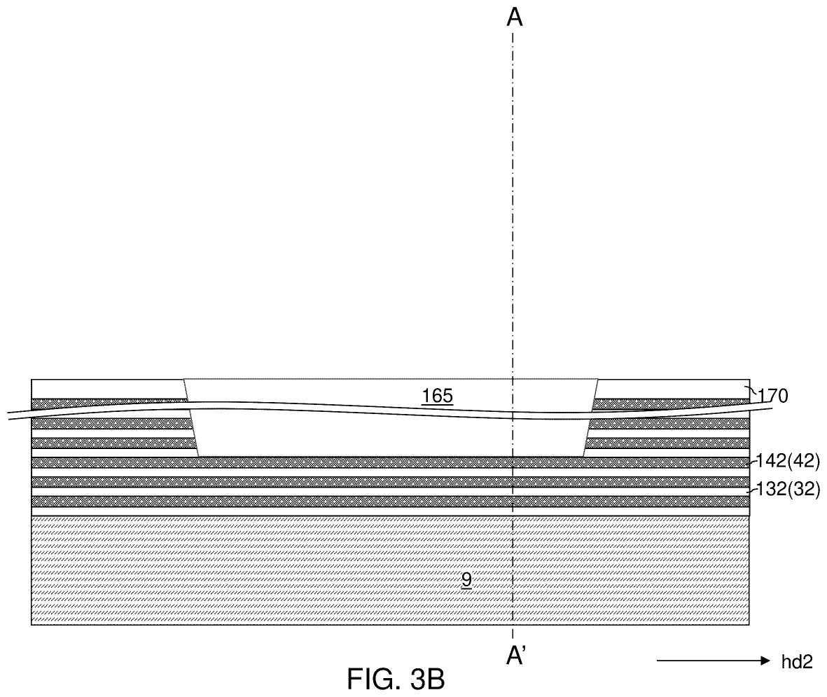

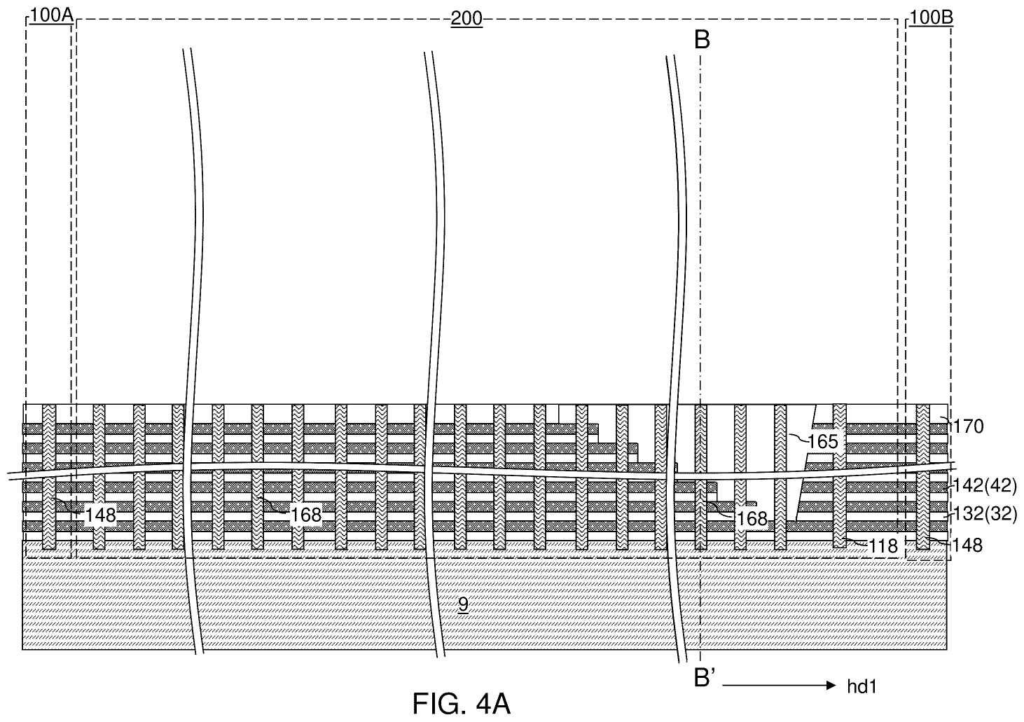

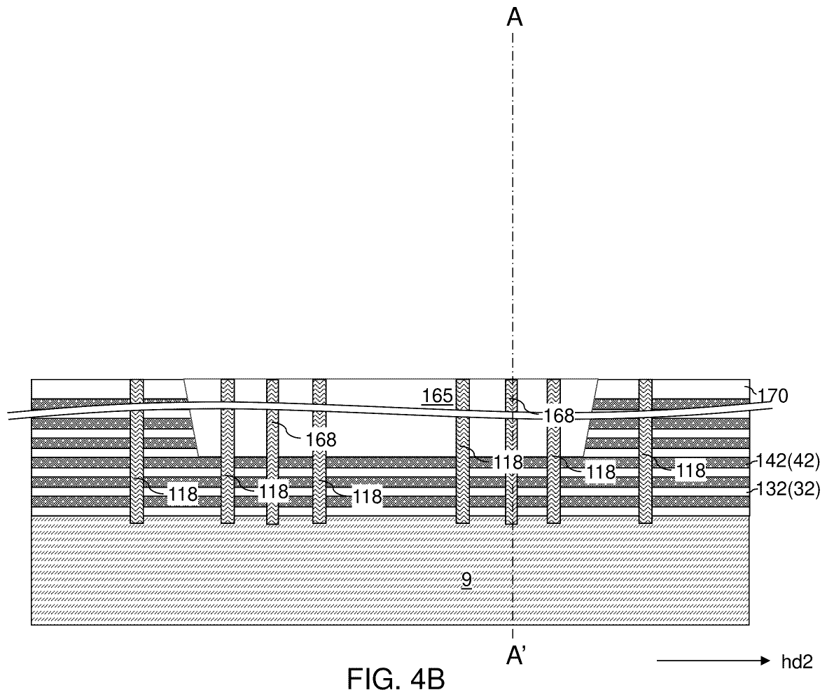

Referring to FIGS. 4A and 4B, various first-tier openings may be formed through the first vertically alternating sequence (132, 142) and into the substrate 9. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the substrate 9 by a first anisotropic etch process to form the various first-tier openings concurrently. The various first-tier openings may include first-tier memory openings formed in the memory array regions 100 and first-tier support openings formed in the inter-array regions 200, and first-tier contact openings formed in the staircase regions (which are located within the inter-array regions 200). Each cluster of first-tier memory openings may be formed as a two-dimensional array of first-tier memory openings. The first-tier support openings are openings that are formed in the inter-array region 200, and are subsequently employed to form support pillar structures. Each first-tier contact opening is formed in a respective area in which a respective tubular layer contact via structure 86 is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

Sacrificial first-tier opening fill structures (148, 118, 168) may be formed in the various first-tier openings. For example, a sacrificial first-tier fill material is concurrently deposited in each of the first-tier openings. The sacrificial first-tier fill material includes a material that may be subsequently removed selectively to the materials of the first-tier insulating layers 132 and the first-tier sacrificial material layers 142. In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the material of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In yet another embodiment, the sacrificial first-tier fill material may include carbon-containing material (such as amorphous carbon or diamond-like carbon) that may be subsequently removed by ashing, or a silicon-based polymer that may be subsequently removed selectively to the materials of the first vertically alternating sequence (132, 142).

Portions of the deposited sacrificial first-tier fill material may be removed from above the topmost layer of the first vertically alternating sequence (132, 142), such as from above the first-tier insulating cap layer 170. For example, the sacrificial first-tier fill material may be recessed to a top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 118, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure 118. Each remaining portion of the sacrificial first-tier fill material in a first-tier contact opening constitutes a sacrificial first-tier contact opening fill structure 168. The various sacrificial first-tier opening fill structures (148, 118, 168) are concurrently formed, i.e., during a same set of processes including the deposition process that deposits the sacrificial first-tier fill material and the planarization process that removes the first-tier deposition process from above the first vertically alternating sequence (132, 142) (such as from above the top surface of the first-tier insulating cap layer 170). The top surfaces of the sacrificial first-tier opening fill structures (148, 118, 168) may be coplanar with the top surface of the first-tier insulating cap layer 170. Each of the sacrificial first-tier opening fill structures (148, 118, 168) may, or may not, include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure. The sacrificial first-tier contact opening fill structures 168 may vertically extend from a horizontal plane including a top surface of the first-tier alternating stack (132, 142) at least to a horizontal plane including a bottom surface of the first-tier alternating stack (132, 142).

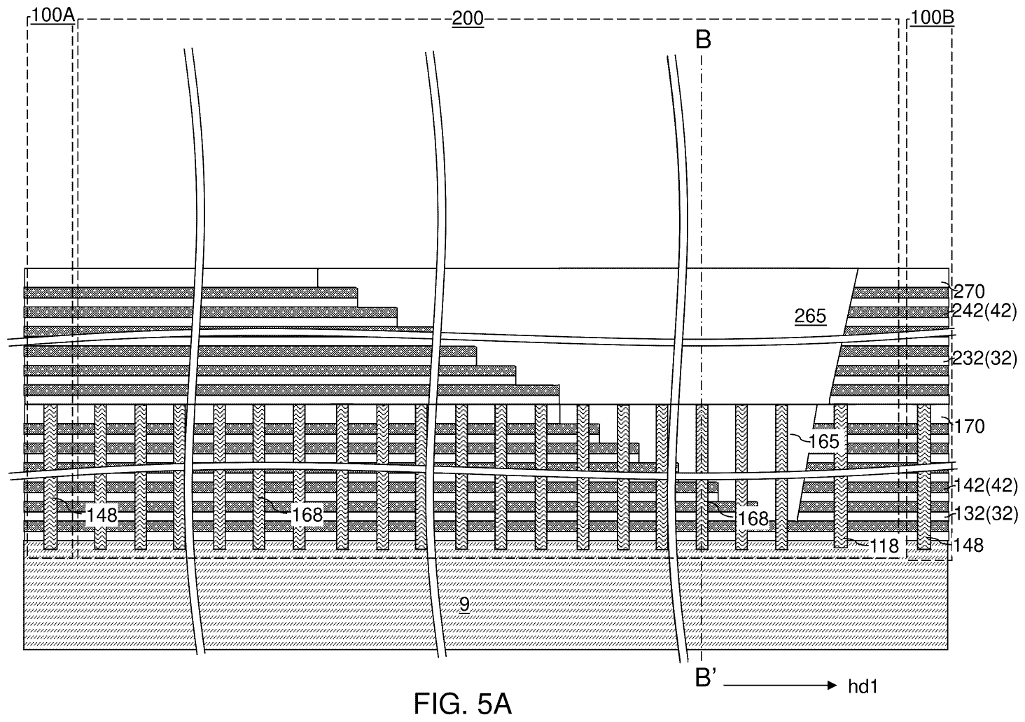

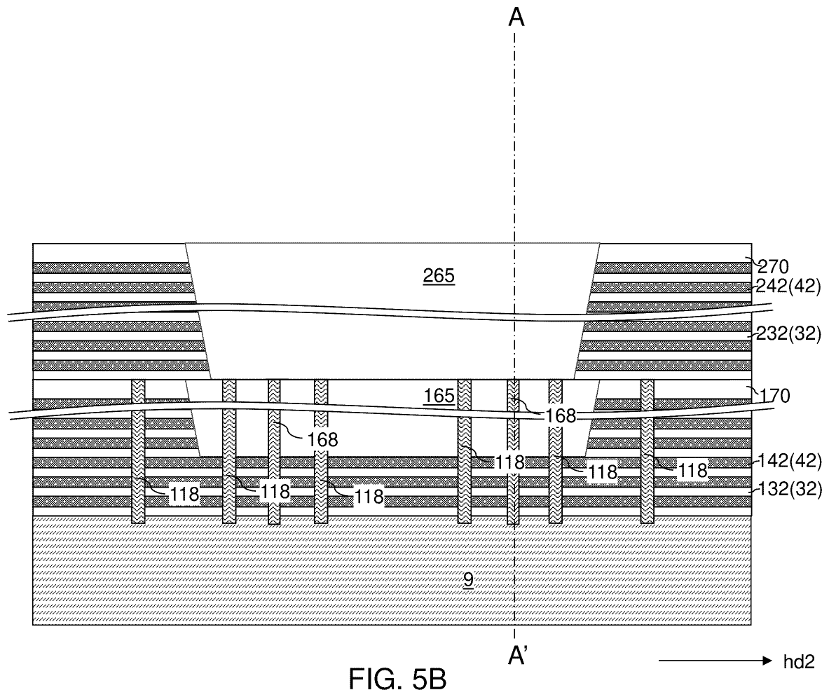

Referring to FIGS. 5A and 5B, a second vertically alternating sequence of second-tier insulating layers 232 and second-tier sacrificial material layers 242 can be formed. Each of the second-tier insulating layers 232 is an insulating layer 32 that continuously extends over the entire area of the substrate 9, and may have a uniform thickness throughout. Each of the second-tier sacrificial material layers 242 is a sacrificial material layer 42 that includes a dielectric material and continuously extends over the entire area of the substrate 9, and may have a uniform thickness throughout. The second-tier insulating layers 232 can have the same material composition and the same thickness as the first-tier insulating layers 132. The second-tier sacrificial material layers 242 can have the same material composition and the same thickness as the first-tier sacrificial material layers 142. A second-tier insulating cap layer 270 can be formed over the second vertically alternating sequence (232, 242).

Second stepped surfaces can be formed within the staircase regions of the inter-array region 200. For example, a combination of a sacrificial hard mask layer and a trimming mask layer may be employed to form the second stepped surfaces. Generally, the processing steps described with reference to FIGS. 2A-2C can be performed to form second-tier stepped cavities, under which a respective set of second stepped surfaces of the second vertically alternating sequence (232, 242) are exposed. Each set of second stepped surfaces may be laterally offset relative to an adjacent and underlying set of first stepped surfaces of the first vertically alternating sequence (132, 142) along the first horizontal direction hd1.

A second dielectric fill material (such as undoped silicate glass (i.e., silicon oxide) or a doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second continuous retro-stepped cavity constitutes a second-tier retro-stepped dielectric material portion 265. First vertical steps S1 of the first stepped surfaces that underlie the first-tier retro-stepped dielectric material portion 165 and second vertical steps S2 of the second stepped surfaces that underlie the second-tier retro-stepped dielectric material portion 265 are illustrated. The second vertical steps S2 are perpendicular to the first horizontal direction hd1. Generally, a second-tier structure is formed, which comprises a second vertically alternating sequence of second-tier insulating layers 232 and second-tier sacrificial material layers 242 and second-tier retro-stepped dielectric material portions 265 overlying second stepped surfaces of the second vertically alternating sequence that are located in the inter-array regions 200.

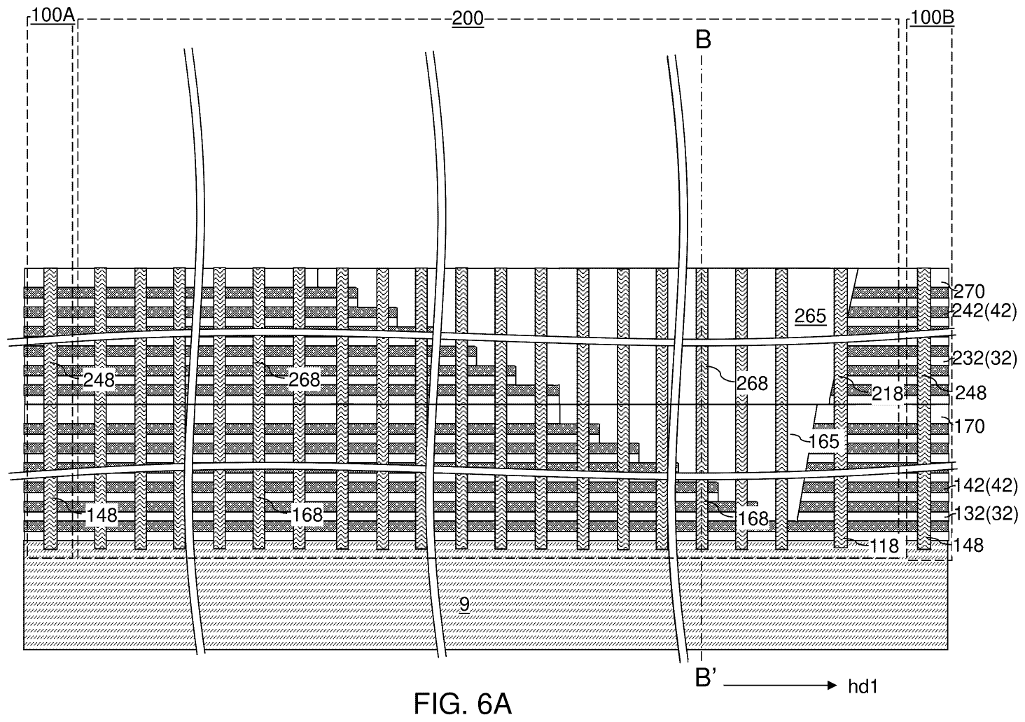

Referring to FIGS. 6A and 6B, various second-tier openings may be formed through the second vertically alternating sequence (232, 242) and over the sacrificial first-tier opening fill structures (148, 118, 168). A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) to form the various second-tier openings concurrently, i.e., during the second isotropic recess etch process.

The various second-tier openings may include second-tier memory openings formed in the memory array regions 100, second-tier support openings formed in the inter-array region 200, and second-tier contact openings formed in the staircase region which is located within the inter-array region 200. Each second-tier opening may be formed within the area of a respective one of the sacrificial first-tier opening fill structures (148, 118, 168). Thus, a top surface of a sacrificial first-tier opening fill structure can be physically exposed at the bottom of each second-tier opening. Specifically, each second-tier memory opening can be formed directly over a respective sacrificial first-tier memory opening fill structure 148, each second-tier support opening can be formed directly over a respective sacrificial first-tier support opening fill structure 118, and each second-tier contact opening can be formed directly over a respective sacrificial first-tier contact opening fill structure 168.

Each cluster of second-tier memory openings may be formed as a two-dimensional array of second-tier memory openings. The second-tier support openings are openings that are formed in the inter-array region 200, and are subsequently employed to form support pillar structures. A subset of the second-tier support openings may be formed through a respective horizontally-extending surface segment of the second stepped surfaces. A subset of the second-tier contact openings may be formed through a respective horizontally-extending surface segment of the second stepped surfaces.

Sacrificial second-tier opening fill structures may be formed in the various second-tier openings. For example, a sacrificial first-tier fill material is concurrently deposited in each of the second-tier openings. The sacrificial second-tier fill material can include any material that may be employed for the sacrificial first-tier fill material. Portions of the deposited sacrificial second-tier fill material may be removed from above the topmost layer of the second vertically alternating sequence (232, 242). Remaining portions of the sacrificial second-tier fill material comprise sacrificial second-tier opening fill structures (248, 218, 268).

Specifically, each remaining portion of the sacrificial second-tier fill material in a second-tier memory opening constitutes a sacrificial second-tier memory opening fill structure 248. Each remaining portion of the sacrificial second-tier fill material in a second-tier support opening constitutes a sacrificial second-tier support opening fill structure 218. Each remaining portion of the sacrificial second-tier fill material in a second-tier contact opening constitutes a sacrificial second-tier contact opening fill structure 268. The top surfaces of the sacrificial second-tier opening fill structures (248, 218, 268) may be coplanar with the top surface of the second-tier insulating cap layer 270. Each of the sacrificial second-tier opening fill structures may, or may not, include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure. The sacrificial second-tier contact opening fill structures 268 may vertically extend from a horizontal plane including a top surface of the second-tier alternating stack (232, 242) at least to a horizontal plane including a bottom surface of the second-tier alternating stack (232, 242).

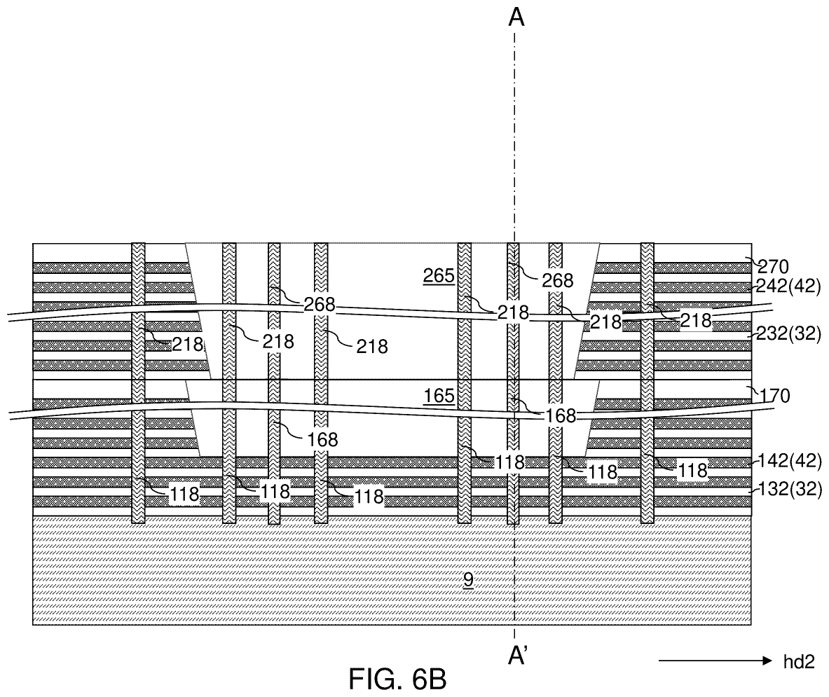

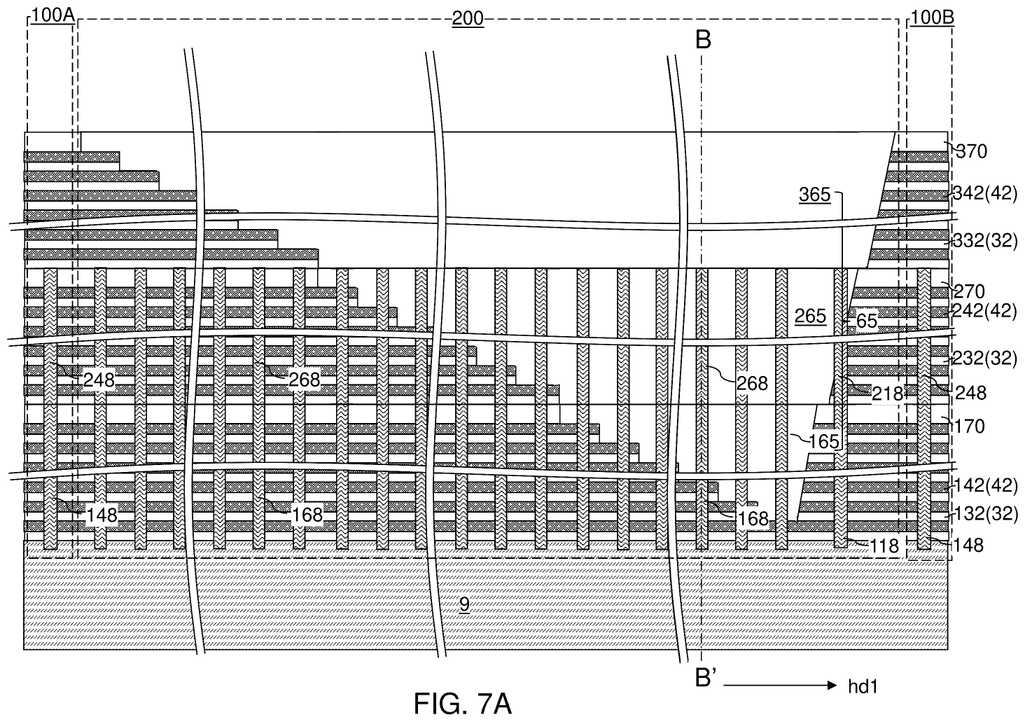

Referring to FIGS. 7A and 7B, a third vertically alternating sequence of third-tier insulating layers 332 and third-tier sacrificial material layers 342 can be formed. Each of the third-tier insulating layers 332 is an insulating layer 32 that continuously extends over the entire area of the substrate 9, and may have a uniform thickness throughout. Each of the third-tier sacrificial material layers 342 is a sacrificial material layer 42 that includes a dielectric material and continuously extends over the entire area of the substrate 9, and may have a uniform thickness throughout. The third-tier insulating layers 332 can have the same material composition and the same thickness as the first-tier insulating layers 132. The third-tier sacrificial material layers 342 can have the same material composition and the same thickness as the first-tier sacrificial material layers 142. A third-tier insulating cap layer 370 can be formed over the third vertically alternating sequence (332, 342).

Third stepped surfaces can be formed within the staircase regions of the inter-array region 200. For example, a combination of a sacrificial hard mask layer and a trimming mask layer may be employed to form the third stepped surfaces. Generally, the processing steps described with reference to FIGS. 2A-2C can be performed to form third-tier stepped cavities, under which a respective set of third stepped surfaces of the third vertically alternating sequence (332, 342) are exposed. Each set of third stepped surfaces may be laterally offset relative to an adjacent and underlying set of second stepped surfaces of the second vertically alternating sequence (232, 242) and relative to an adjacent and underlying set of first stepped surfaces of the first vertically alternating sequence (132, 142) along the first horizontal direction hd1.

A third dielectric fill material (such as undoped silicate glass (i.e., silicon oxide) or a doped silicate glass) can be deposited in each third continuous retro-stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third continuous retro-stepped cavity constitutes a third-tier retro-stepped dielectric material portion 365.

Generally, at least one tier structure is formed. Each tier structure comprises an alternating stack of insulating layers 32 and sacrificial material layers 42. Stepped surfaces can be formed by patterning the alternating stack (32, 42) in a staircase region. A retro-stepped dielectric material portion 65 can be formed over the stepped surfaces.

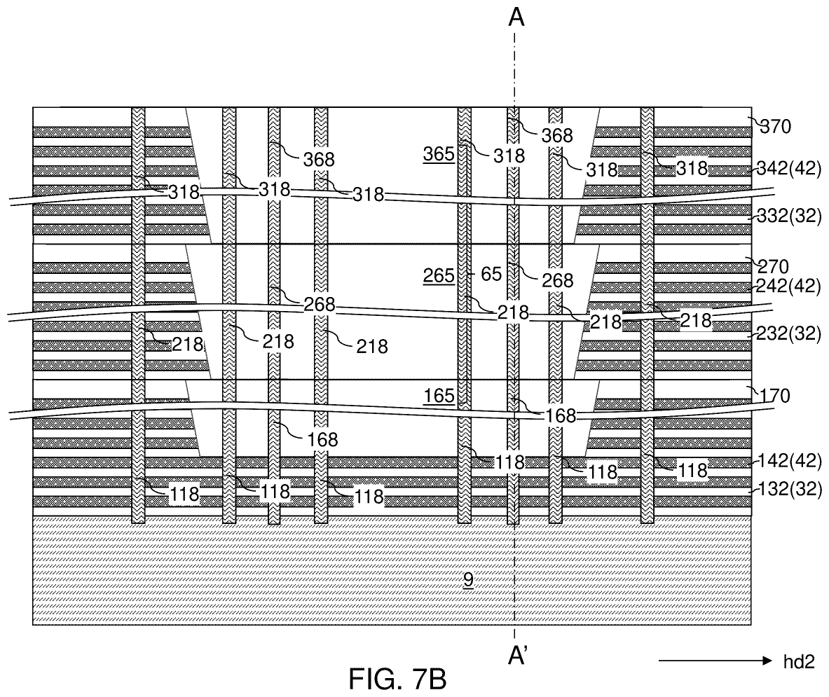

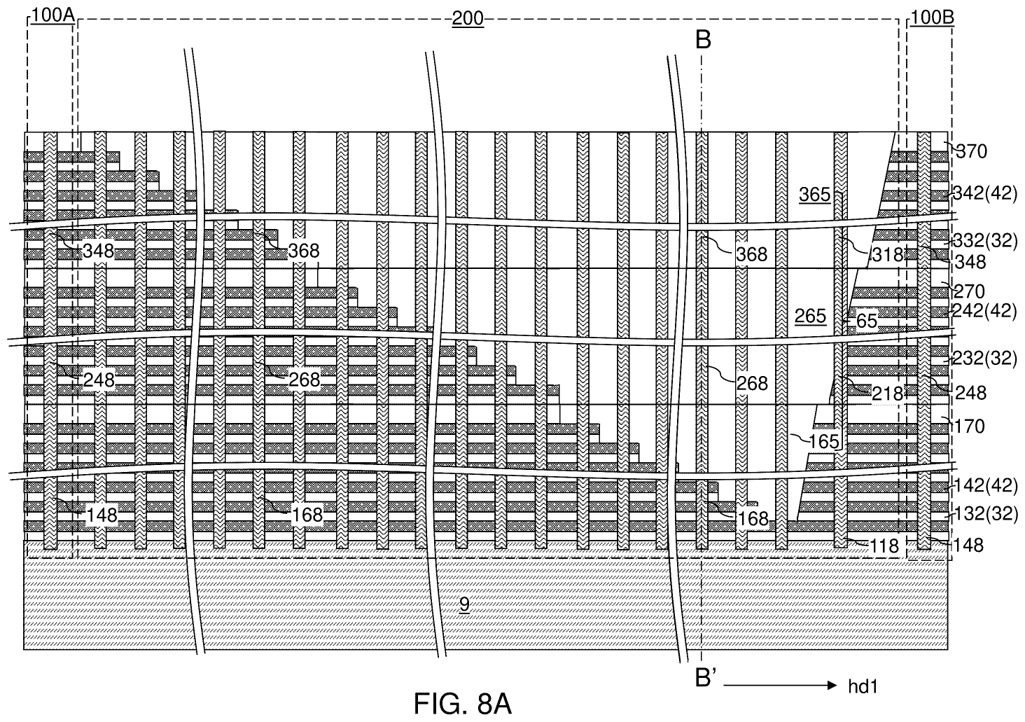

Referring to FIGS. 8A and 8B, various third-tier openings may be formed through the third vertically alternating sequence (332, 342) and over the sacrificial second-tier opening fill structures (248, 218, 268). A photoresist layer (not shown) may be applied over the third vertically alternating sequence (332, 342), and may be lithographically patterned to form various openings therethrough. The pattern of openings in the photoresist layer may be transferred through the third vertically alternating sequence (332, 342) to form the various third-tier openings concurrently, i.e., during the third isotropic etch process.

The various third-tier openings may include third-tier memory openings formed in the memory array regions 100, third-tier support openings formed in the inter-array region 200, and third-tier contact openings formed in the staircase region which is located within the inter-array region 200. Each third-tier opening may be formed within the area of a respective one of the sacrificial second-tier opening fill structures (248, 218, 268). Thus, a top surface of a sacrificial second-tier opening fill structure can be physically exposed at the bottom of each third-tier opening. Specifically, each third-tier memory opening can be formed directly over a respective sacrificial second-tier memory opening fill structure 248, each third-tier support opening can be formed directly over a respective sacrificial second-tier support opening fill structure 218, and each third-tier contact opening can be formed directly over a respective sacrificial second-tier contact opening fill structure 268. Each cluster of third-tier memory openings may be formed as a two-dimensional array of third-tier memory openings. The third-tier support openings are openings that are formed in the inter-array region 200, and are subsequently employed to form support pillar structures. A subset of the third-tier support openings may be formed through a respective horizontally-extending surface segment of the third stepped surfaces. A subset of the third-tier contact openings may be formed through a respective horizontally-extending surface segment of the third stepped surfaces.

Sacrificial third-tier opening fill structures may be formed in the various third-tier openings. For example, a sacrificial second-tier fill material is concurrently deposited in each of the third-tier openings. The sacrificial third-tier fill material can include any material that may be employed for the sacrificial second-tier fill material. Portions of the deposited sacrificial third-tier fill material may be removed from above the topmost layer of the third vertically alternating sequence (332, 342). Remaining portions of the sacrificial third-tier fill material comprise sacrificial third-tier opening fill structures (348, 318, 368). Specifically, each remaining portion of the sacrificial third-tier fill material in a third-tier memory opening constitutes a sacrificial third-tier memory opening fill structure 348. Each remaining portion of the sacrificial third-tier fill material in a third-tier support opening constitutes a sacrificial third-tier support opening fill structure 318. Each remaining portion of the sacrificial third-tier fill material in a third-tier contact opening constitutes a sacrificial third-tier contact opening fill structure 368. The top surfaces of the sacrificial third-tier opening fill structures (348, 318, 368) may be coplanar with the top surface of the third-tier insulating cap layer 370. Each of the sacrificial third-tier opening fill structures may, or may not, include cavities therein. The set of all structures located between the bottommost surface of the third vertically alternating sequence (332, 342) and the topmost surface of the third vertically alternating sequence (332, 342) or embedded within the third vertically alternating sequence (332, 342) constitutes a third-tier structure. The sacrificial third-tier contact opening fill structures 368 may vertically extend from a horizontal plane including a top surface of the third-tier alternating stack (332, 342) at least to a horizontal plane including a bottom surface of the third-tier alternating stack (332, 342).

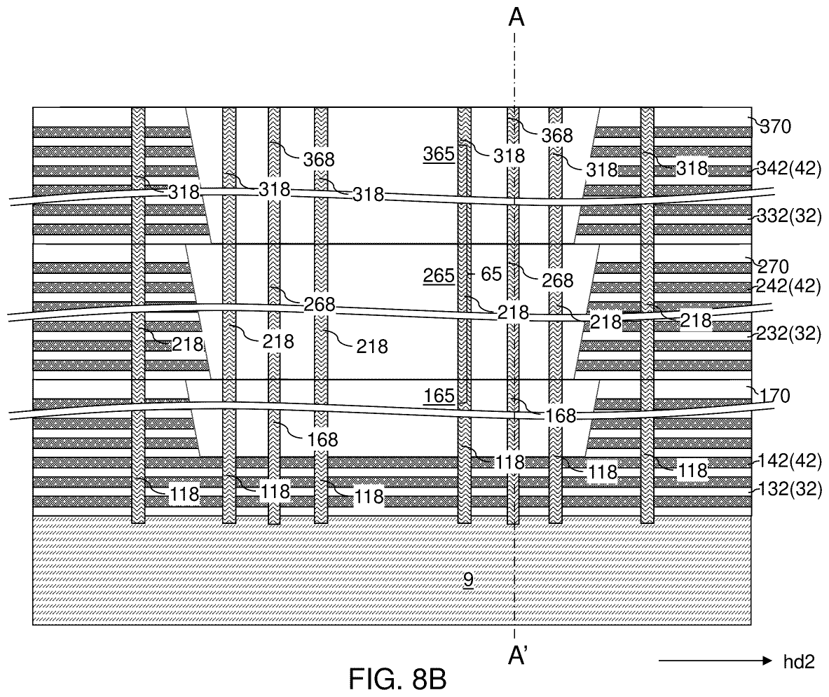

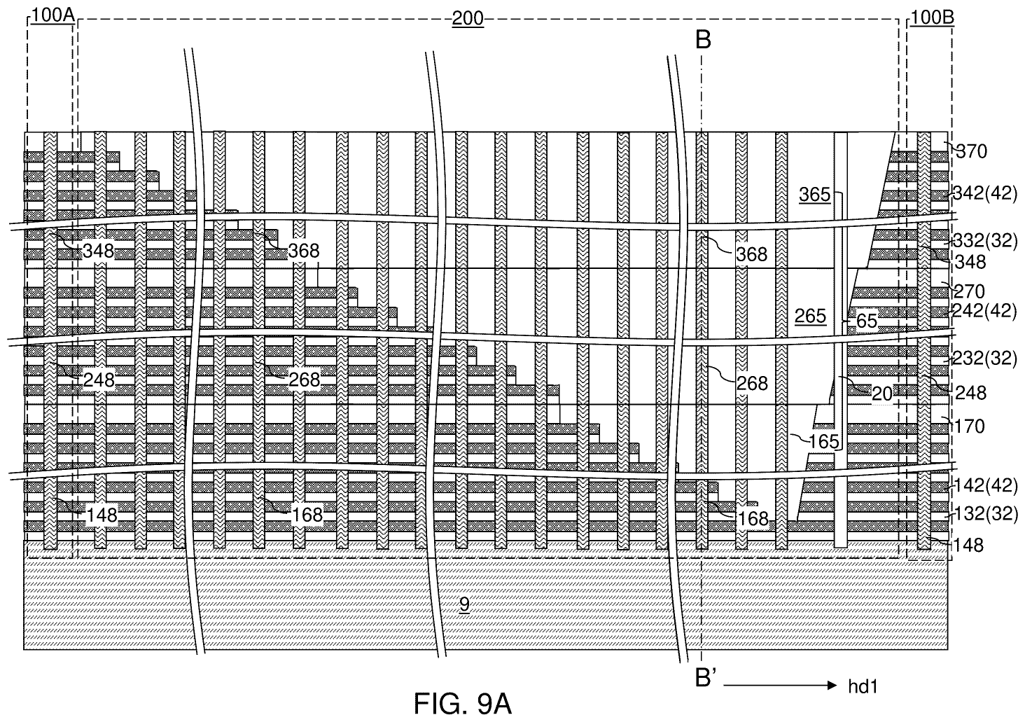

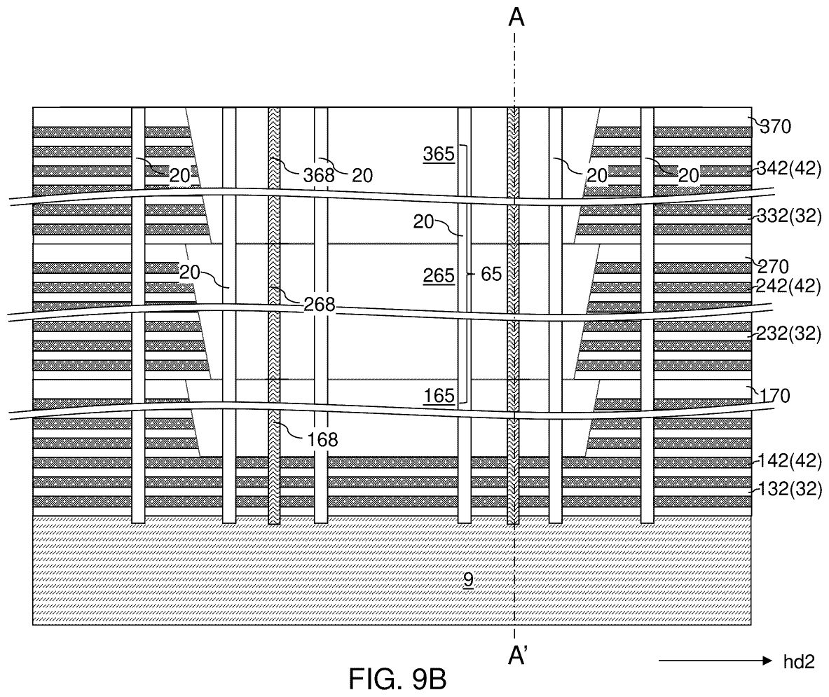

Referring to FIGS. 9A and 9B a photoresist layer (not shown) can be applied over the third-tier structure, and can be lithographically patterned to form openings over the areas of the sacrificial third-tier support opening fill structures 318. The sacrificial fill materials of the sacrificial third-tier support opening fill structures 318, the sacrificial second-tier support opening fill structures 218, and the sacrificial first-tier support opening fill structures 118 can be removed selectively to the materials of the retro-stepped dielectric material portions 65, the insulating layers 32, and the sacrificial material layers 42. Support pillar cavities can be formed in the volumes from which the materials of the sacrificial third-tier support opening fill structures 318, the sacrificial second-tier support opening fill structures 218, and the sacrificial first-tier support opening fill structures 118 are removed. The photoresist layer can be subsequently removed, for example, by ashing.

A dielectric fill material can be deposited in the support pillar cavities by performing a conformal deposition process. The dielectric fill material comprises a dielectric material that is different from the material of the sacrificial material layers 42. For example, the dielectric fill material may comprise undoped silicate glass or a doped silicate glass. Excess portions of the dielectric fill material can be removed from above the horizontal plane including the top surface of the topmost retro-stepped dielectric material portions 65 (such as the third-tier retro-stepped dielectric material portion 365). Each remaining portion of the dielectric fill material that fills a respective support pillar cavity constitutes a support pillar structure 20. The support pillar structures 20 can be formed in the inter-array region 200, and may vertically extend from the substrate 9 to a horizontal plane including the topmost surfaces of the retro-stepped dielectric material portions 65 and the third-tier insulating cap layer 370.

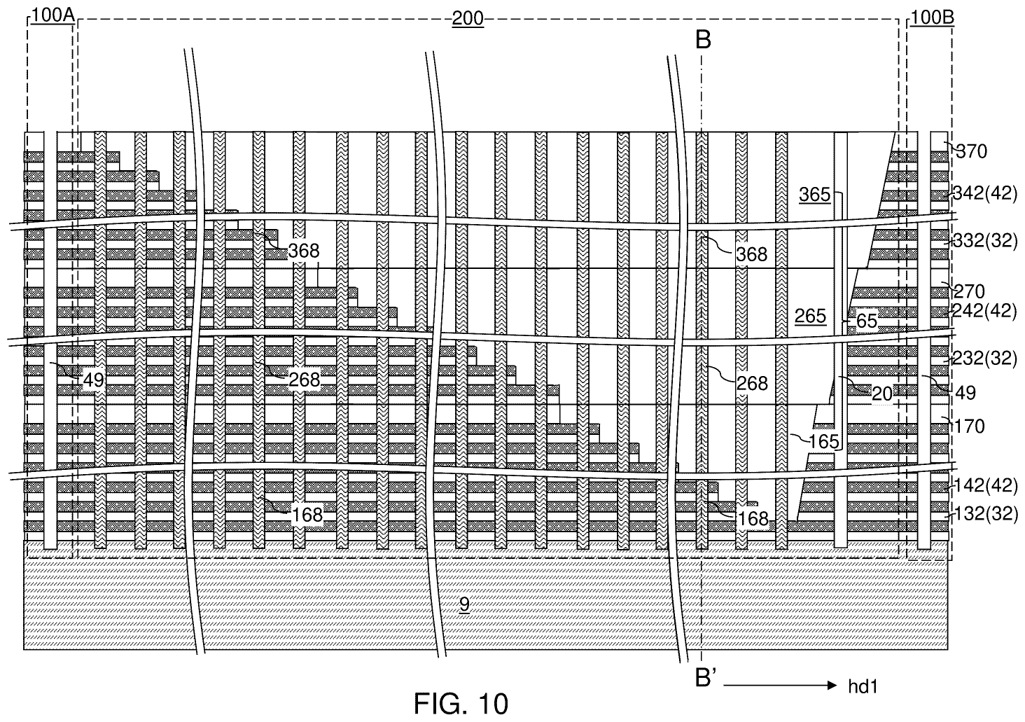

Referring to FIG. 10, a photoresist layer (not shown) can be applied over the third-tier structure, and can be lithographically patterned to cover the inter-array regions 200 without covering the memory array regions 100. The sacrificial fill materials of the sacrificial memory opening fill structures (148, 248, 348) can be removed selectively to the materials of the insulating layers 32, the sacrificial material layers 42, and the substrate 9. Memory openings 49 are formed in the voids from which the sacrificial fill materials of the sacrificial memory opening fill structures (148, 248, 348) are removed.

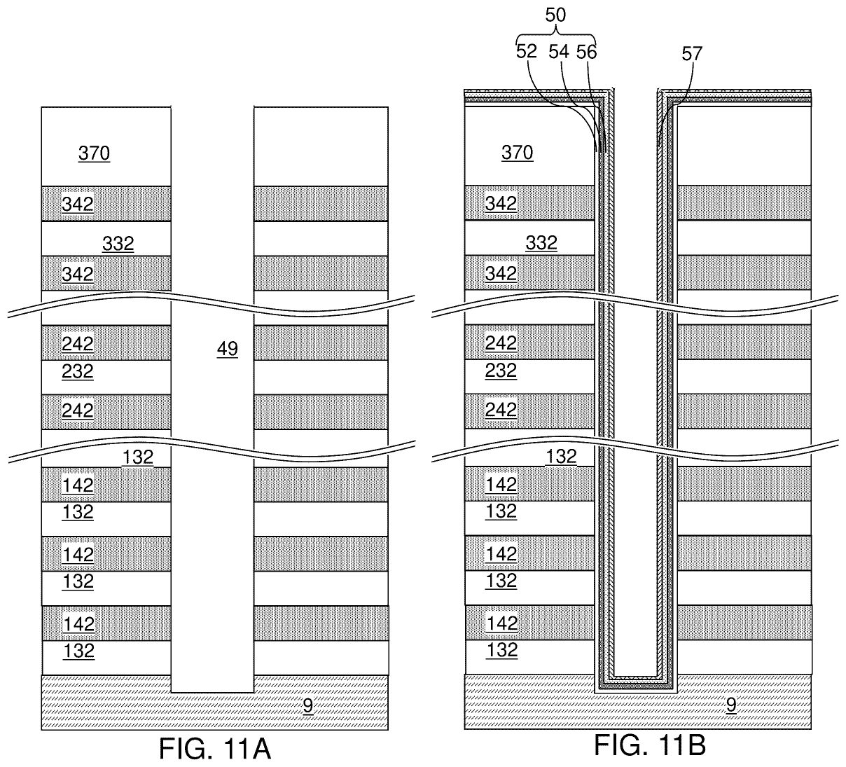

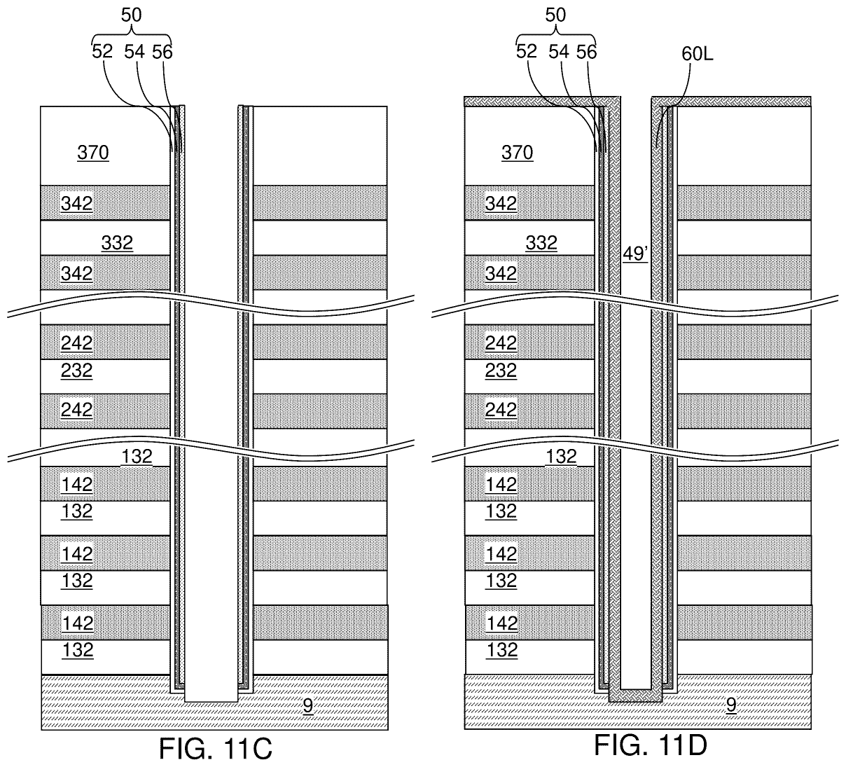

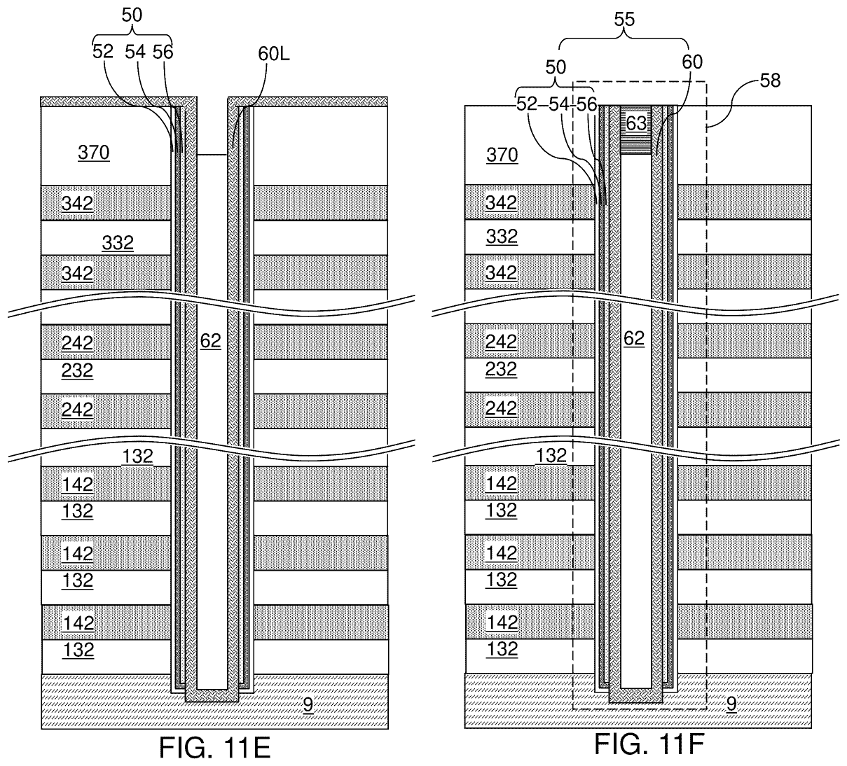

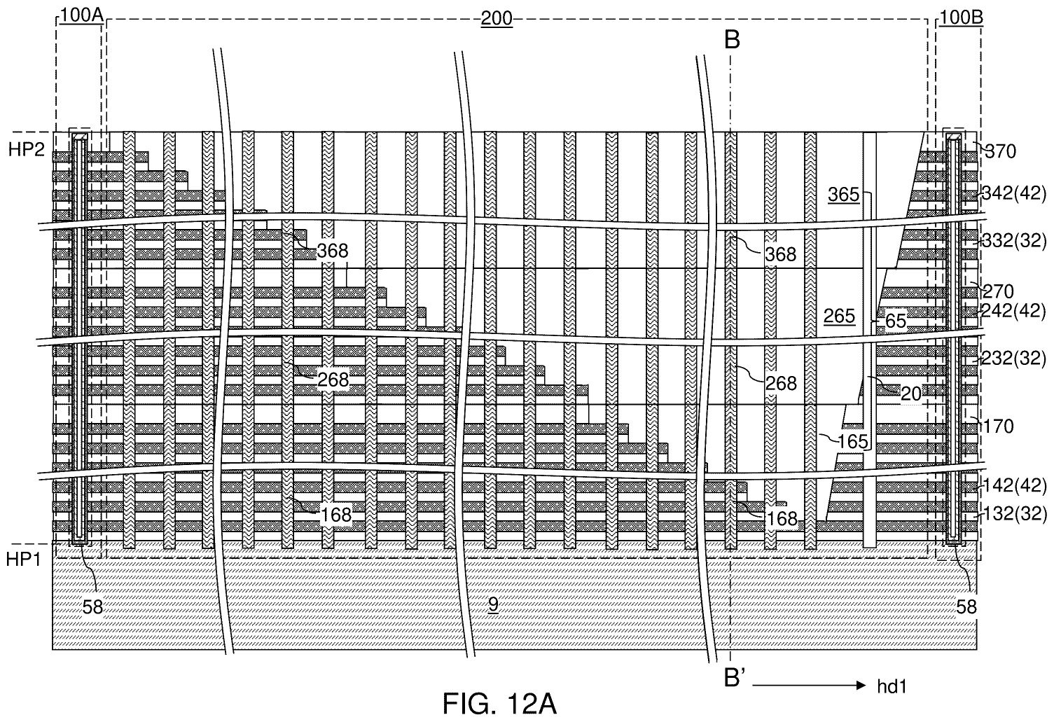

FIGS. 11A-11F illustrate sequential vertical cross-sectional views of a memory opening during formation of a memory opening fill structure according to the first embodiment of the present disclosure.

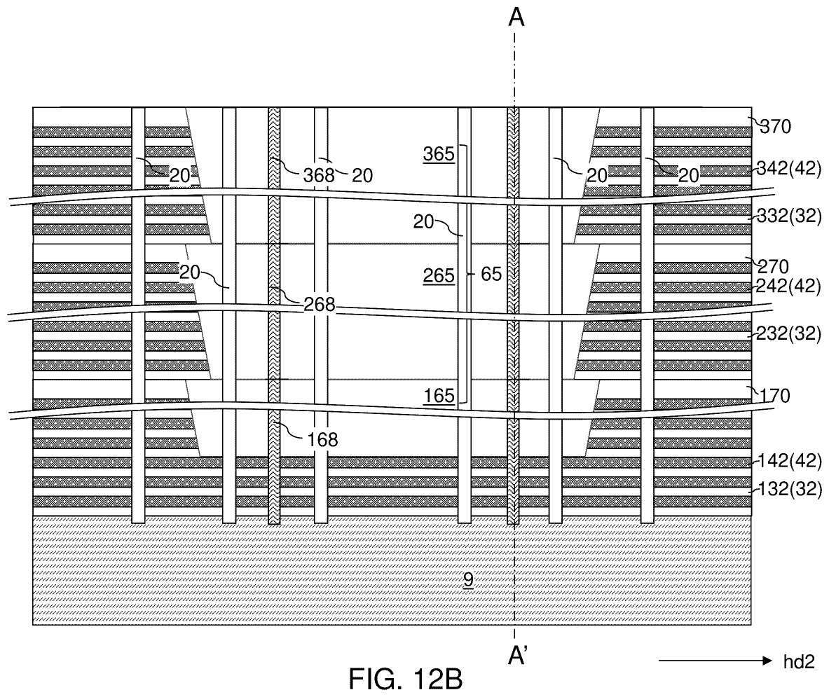

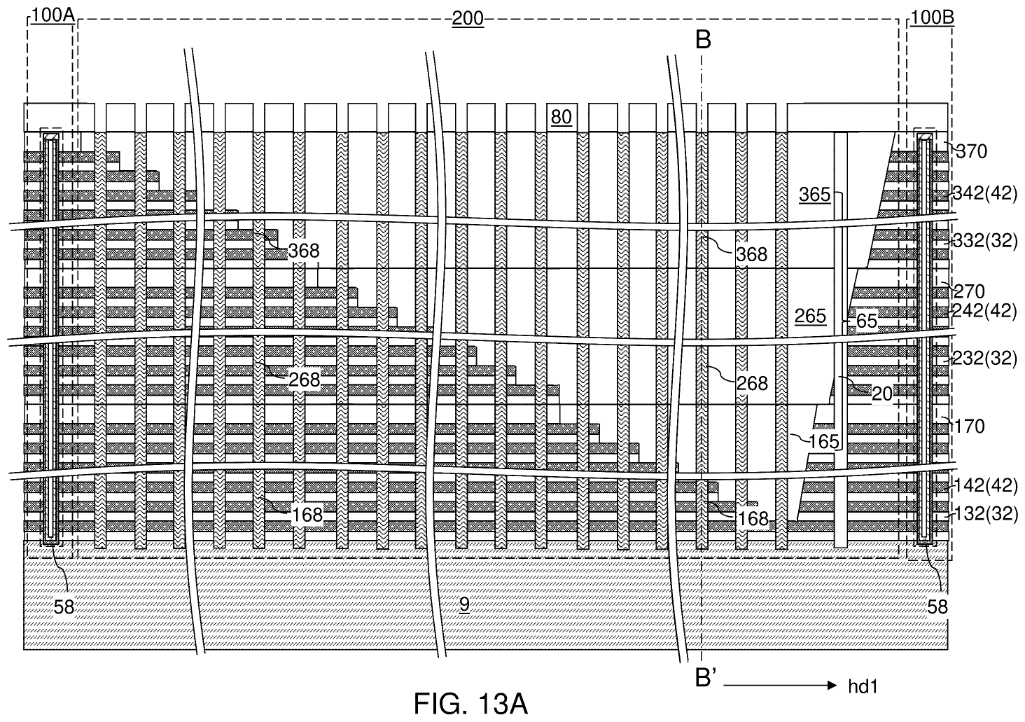

Referring to FIG. 11A, a memory opening 49 in the first exemplary structure of FIG. 12 is illustrated.

Referring to FIG. 11B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selectively to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 11C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selectively to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 11D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 11E, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 11F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions 100 of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

Referring to FIGS. 12A and 12B, the first exemplary structure is illustrated after the processing steps of FIG. 11F, i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the electrically conductive layers 46 within the plurality of tier structures, and further comprises a respective vertical semiconductor channel 60 that vertically extends through the plurality of tier structures. Each memory opening fill structure 58 vertically extends from below a first horizontal plane HP1 including a bottommost surface of the at least one alternating stack (32, 42) to a second horizontal plane HP2 including the top surfaces of the memory opening fill structures 58.

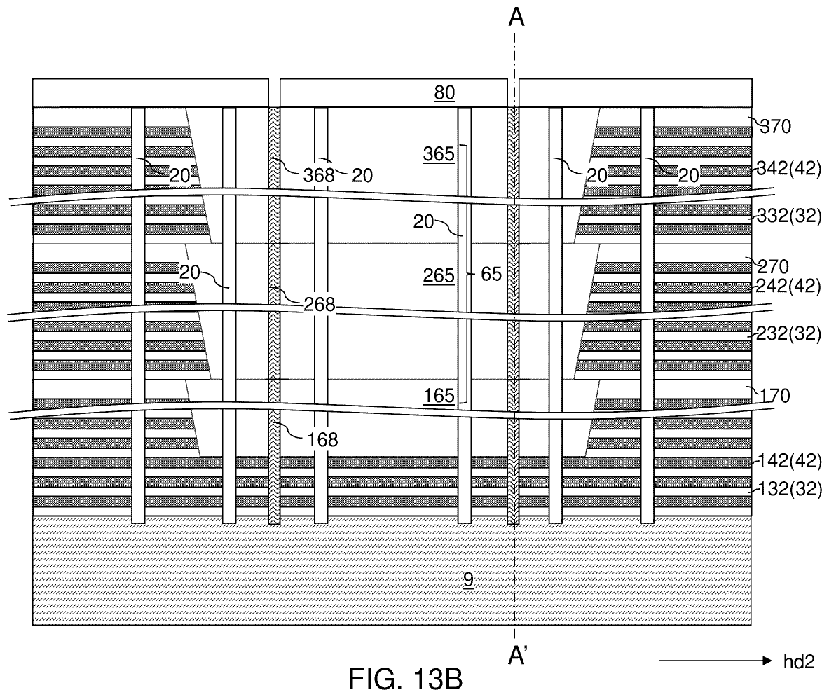

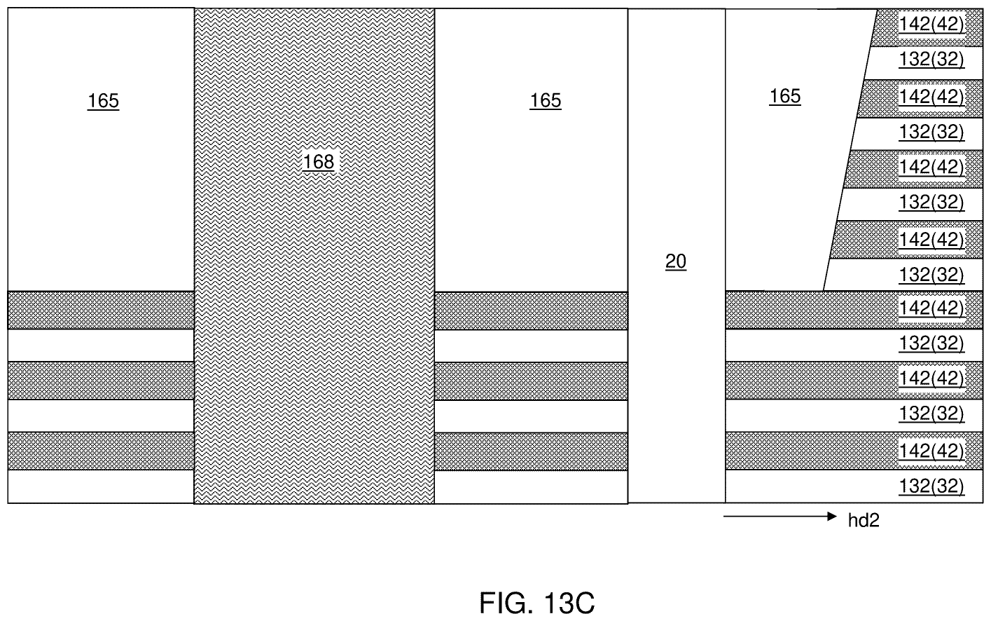

Referring to FIGS. 13A-13C, a contact-level dielectric layer 80 can be deposited over the third-tier insulating cap layer 370 and the third-tier retro-stepped dielectric material portions 365. The contact-level dielectric layer 80 comprises a dielectric material such as silicon oxide, and may have a thickness in a range from 100 nm to 800 nm, although lesser and greater thicknesses may also be employed.

Connection via openings can be formed through the contact-level dielectric layer 80 over the sacrificial third-tier contact opening fill structures 368. For example, a photoresist layer (not shown) can be applied over the contact-level dielectric layer 80, and can be lithographically patterned to form openings within the areas of the sacrificial third-tier contact opening fill structures 368. An anisotropic etch process can be performed to transfer the pattern of the openings in the photoresist layer through the contact-level dielectric layer 80. The photoresist layer may be subsequently removed, for example, by ashing.

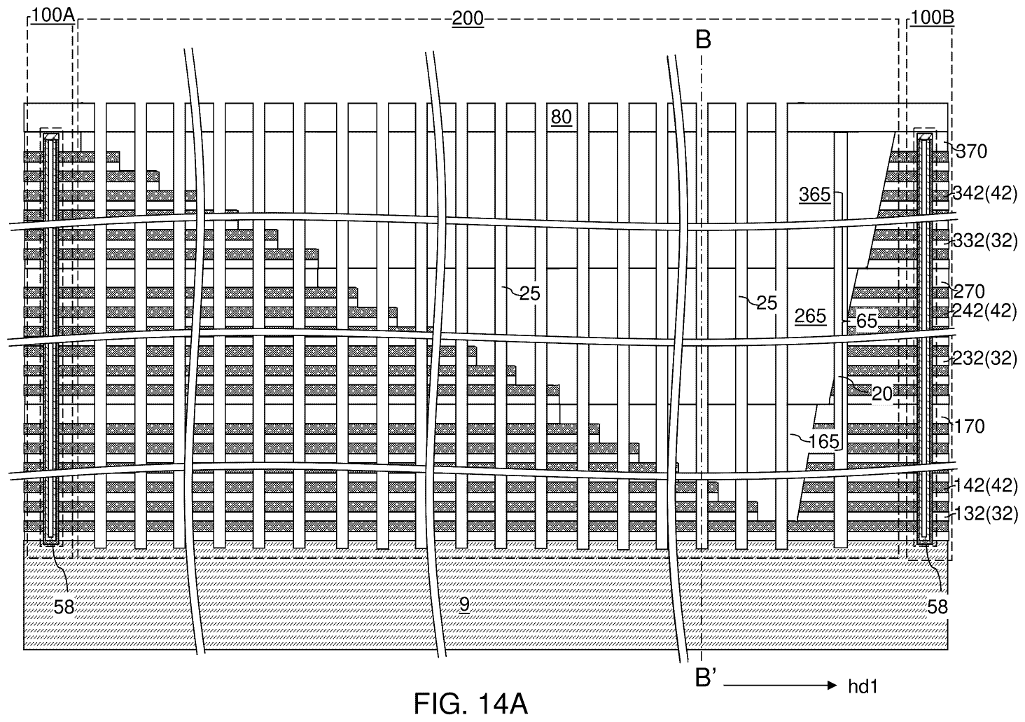

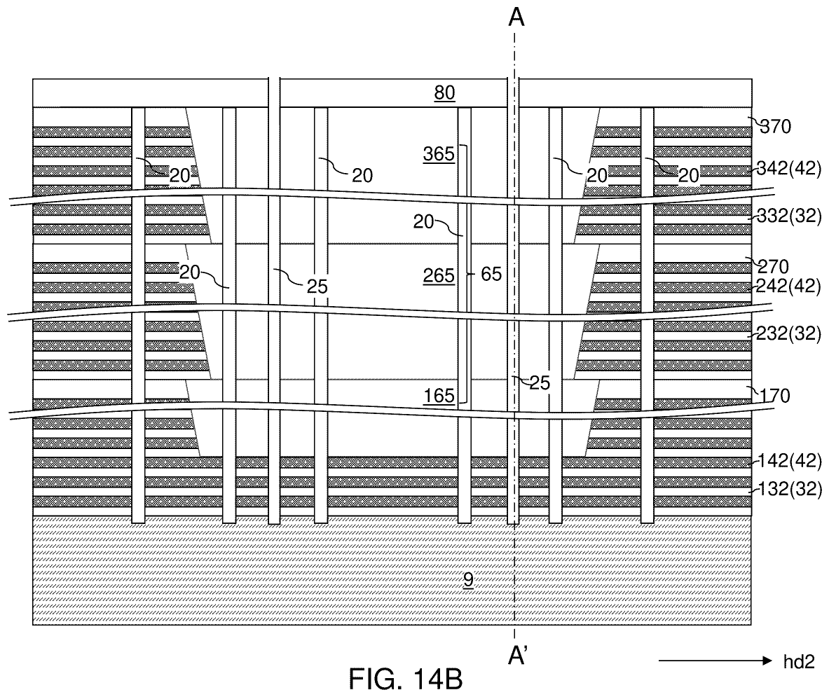

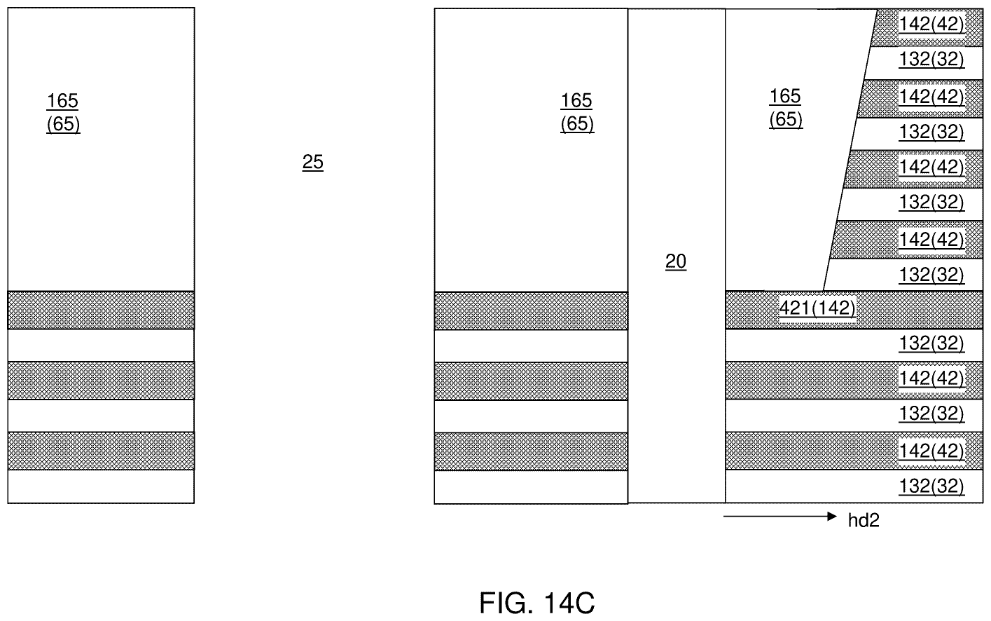

Referring to FIGS. 14A-14C, the sacrificial fill materials of the sacrificial third-tier contact opening fill structures 368, the sacrificial second-tier contact opening fill structures 268, and the sacrificial first-tier contact opening fill structures 168 can be removed selectively to the materials of the retro-stepped dielectric material portions 65, the insulating layers 32, the sacrificial material layers 42, and the support pillar structures 20. Contact via openings 25 are formed in the volumes from which the materials of the sacrificial third-tier contact opening fill structures 368, the sacrificial second-tier contact opening fill structures 268, and the sacrificial first-tier contact opening fill structures 168 are removed. Each contact via opening 25 vertically extends from the horizontal plane including the planar top surfaces of the third-tier retro-stepped dielectric material portion 365 to the substrate 9. Each contact via opening 25 may vertically extend through a respective set of at least one insulating layer 32 and a respective set of at least one sacrificial material layer 42 of an alternating stack of insulating layers 32 and sacrificial material layers 42. Each contact via opening 25 may have a width (e.g., diameter) in a range from 100 nm to 400 nm, although lesser and greater widths may also be employed.

Each contact via opening 25 vertically extends through at least one retro-stepped dielectric material portion 65 and a subset of the sacrificial material layers 42 within the alternating stack (32, 42). As shown in FIG. 14C, the subset of the sacrificial material layers 42 comprises a first sacrificial material layer 421 which is a topmost sacrificial material layer 42 of the subset of the sacrificial material layers 42 and further comprises at least one second sacrificial material layer 42 (which may be a plurality of second sacrificial material layers 42) that underlie the first sacrificial material layer 421. Each contact via opening 25 can be formed through at least one retro-stepped dielectric material portion 65 (e.g., 165, 265, and/or 365), a respective subset of the sacrificial material layers 42 within an alternating stack (32, 42), and a respective subset of the insulating layers 32 within the alternating stack (32, 42). For each contact via opening 25 vertically extending through a respective subset of the sacrificial material layers 42, a topmost layer within the subset of the sacrificial material layers 42 is herein referred to as the first sacrificial material layer 421.

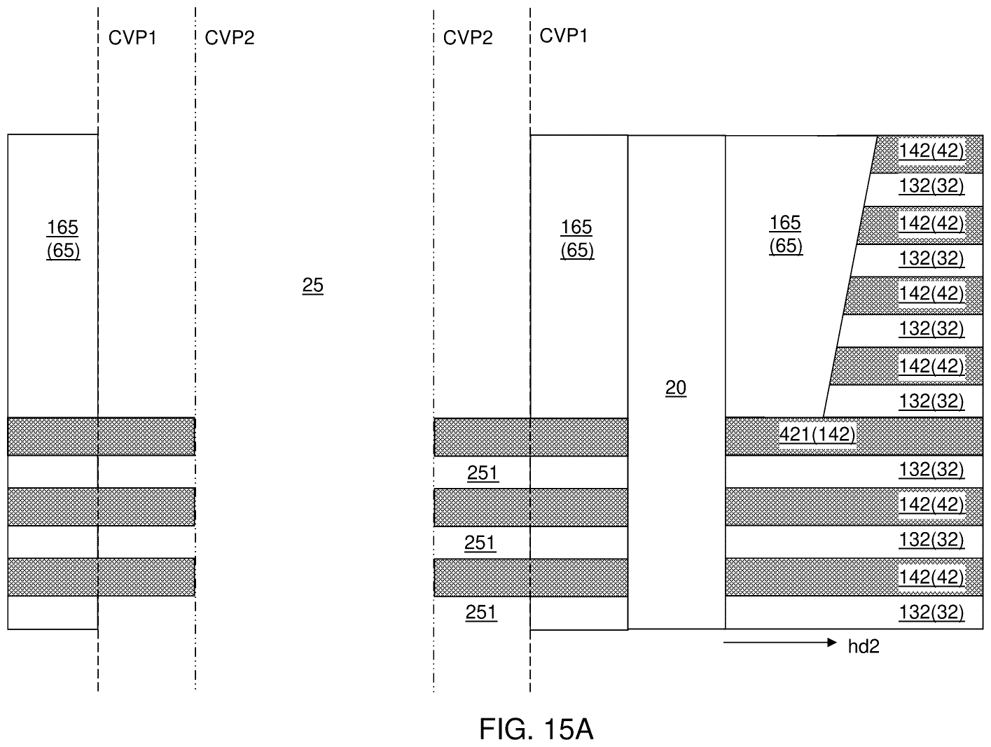

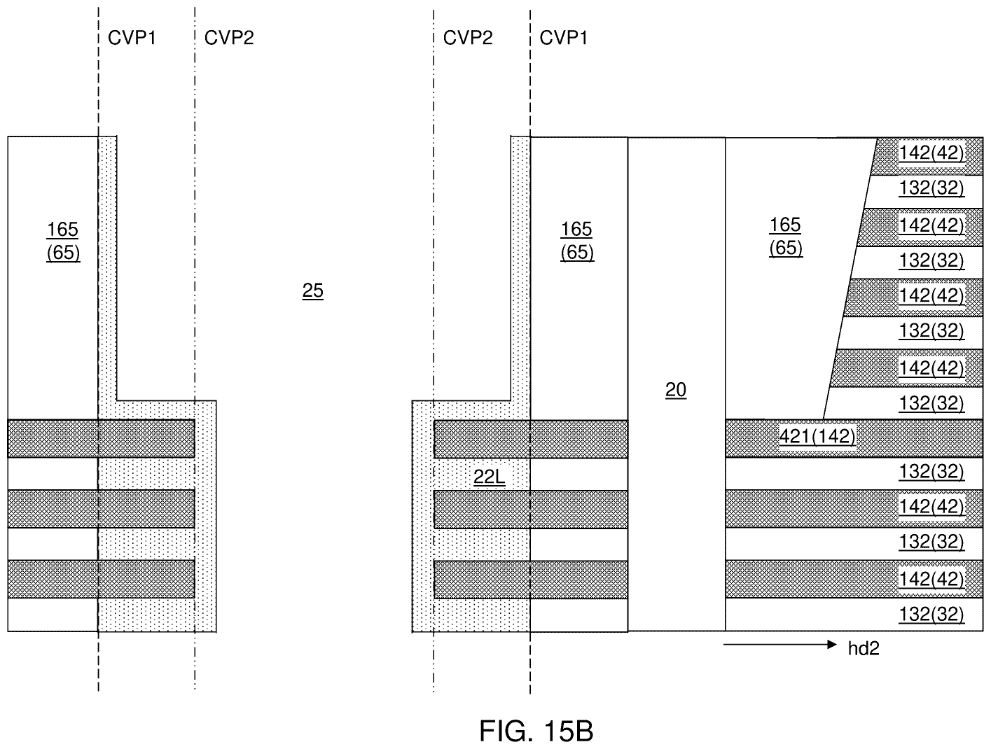

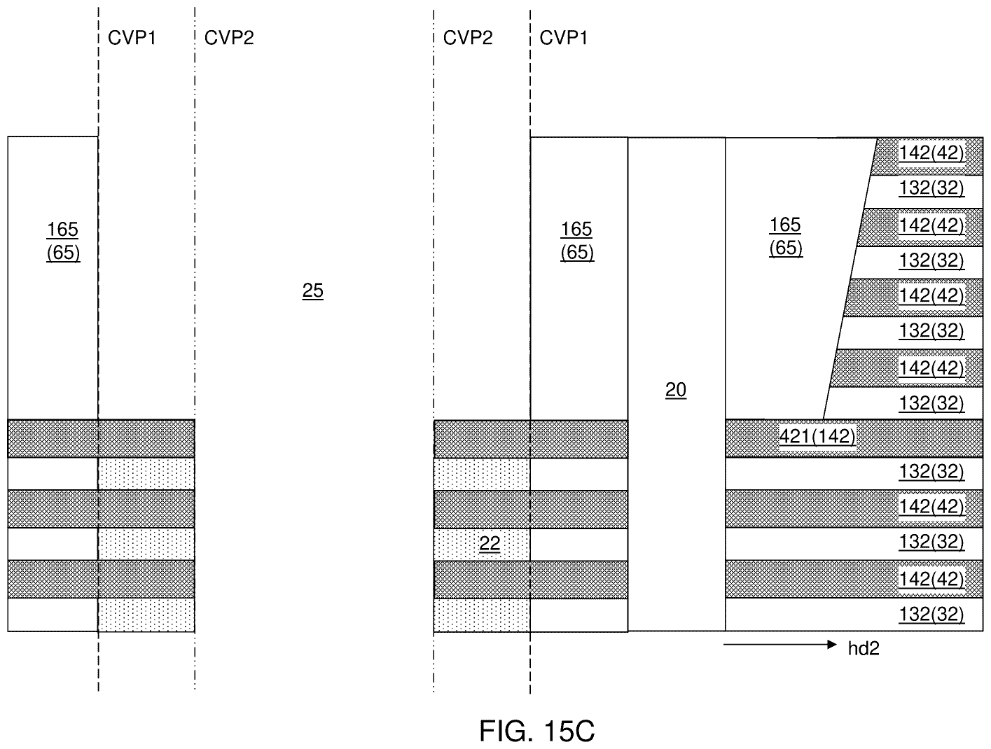

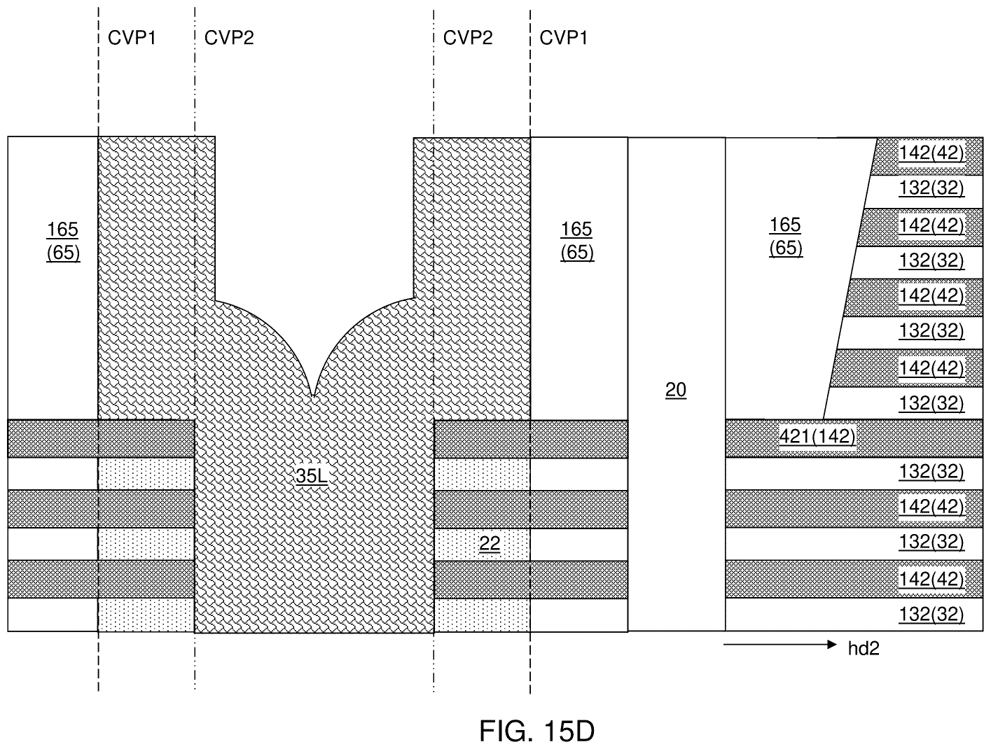

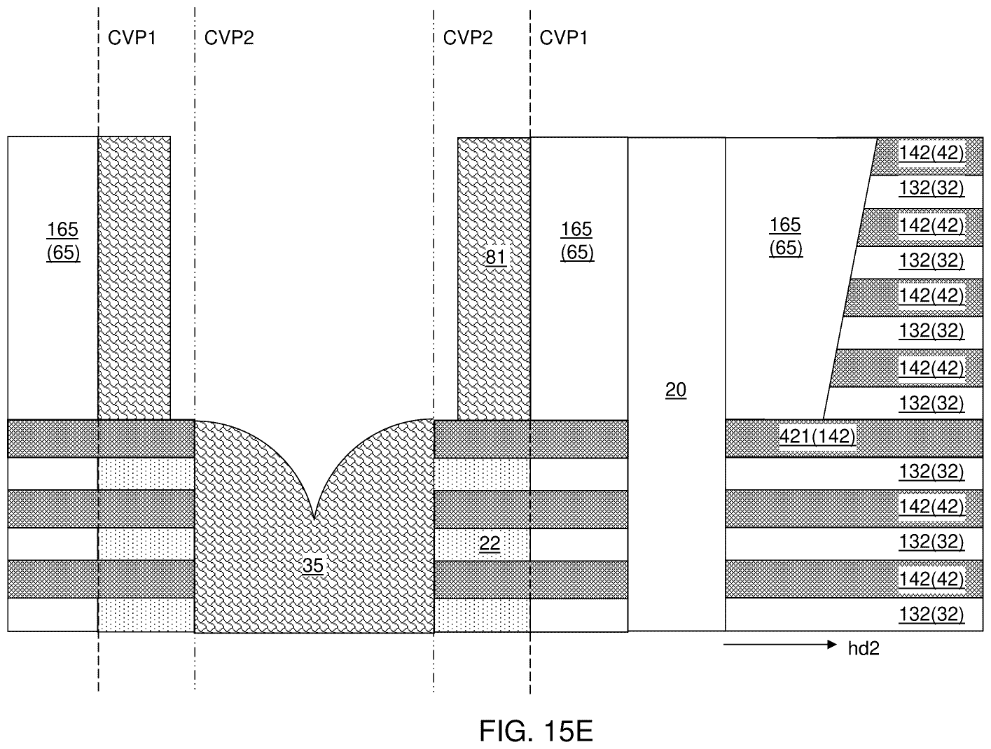

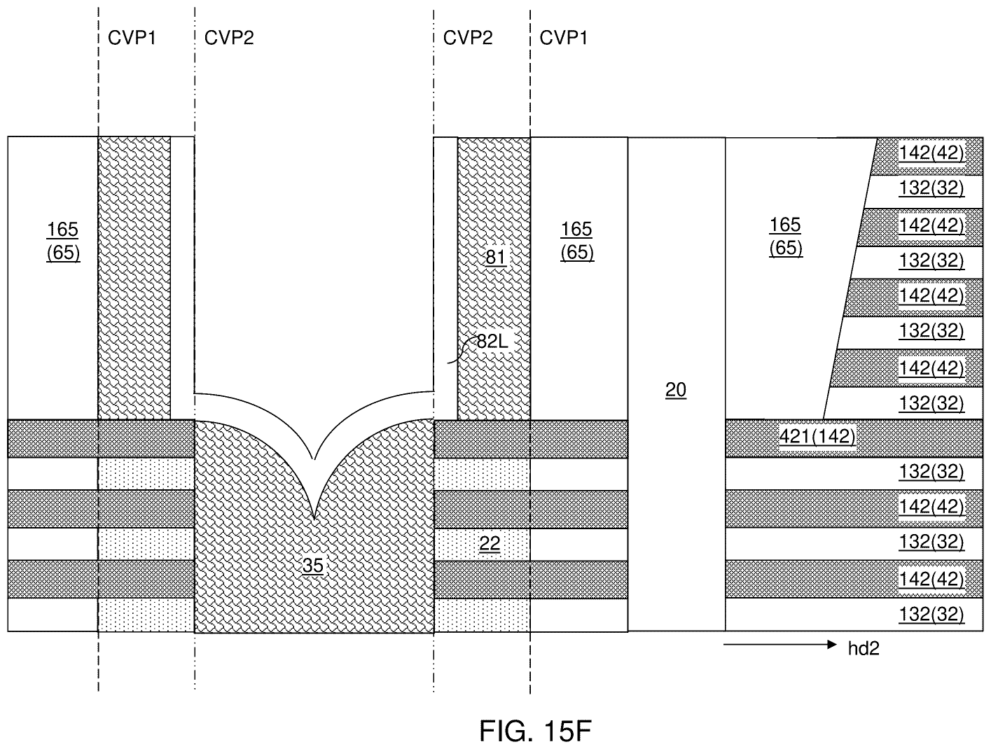

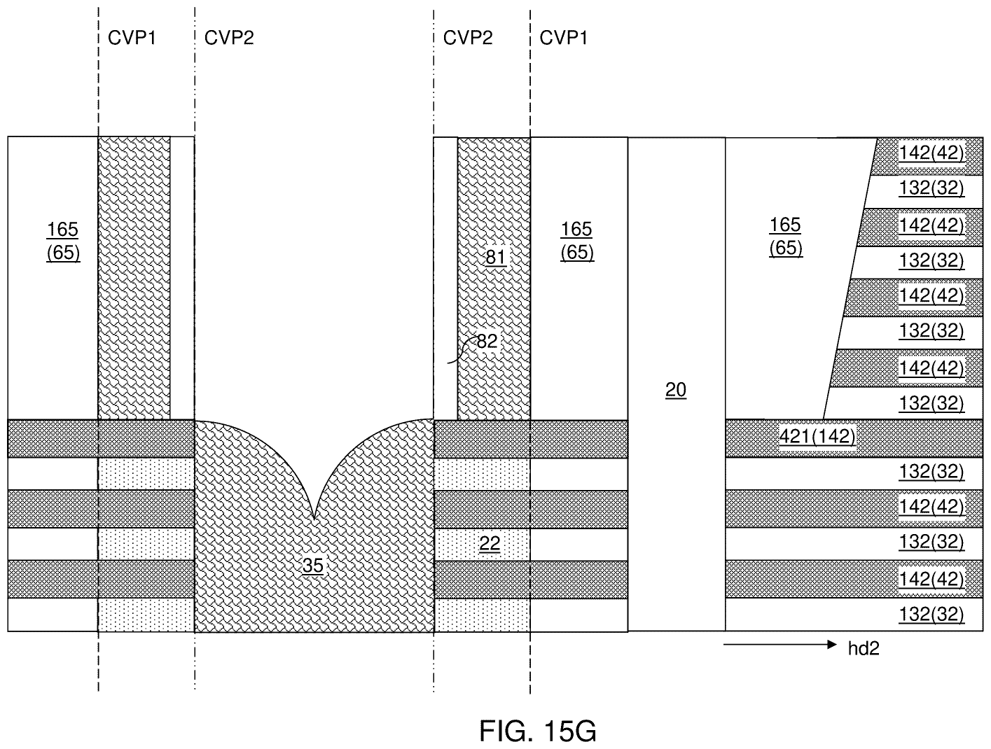

FIGS. 15A-15G are sequential vertical cross-sectional views of a region around a contact via opening 25 in the first exemplary structure during a sequence of processing steps for formation of various structural elements therein according to the first embodiment of the present disclosure.

Referring to FIG. 15A, an isotropic etch process can be performed to laterally recess the sidewalls of the at least one retro-stepped dielectric material portion 65 around the contact via openings 25. For example, the at least one retro-stepped dielectric material portion 65 may comprise a silicate glass material (i.e., silicon oxide), and the isotropic etch process may comprise a wet etch process employing dilute hydrofluoric acid. In one embodiment, the isotropic etch process may collaterally etch portions of the insulating layers 32 that are proximal to the contact via openings 25. In one embodiment, the isotropic etch process forms a vertical stack of annular cavities 251 by laterally recessing the subset of the insulating layers 32 around the contact via opening 25. Each laterally recessed sidewall of the at least one retro-stepped dielectric material portion 65 may be formed in a respective first cylindrical vertical plane CVP1, which is a vertical plane having a lateral curvature such that a horizontal cross-sectional shape of the vertical plane is a circle. In one embodiment, the insulating layers 32 and the at least one retro-stepped dielectric material portion 65 may comprise a same material (such as undoped silicate glass or a doped silicate glass), and a first cylindrical vertical plane CVP1 may contain a cylindrical sidewall of the at least one retro-stepped dielectric material portion 65 and each cylindrical sidewall of underlying insulating layers 32 around a respective contact via opening 25. Unrecessed cylindrical sidewalls of the subset of the sacrificial material layers 42 around the respective contact via opening 25 may be formed within a respective second cylindrical vertical plane CVP2, which may be laterally offset inward relative to the first cylindrical vertical plane CVP1 by the etch distance of the isotropic etch process. In one embodiment, the etch distance of the isotropic etch process may be in a range from 40 nm to 200 nm, such as 50 nm to 75 nm, although lesser and greater etch distances may also be employed.

Referring to FIG. 15B, a dielectric spacer material layer 22L can be conformally deposited in the annular cavities 251 and in peripheral regions of the contact via openings 25. The dielectric spacer material layer 22L comprises a dielectric material that is different from the material of the sacrificial material layers 42. For example, the dielectric spacer material layer 22L may comprise undoped silicate glass, a doped silicate glass, silicon oxynitride, silicon oxycarbide, a dielectric metal oxide, etc. The dielectric spacer material layer 22L can be deposited by a conformal deposition process, such as a chemical vapor deposition process or an atomic layer deposition process. The thickness of the dielectric spacer material layer 22L may be greater than one half of the height of each annular cavity 251. The annular cavities 251 can be filled within the material of the dielectric spacer material layer 22L.

Referring to FIG. 15C, a recess etch process can be performed to isotropically or anisotropically recess the material of the dielectric spacer material layer 22L. The duration of the recess etch process may be selected such that the etch distance of the recess etch process for the material of the dielectric spacer material layer 22L is in a range from 100% to 150% of the thickness of the dielectric spacer material layer 22L on sidewalls of the at least one retro-stepped dielectric material portion 65. The recess etch process can remove portions of the dielectric spacer material layer 22L located outside the annular cavities 251. Remaining portions of the dielectric spacer material layer 22L located in the annular cavities 251 constitute annular dielectric spacers 22. For each contact via opening 25 that is laterally surrounded by more than one insulating layer 32, a vertical stack of annular dielectric spacers 22 can be formed in the vertical stack of annular cavities 251 that surrounds the contact via opening 25.

Each contact via opening 25 is laterally surrounded by a set of at least one sacrificial material layer 42. As noted above, the topmost sacrificial material layer 42 within the set of at least one sacrificial material layer 42 is herein referred to as the first sacrificial material layer 421. For each contact via opening 25 that is laterally surrounded by more than one insulating layer 32, a vertical stack of annular dielectric spacers 22 can be formed at levels of a subset of the insulating layers 32 that underlie the first sacrificial material layer 421. Each annular dielectric spacer 22 within the vertical stack of annular dielectric spacers 22 comprise an outer cylindrical sidewall in contact with a cylindrical surface of a respective one of the insulating layers 32. If the at least one retro-stepped dielectric material portion 65 and the insulating layers 32 have a same etch rate under the recess etch process, a recessed cylindrical sidewall of the at least one retro-stepped dielectric material portion 65 and outer sidewalls of underlying annular dielectric spacers 22 may be formed within a same cylindrical vertical plane (such as a first cylindrical vertical plane CVP1).

Referring to FIG. 15D, a sacrificial fill material layer 35L can be conformally deposited in the contact via openings 25 after forming the vertical stack of annular dielectric spacers 22. The thickness of the sacrificial fill material layer 35L can be selected such that a lower portion of each contact via opening 25 located below a respective horizontal plane including a top surface of a respective first sacrificial material layer 421 is filled within the sacrificial fill material layer 35L, while an upper portion of each contact via opening 25 located above the respective horizontal plane comprises a void that is not filled with the sacrificial fill material layer 35L. The sacrificial fill material layer 35L comprises a material that is different from the materials of the insulating layers 32 and the sacrificial material layers 42. For example, the sacrificial fill material layer 35L may comprise a semiconductor material, such as amorphous silicon or silicon-germanium, a carbon-based material, such as amorphous carbon or diamond-like carbon, a polymer material, or a porous material. such as organosilicate glass.

Referring to FIG. 15E, the sacrificial fill material layer 35L can be etched employing a recess etch process, such that a vertical recess distance for the sacrificial fill material layer 35L is greater than a lateral recess distance for the sacrificial fill material layer 35L. The recess etch process can be an isotropic etch process, an anisotropic etch process, or a combination thereof. The isotropic etch process may be performed prior to or after the anisotropic etch process. The etch distance of the isotropic etch distance is less than the thickness of the sacrificial fill material layer 35L on the cylindrical sidewalls of the at least one retro-stepped dielectric material portion 65 such that the cylindrical sidewalls of the at least one retro-stepped dielectric material portion 65 are covered with remaining portions of the sacrificial fill material layer 35L after the isotropic etch process. The anisotropic etch process may comprise a reactive ion etch process, and removes horizontally-extending portions of the sacrificial fill material layer 35L. The duration of the anisotropic etch process can be selected such that the vertical etch distance of the anisotropic etch process for the sacrificial fill material layer 35L is greater than the difference between the thickness of the sacrificial fill material layer 35L over the sidewalls of the at least one retro-stepped dielectric material portion 65 and the etch distance of the isotropic etch process for the sacrificial fill material layer 35L. In one embodiment, an annular top surface segment of a respective first sacrificial material layer 421 can be physically exposed within each contact via opening 25 after performing the combination of the isotropic etch process and the anisotropic etch process.

A first remaining portion of the sacrificial fill material layer 35L that remains within an upper portion of each contact via opening 25 comprises a sacrificial tubular structure 81. Each sacrificial tubular structure 81 may be formed in a peripheral region of a respective contact via opening 25 on a laterally recessed sidewall of the at least one retro-stepped dielectric material portion 65. A second remaining portion of the sacrificial fill material layer 35L that remains within a lower portion of each contact via opening 25 comprises a sacrificial fill material portion 35. The sacrificial fill material portion 35 can be located below a horizontal plane including the top surface of the first sacrificial material layer 421 for the contact via opening 25.

In one embodiment, each sacrificial tubular structure 81 may have an outer cylindrical sidewall located within a first cylindrical vertical plane CVP1, and an inner cylindrical sidewall located between the first cylindrical vertical plane CVP1 and a second cylindrical vertical plane CVP2 that contains a cylindrical sidewall of each underlying sacrificial material layer 42. The lateral thickness of each sacrificial tubular structure 81 (i.e., the distance between an outer sidewall and an inner sidewall) may be in a range from 30 nm to 150 nm, although lesser and greater lateral thicknesses may also be employed. In one embodiment, each sacrificial fill material portion 35 may comprise cylindrical surface segments contacting a cylindrical sidewall of each sacrificial material layer 42 located around the contact via opening 25 and located within the second cylindrical vertical plane CVP2.

In one embodiment, each sacrificial fill material portion 35 may comprise a contoured top surface. In one embodiment, a center point of the contoured top surface may be a lowest point of the contoured top surface, and the vertical distance between any arbitrarily selected point on the contoured top surface and a horizontal plane including a bottommost surface of the alternating stack (32, 42) increases with a radial distance from the center point to the arbitrarily selected point.

Referring to FIG. 15F, a conformal dielectric spacer material layer 82L can be formed on the physically exposed surfaces of the sacrificial fill material portion 35 and the sacrificial tubular structures 81. The conformal dielectric spacer material layer 82L comprises a dielectric material that is different from the material of the sacrificial material layers 42. In one embodiment, the conformal dielectric spacer material layer 82L comprises undoped silicate glass (i.e., silicon oxide) or a doped silicate glass. The conformal dielectric spacer material layer 82L may be formed by conformal deposition of a dielectric material layer. Alternatively, if the sacrificial fill material layer 35L comprises a semiconductor material such as silicon or silicon-germanium, the conformal dielectric spacer material layer 82L may be formed by by oxidation of surface portions of the sacrificial fill material portion 35 and the sacrificial tubular structures 81. The thickness of the conformal dielectric spacer material layer 82L may be in a range from 10 nm to 50 nm, although lesser and greater thicknesses may also be employed.

Referring to FIG. 15G, an anisotropic sidewall spacer etch process can be performed to remove horizontally-extending portions of the conformal dielectric spacer material layer 82L. A top surface of each sacrificial fill material portion 35 can be physically exposed. Each remaining cylindrical portion of the conformal dielectric spacer material layer 82L comprises a tubular dielectric spacer 82. Each tubular dielectric spacer 82 may be formed by deposition of a dielectric material on a sacrificial tubular structure 81, or by conversion of a surface portion of a sacrificial tubular structure 81 around an inner cylindrical sidewall of the sacrificial tubular structure 81 into a tubular oxide portion (such as a tubular silicon oxide portion). Each tubular dielectric spacer 82 is laterally surrounded by a sacrificial tubular structure 81 and overlying a respective first sacrificial material layer 421.

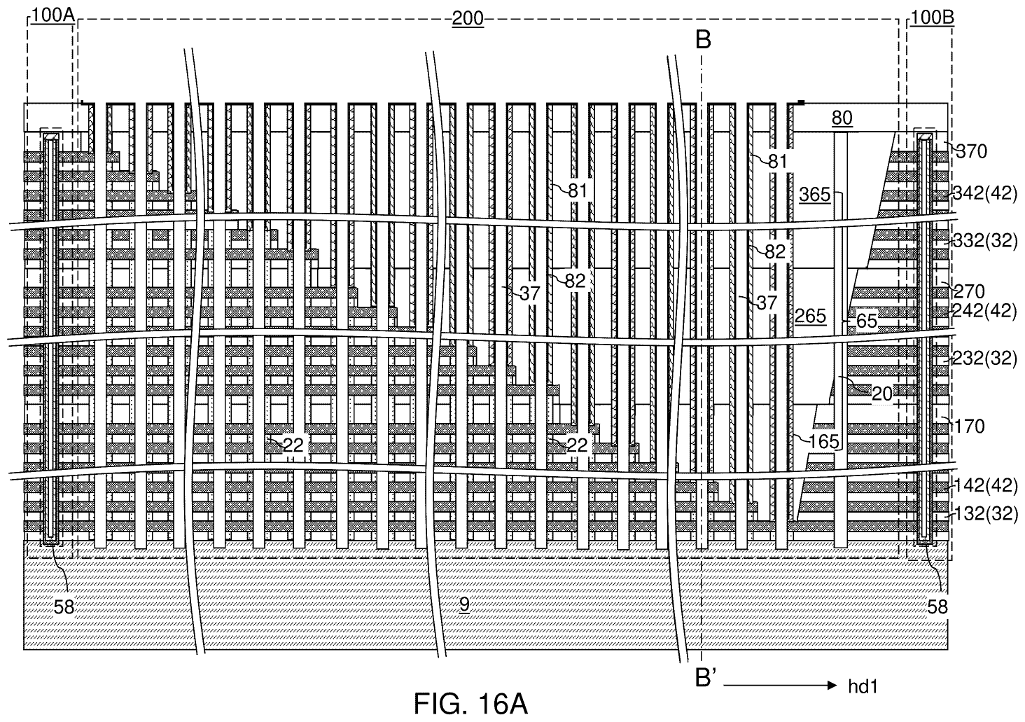

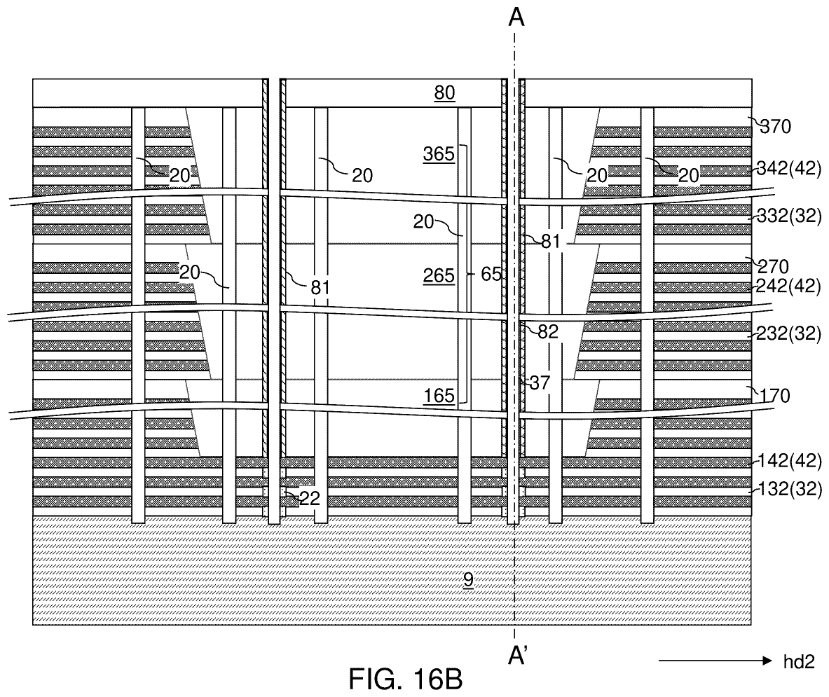

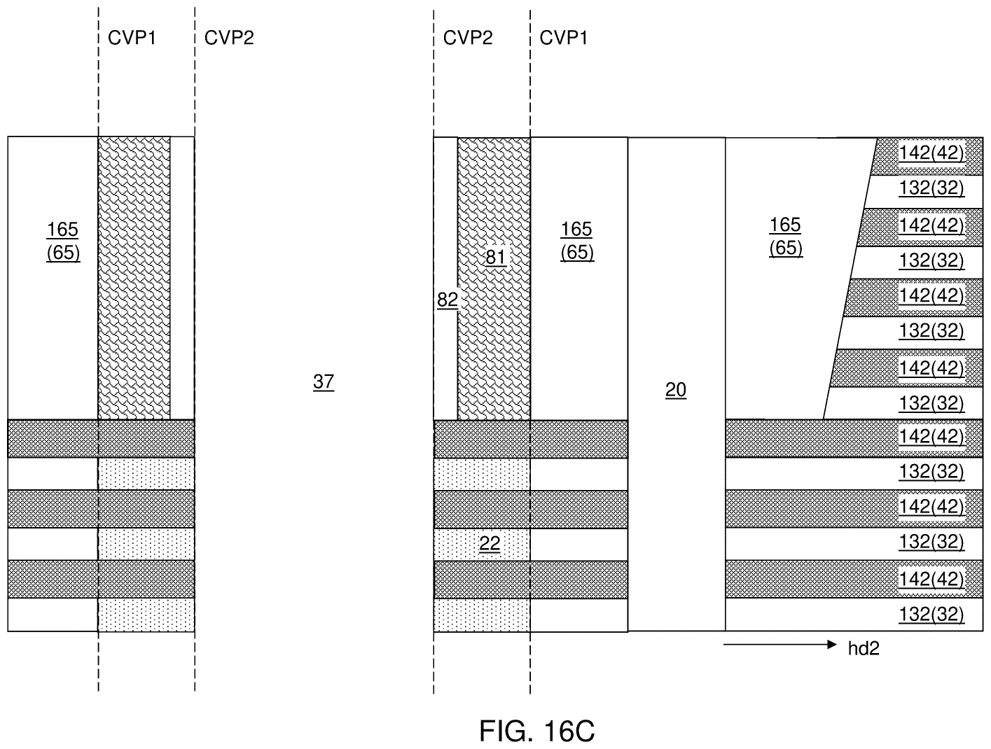

Referring to FIGS. 16A-16C, a selective removal process can be performed to remove the sacrificial fill material portions 35 from bottom regions of the contact via openings 25 without removing the tubular dielectric spacers 82 or the sacrificial tubular structures 81. For example, if the sacrificial fill material portions 35 comprise a semiconductor material, such as amorphous silicon, a wet etch process using hot trimethyl-2 hydroxyethyl ammonium hydroxide (“hot TMY”) or tetramethyl ammonium hydroxide (TMAH) may be performed to etch the sacrificial fill material portions 35 without removing the tubular dielectric spacers 82. The sidewalls of the sacrificial tubular structures 81 are covered by the tubular dielectric spacers 82, and thus, are not removed during the selective removal process. The top surfaces of the sacrificial tubular structures 81 may be covered by byproducts (e.g., residue) of reactive ion etching of the conformal dielectric spacer material layer 82L and/or by an additional photoresist mask.

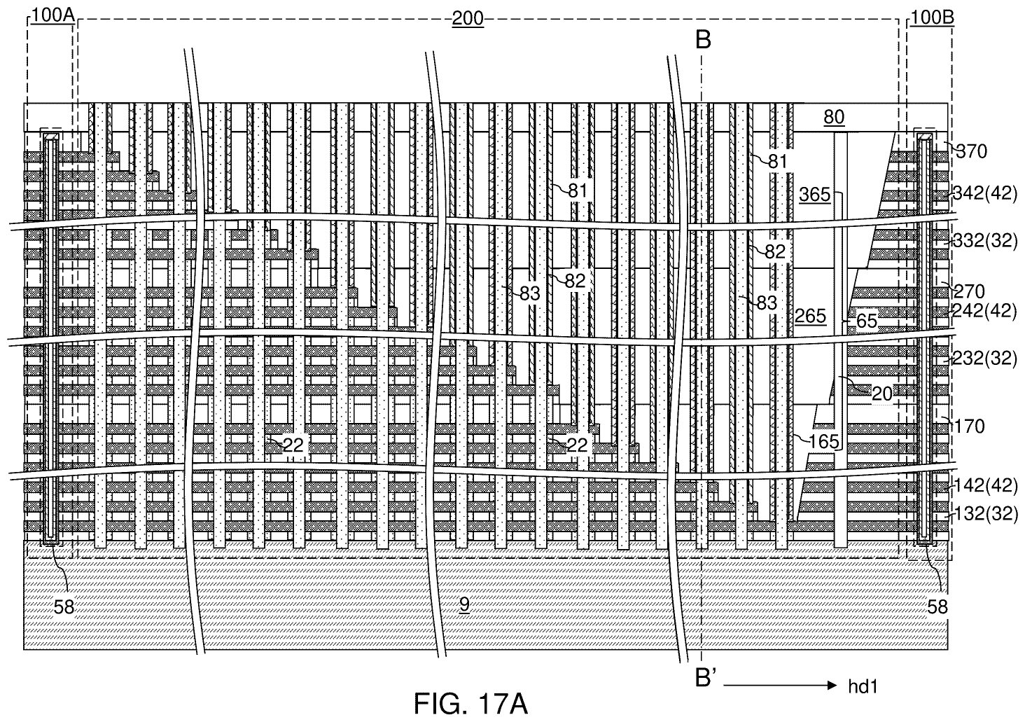

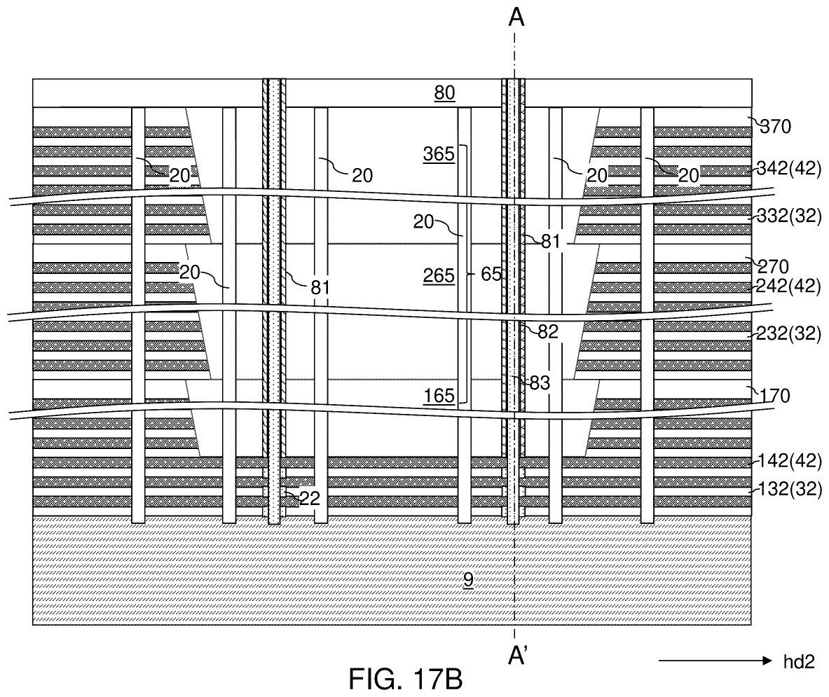

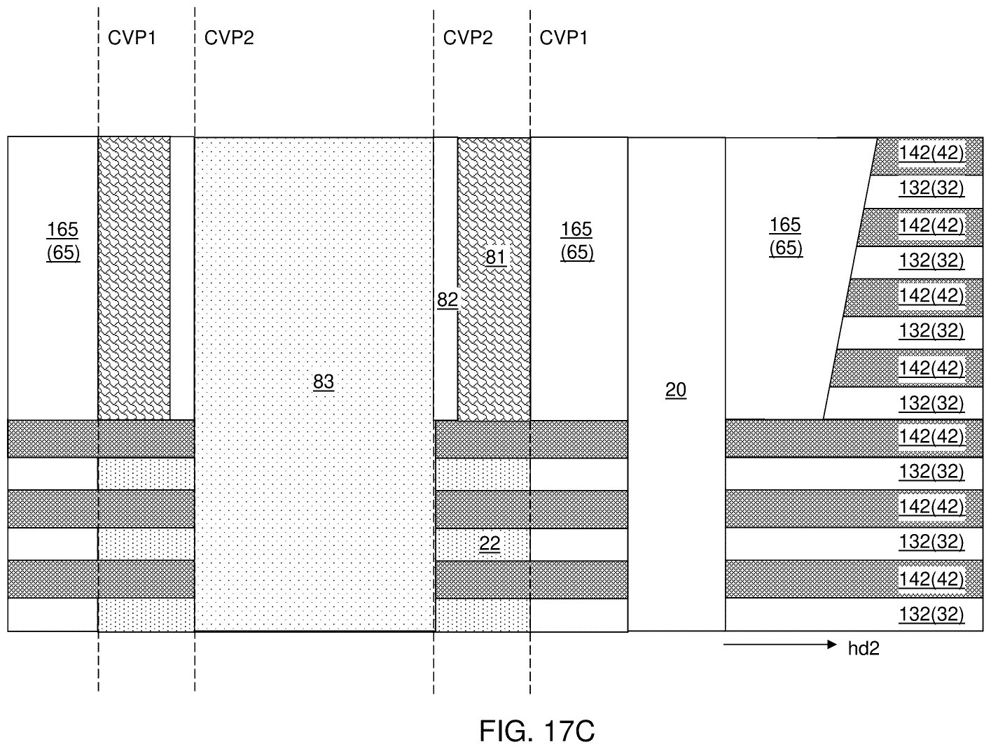

Referring to FIGS. 17A-17C, a dielectric fill material, such as silicate glass (e.g., silicon oxide), can be deposited in the volumes of the voids within the contact via openings 25. Excess portions of the dielectric fill material can be removed from above the horizontal plane including the top surface of the contact-level dielectric layer 80 by chemical mechanical planarization and/or etch back planarization step. Any reactive ion etch residue located over the top surfaces of the sacrificial tubular structures 81 is also removed during the planarization step. Each remaining portion of the dielectric fill material that fills a respective one of the voids within the contact via openings 25 constitutes a dielectric pillar 83. Thus, the dielectric pillars 83 fill the entirety of the volumes from which the sacrificial fill material portions 35 are removed.

Generally, the dielectric pillars 83 can be formed in the center regions of the contact via openings 25. Each dielectric pillar 83 is laterally surrounded by a respective tubular dielectric spacer 82, and vertically extends through an opening in a respective sacrificial material layer 421 and a subset of the sacrificial material layers 42 that underlie the first sacrificial material layer 421. In one embodiment, each dielectric pillar 83 may have a shape of a cylinder and may consist of a dielectric fill material. In one embodiment, each dielectric pillar 83 may comprise a cylindrical sidewall that vertically extends from a bottommost layer within the alternating stack (32, 42) at least to a horizontal plane including a top surface of a respective first sacrificial material layer 421. A dielectric pillar 83 may be laterally surrounded by a vertical stack of annular dielectric spacers 22. In this case, each annular dielectric spacer 22 within the vertical stack of annular dielectric spacers 22 comprise an inner cylindrical sidewall in contact with a respective cylindrical surface segment of the dielectric pillar 83 and an outer cylindrical sidewall in contact with a cylindrical surface of a respective one of the insulating layers 32.

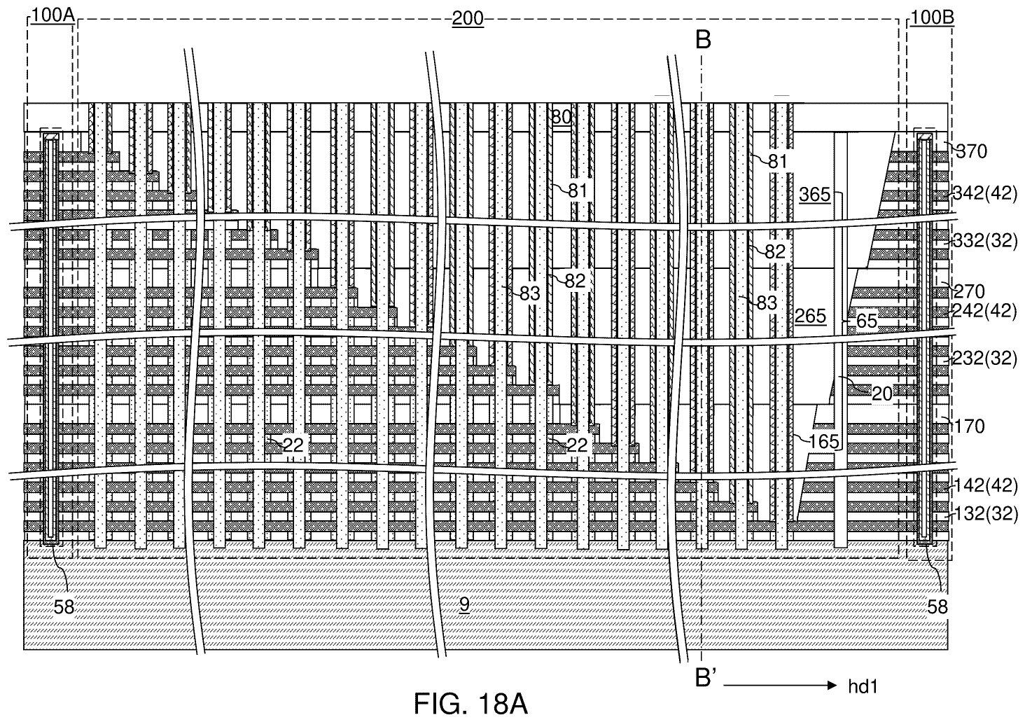

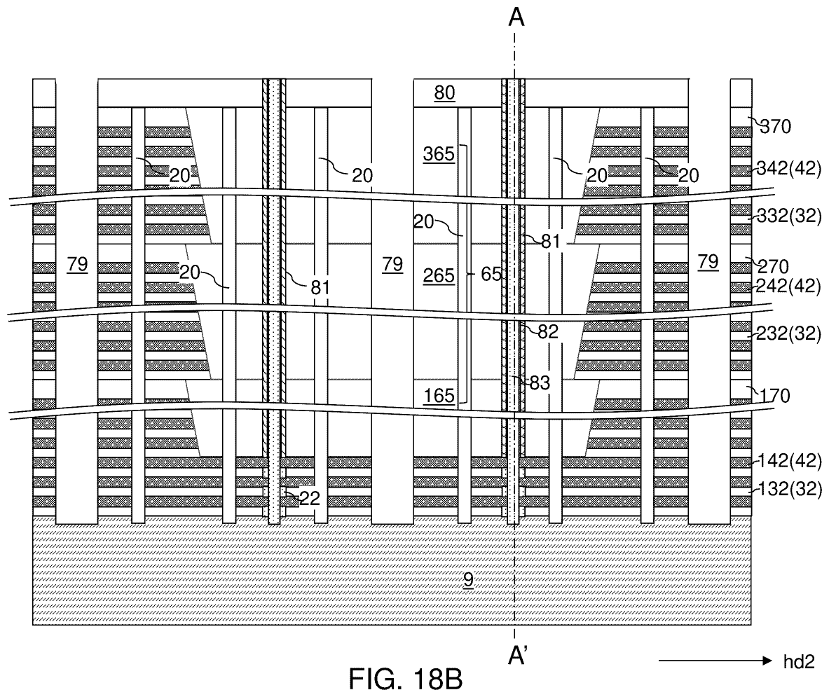

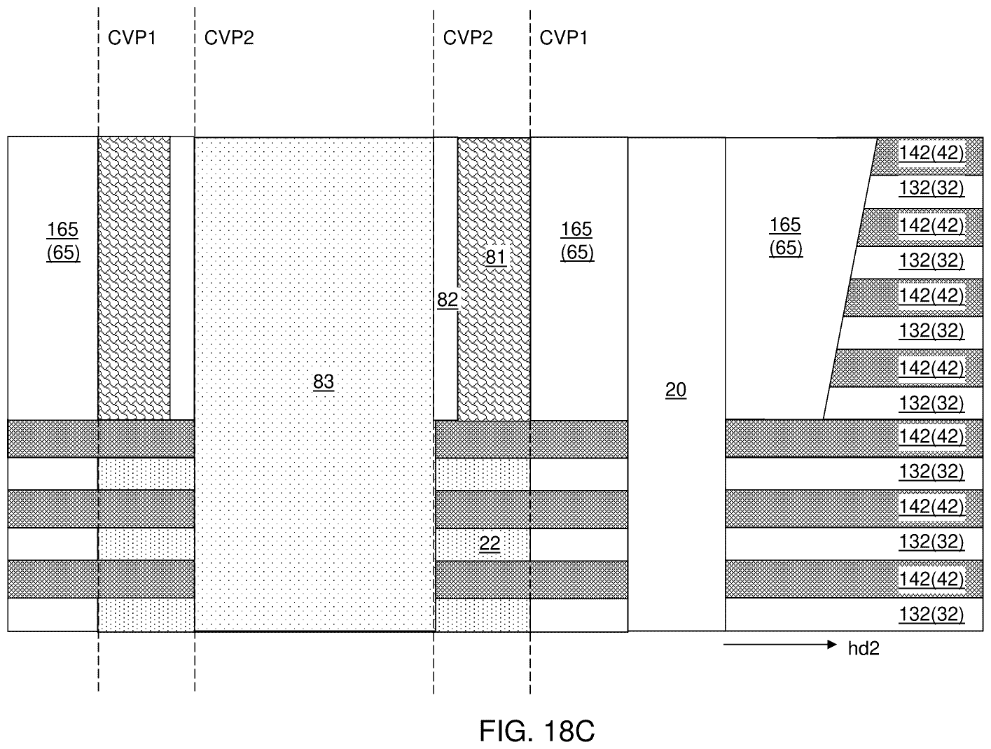

Referring to FIGS. 18A-18C, a masking layer, such as a photoresist layer and/or a carbon patterning film can be applied over the contact-level dielectric layer 80, and can be lithographically patterned to form elongated openings that laterally extend along the first horizontal direction hd1. The elongated openings can be formed in areas in which the memory opening fill structure 58, the support pillar structures 20, and the contact via openings 25 are not present. An anisotropic etch process can be performed to transfer the pattern of the elongated openings through the contact-level dielectric layer 80 and the vertically alternating sequences (32, 42) of the insulating layers 32 and the sacrificial material layers 42.

Lateral isolation trenches 79 can be formed in the voids formed by removal of the material portions of the contact-level dielectric layer 80 and the vertically alternating sequence. Each of the vertically alternating sequences is divided into a respective set of alternating stacks {(132, 142), (232, 242), (332, 342)} of insulating layers 32 and sacrificial material layers 42 that are laterally spaced apart along a second horizontal direction hd2. For example, the first vertically alternating sequence is divided into first-tier alternating stacks of first-tier insulating layers 132 and first-tier sacrificial material layers 142; the second vertically alternating sequence is divided into second-tier alternating stacks of second-tier insulating layers 232 and second-tier sacrificial material layers 242; and the third vertically alternating sequence is divided into third-tier alternating stacks of third-tier insulating layers 332 and third-tier sacrificial material layers 342. The locations of the lateral isolation trenches 79 may be the same as the locations of the lateral isolation trench fill structures 76 illustrated in FIGS. 1A-1E.

The lateral isolation trenches 79 may comprise first lateral isolation trenches 791 that cut through the retro-stepped dielectric material portion (165, 265, 365) and second lateral isolation trenches 792 that do not cut through the retro-stepped dielectric material portion (165, 265, 365). In one embodiment, each first lateral isolation trench 791 divides each retro-stepped dielectric material portion (165, 265, 365) into a respective pair of retro-stepped dielectric material portions (such as first-tier retro-stepped dielectric material portions 265, second-tier retro-stepped dielectric material portions 265 and/or third-tier retro-stepped dielectric material portions 365). Generally, a plurality of tier structures that are vertically stacked can be formed over a substrate 9. Each tier structure within the plurality of tier structures comprises a respective set of alternating stacks of insulating layers 32 and sacrificial material layers 42. The photoresist layer can be subsequently removed, for example, by ashing.

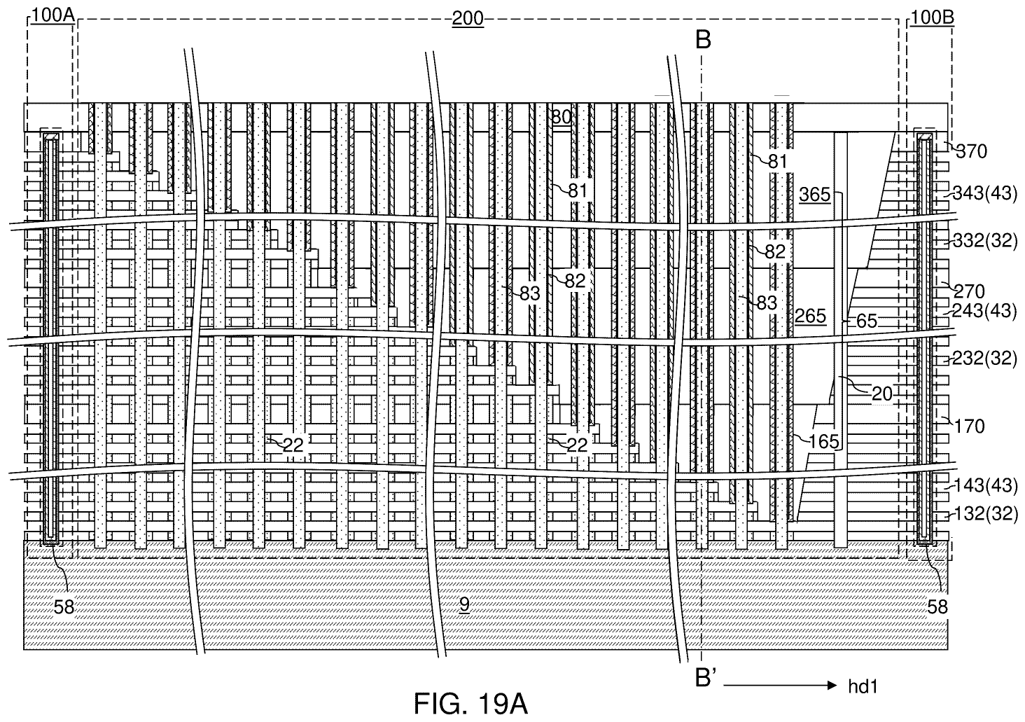

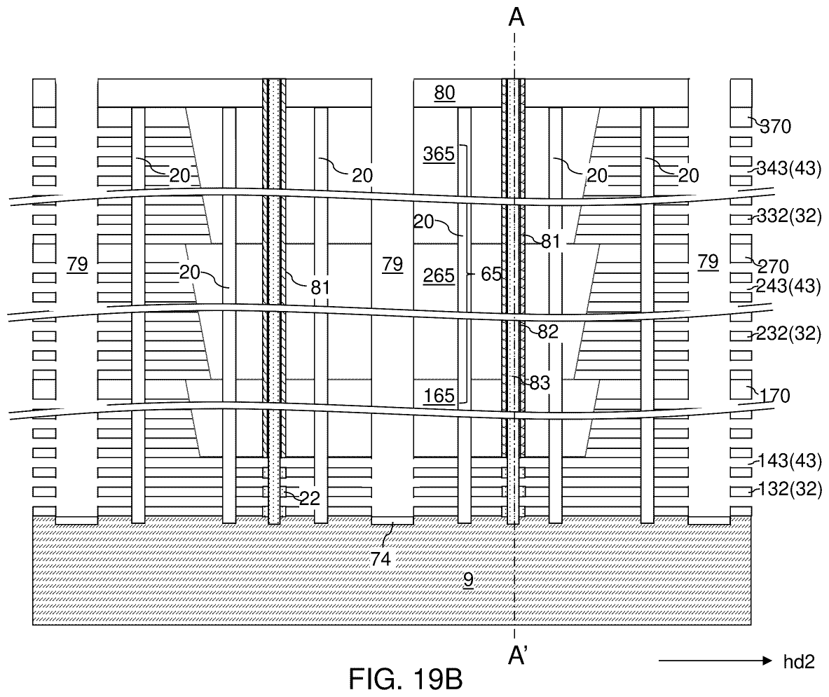

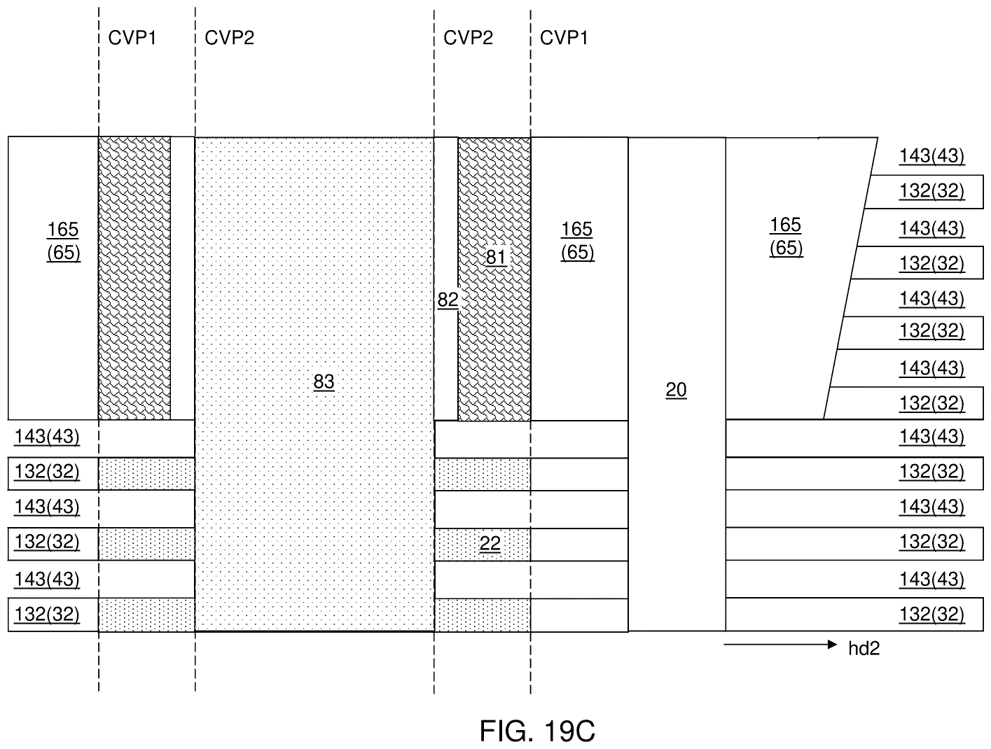

Referring to FIGS. 19A-19C, in case the substrate 9 comprises a semiconductor material, such as silicon, an oxidation process may be performed to convert physically exposed surface portions of the substrate 9 into semiconductor oxide spacer liners 74, such as silicon oxide spacers. The semiconductor oxide spacer liners 74 are formed underneath the lateral isolation trenches 79. The thickness of the semiconductor oxide spacer liners 74 may be in a range from 3 nm to 8 nm, although lesser and greater thicknesses may also be employed. In one embodiments, collateral oxidation of the physically exposed surfaces of the sacrificial material layers 42 may be minimized by reducing the thickness of the semiconductor oxide spacer liners 74.

The sacrificial material layers 42 may be isotropically etched selectively to the insulating layers 32, the dielectric pillars 83, and the retro-stepped dielectric material portions 65 by supplying an isotropic etchant into the lateral isolation trenches 79. In this case, an isotropic etchant may be applied into the lateral isolation trenches 79. Thus, the lateral isolation trenches 79 can be employed as conduits for supplying the isotropic etchant of the selective isotropic etch process. In one embodiment, an etchant that selectively etches the materials of the sacrificial material layers 42 with respect to the materials of the insulating layers 32, the retro-stepped dielectric material portions (165, 265, 365), the material of the dielectric pillars 83, and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the retro-stepped dielectric material portions (165, 265, 365), and the outermost layer of the memory films 50 comprise silicon oxide materials, the etch process may comprise a wet etch tank employing hot phosphoric acid, which etches silicon nitride selectively to silicon oxide, silicon, and various other materials used in the art.

Lateral recesses 43 are formed in volumes from which the sacrificial material layers 42 are removed. The lateral recesses 43 include first lateral recesses 143 that are formed in volumes from which the first-tier sacrificial material layers 142 are removed, second lateral recesses 243 that are formed in volumes from which the second-tier sacrificial material layers 242 are removed, and third lateral recesses 343 that are formed in volumes from which the third-tier sacrificial material layers 342 are removed. Each of the lateral recesses 43 may be a laterally extending cavity having a greater lateral dimension that is greater than a vertical extent. In other words, the lateral dimension of each of the lateral recesses 43 may be greater than the height of the respective lateral recess. A plurality of lateral recesses 43 may be formed in the volumes from which the material of the sacrificial material layers 42 is removed. Each of the lateral recesses 43 may extend substantially parallel to the top surface of the substrate 9. A lateral recess 43 may be vertically bounded by a top surface of an underlying insulating layer 32 and a bottom surface of an overlying insulating layer 32.

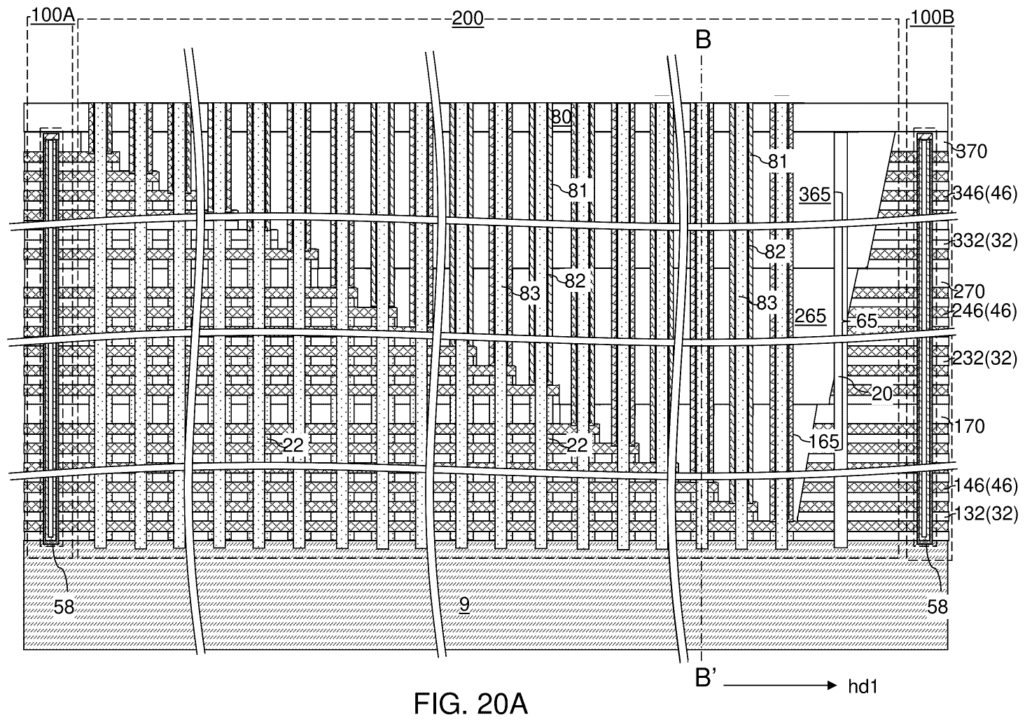

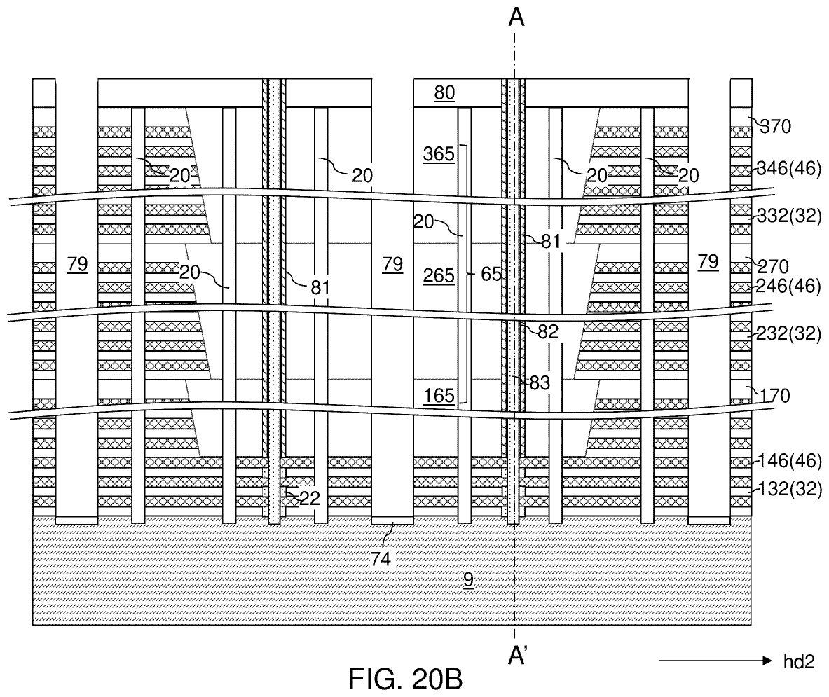

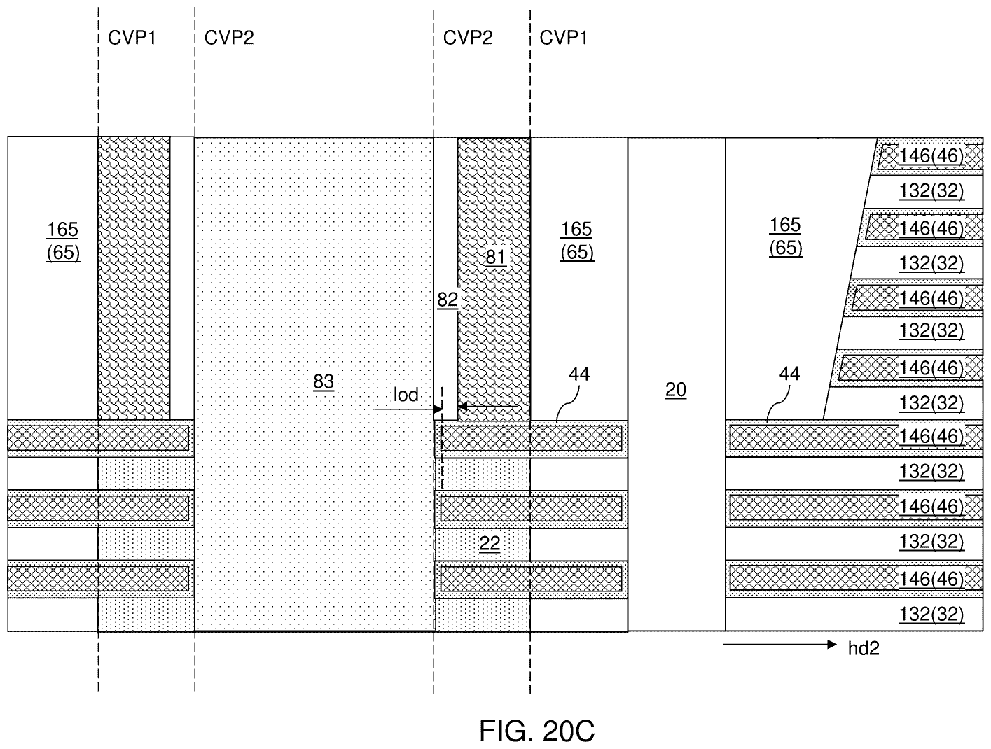

Referring to FIGS. 20A-20C, an outer blocking dielectric layer 44 may be conformally deposited in peripheral portions of the lateral recesses 43 and the lateral isolation trenches 79. The outer blocking dielectric layer 44 includes a dielectric material, such as a dielectric metal oxide (e.g., aluminum oxide, hafnium oxide, etc.). The outer blocking dielectric layer 44 may be formed as a continuous material layer by a conformal deposition process, such as an atomic layer deposition process or a chemical vapor deposition process. The thickness of the outer blocking dielectric layer 44 may be in a range from 2 nm to 10 nm, such as from 3 nm to 8 nm, although lesser and greater thicknesses may also be employed.

At least one metallic material may be conformally deposited on the physically exposed surfaces of the outer blocking dielectric layer 44 in peripheral portions of the lateral recesses 43 and the lateral isolation trenches 79. The at least one metallic material may comprise a combination of a metallic barrier material (such as TiN, TaN, WN, and/or MoN) and a metal fill material (such as W, Ti, Ta, Co, Ru, Mo, Cu, etc.) Portions of the at least one metallic material that are deposited outside the lateral recesses 43 may be removed by performing an etch back process, which may comprise an isotropic etch process and/or an anisotropic etch process.

Remaining portions of at least one metallic material comprise electrically conductive layers 46. The electrically conductive layers 46 comprise first-tier electrically conductive layers 146, second-tier electrically conductive layers 246, and third-tier electrically conductive layers 346. A plurality of first-tier electrically conductive layers 146 may be formed in the plurality of first lateral recesses 143, a plurality of second-tier electrically conductive layers 246 may be formed in the plurality of second lateral recesses 243, and a plurality of third-tier electrically conductive layers 346 may be formed in the plurality of third lateral recesses 343. Each of the electrically conductive layers 46 may include a respective metallic barrier liner and a respective metal fill material portion. Each dielectric pillar 83 can be contacted by a respective set of at least one outer blocking dielectric layer 44 which embeds a respective electrically conductive layer 46.

Generally, lateral recesses 43 can be formed by removing the sacrificial material layers 42 selectively to the insulating layers 32 and the dielectric pillars 83. A combination of a respective outer blocking dielectric layer 44 and a respective one of the electrically conductive layers 46 can be formed in each lateral recess 43. Thus, the sacrificial material layers 42 are replaced with material portions comprising electrically conductive layers 46 and outer blocking dielectric layers 44. For each dielectric pillar 83, a first sacrificial material layer 421 that is proximal to the dielectric pillar 83 is replaced with a respective first electrically conductive layer 461.

Each dielectric pillar 83 is laterally surrounded by a respective set of at least one electrically conductive layer 46, which includes a respective first electrically conductive layer 461 as a topmost electrically conductive layer 46. For each dielectric pillar 83 that is laterally surrounded by a subset of electrically conductive layers 46, each electrically conductive layer 46 within the subset of the electrically conductive layers 46 may be laterally spaced from the dielectric pillar 83 by a respective outer blocking dielectric layer 44. In one embodiment, the first electrically conductive layer 461 comprises an opening having a cylindrical sidewall, and an inner periphery of the annular top surface segment of the first electrically conductive layer 461 is laterally offset outward from an inner cylindrical sidewall of the sacrificial tubular structure 81 by a lateral offset distance lod, as shown in FIG. 20C. In one embodiment, each electrically conductive layer 461 may have a uniform thickness throughout.

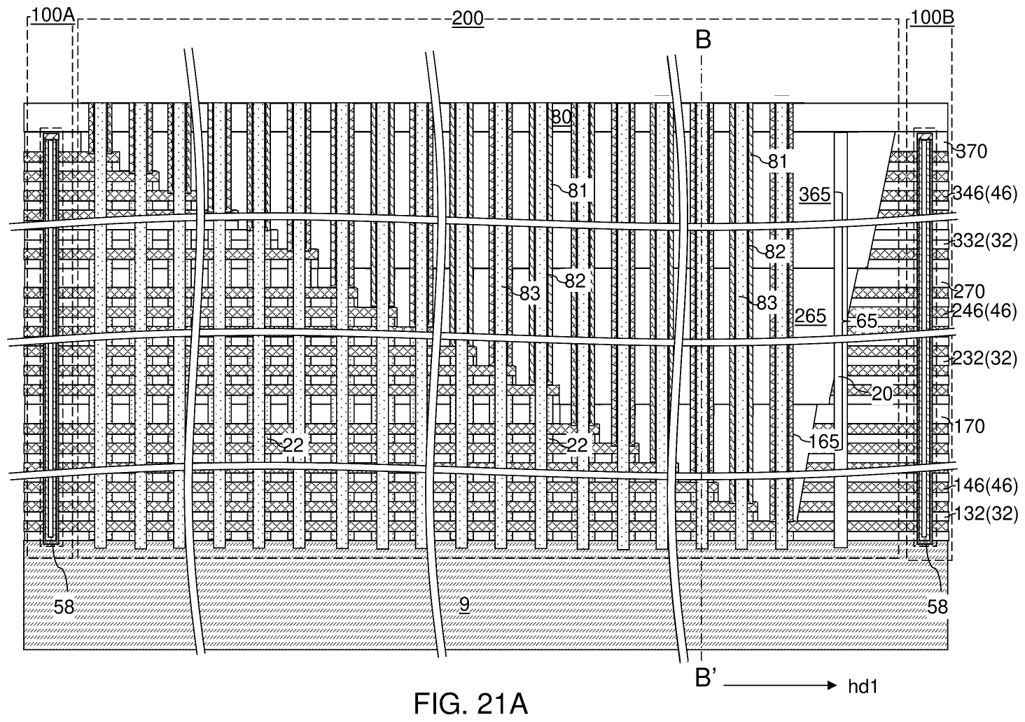

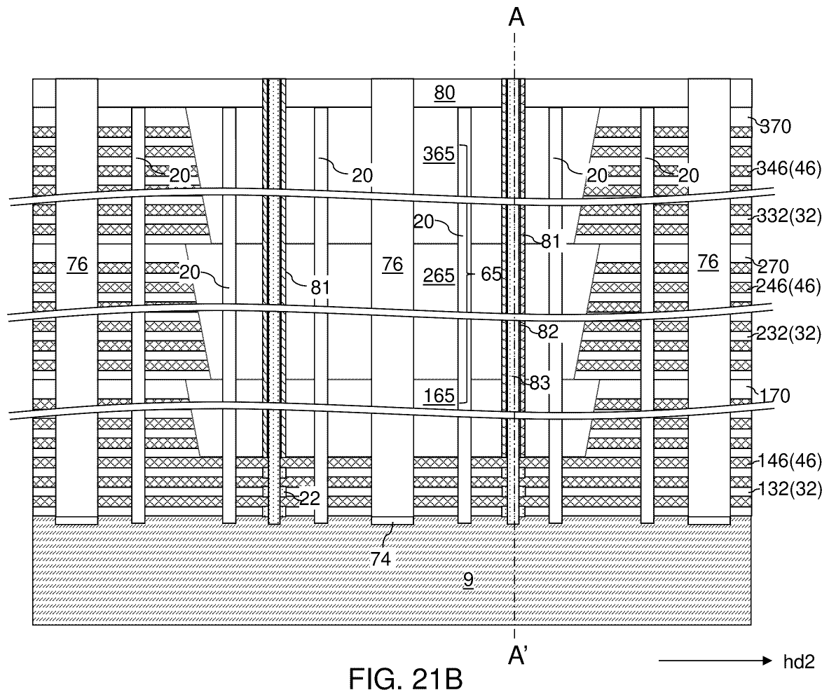

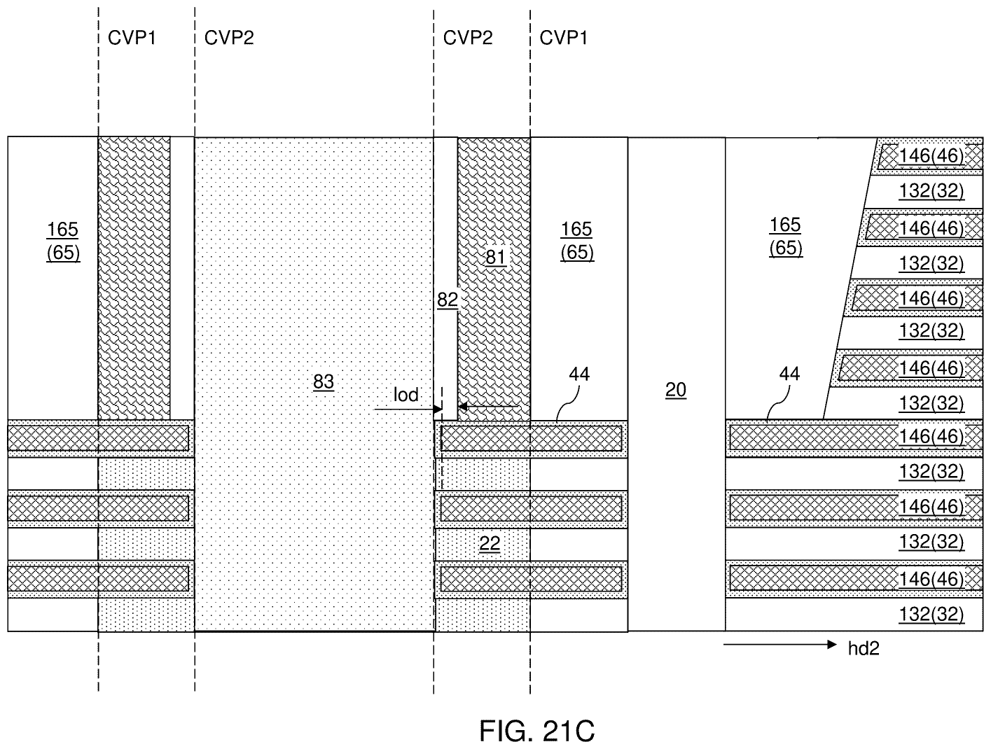

Referring to FIGS. 21A-21C, a dielectric fill material, such as undoped silicate glass or a doped silicate glass can be deposited in the lateral isolation trenches 79 by a conformal deposition process. A planarization process can be performed to remove the portion of the deposited dielectric fill material from above the horizontal plane including the top surface of the contact-level dielectric layer 80. The planarization process may comprise a recess etch process and/or a chemical mechanical polishing process. Each remaining portion of the dielectric fill material that fills a respective one of the lateral isolation trenches 79 constitute a lateral isolation trench fill structure 76.

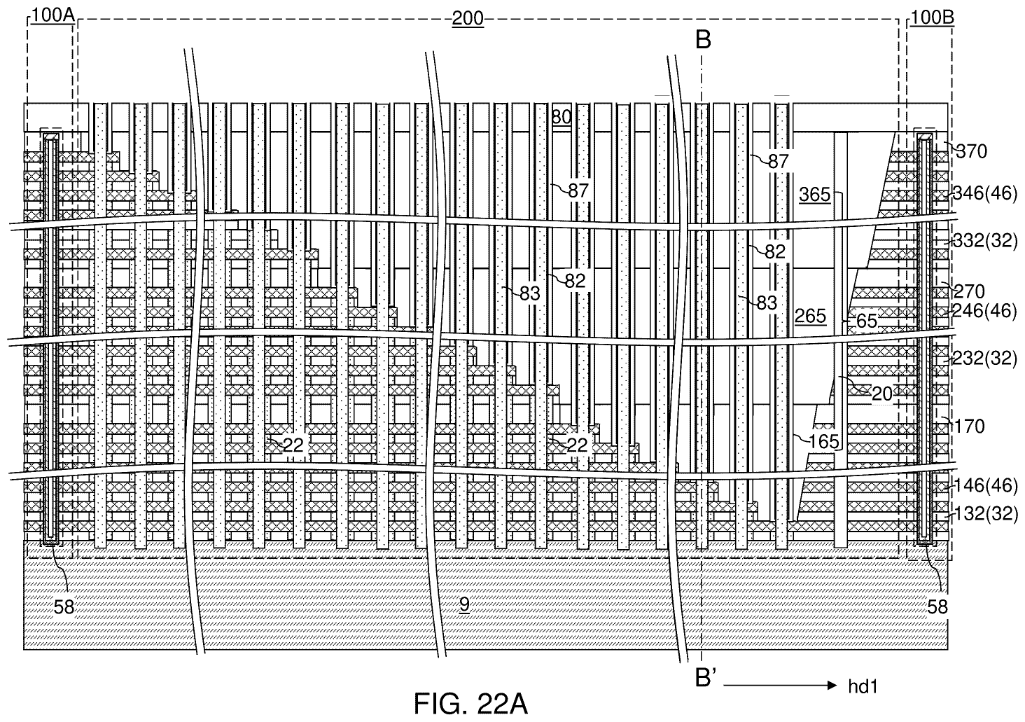

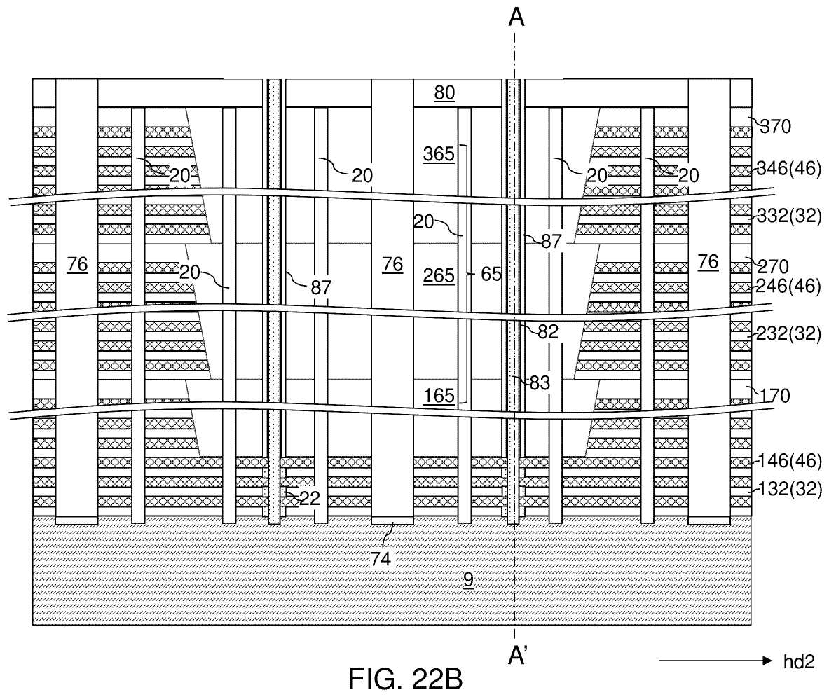

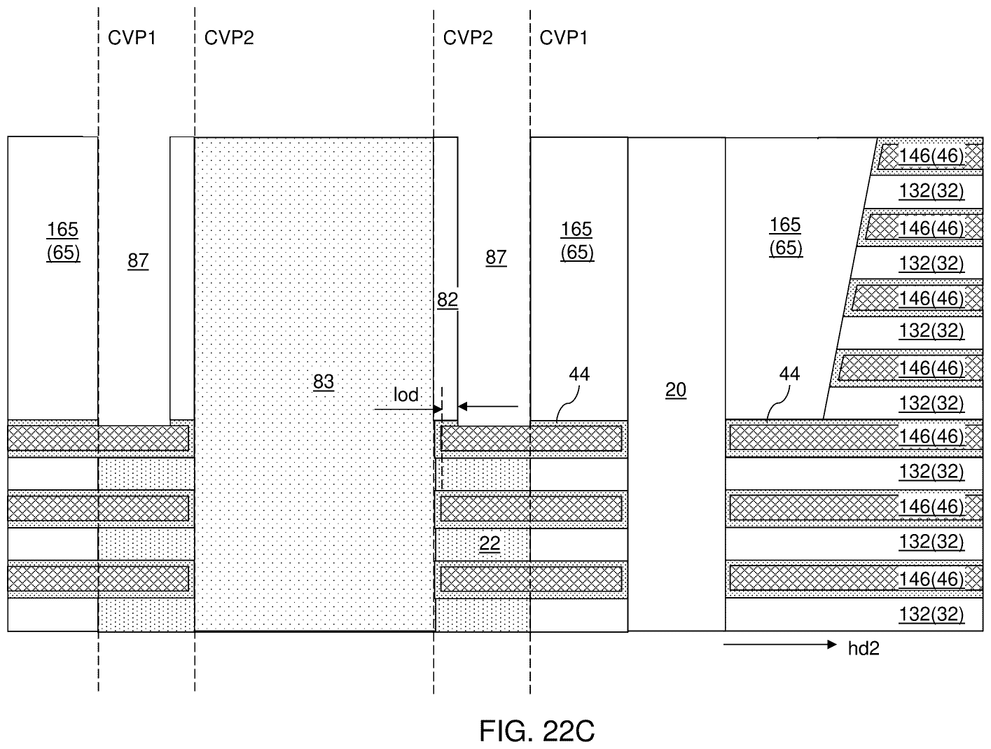

Referring to FIGS. 22A-22C, an isotropic etch process can be performed to etch material of the sacrificial tubular structure 81 selectively to the materials of the tubular dielectric spacers 82, the at least one retro-stepped dielectric material portion 65, and the contact-level dielectric layer 80. A tubular cavity 87 is formed in each volume from which a sacrificial tubular structure 81 is removed. A selective etch process can be performed to etch physically exposed portions of the outer blocking dielectric layers 44 in the tubular cavities 87 selectively to the materials of the electrically conductive layers 46. The selective etch process may comprise an isotropic etch process (such as a wet etch process) or an anisotropic etch process (such as a reactive ion etch process). An annular surface segment of a top surface of a respective first electrically conductive layer 461 may be physically exposed underneath each tubular cavity 87. In one embodiment, the selective etch process that etches physically exposed portions of the outer blocking dielectric layers 44 may stop of the top portion of the first electrically conductive layer 461.

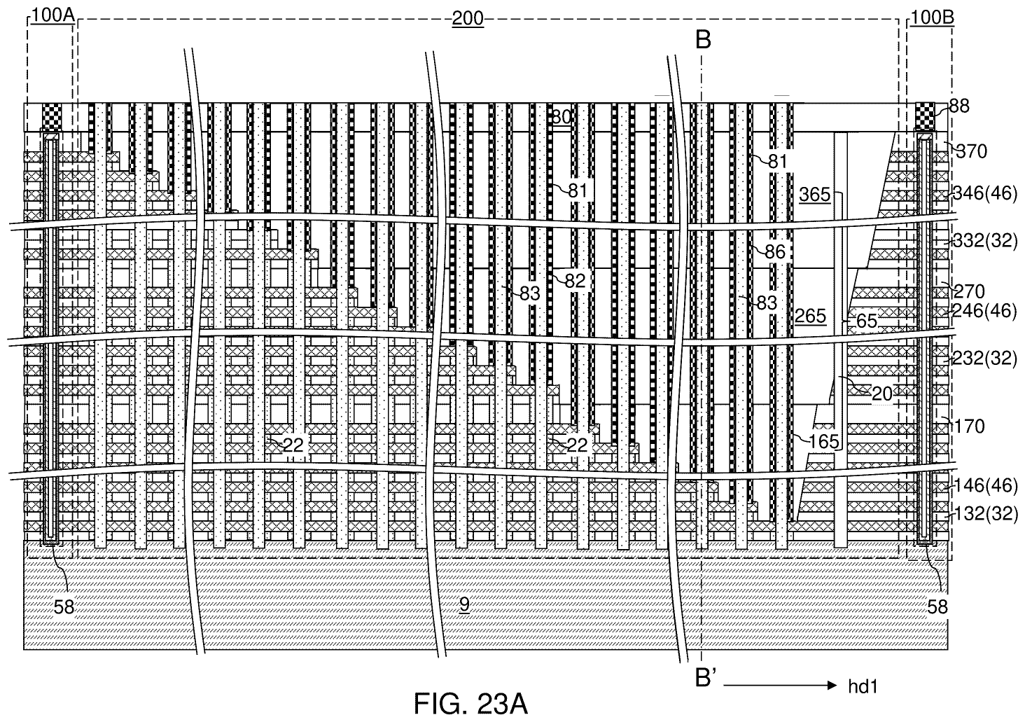

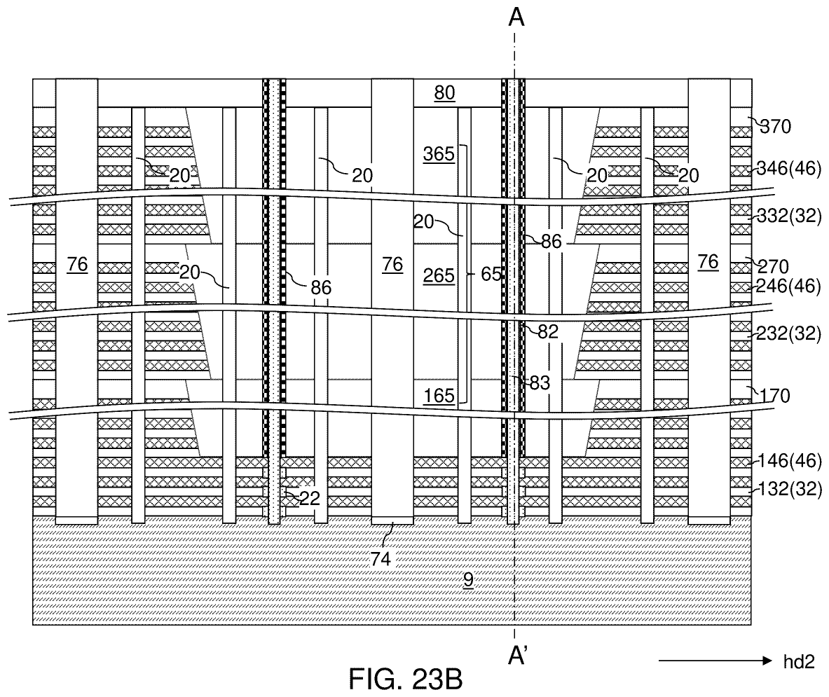

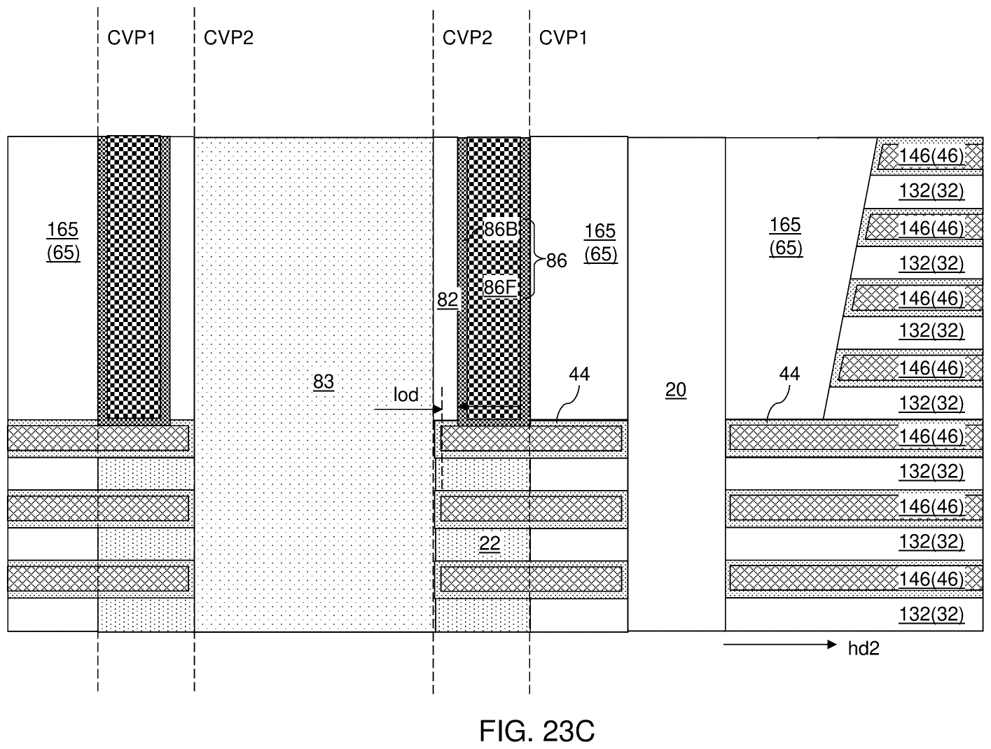

Referring to FIGS. 23A-23C, at least one electrically conductive material can be deposited in each tubular cavity 87 on the exposed annular surface segments of the top surface of the first electrically conductive layers 461. Excess portions of the at least one electrically conductive material can be removed from above the horizontal plane including the top surface of the contact-level dielectric layer 80. Each remaining portion of the at least one electrically conductive material that fills a respective one of the tubular cavities 87 constitutes a tubular layer contact via structure 86 that contacts a respective first electrically conductive layer 461 of the electrically conductive layers 46.

In one embodiment shown in FIG. 23C, the at least one electrically conductive material may comprise a metallic barrier material and a metal fill material. In this case, each tubular layer contact via structure 86 may comprise a metallic barrier liner 86B and a metal fill material portion 86F that is laterally surrounded by the metallic barrier liner 86B. The metallic barrier liner 86B comprises the metallic diffusion barrier material. For example, the metallic diffusion barrier material comprises a conductive metallic nitride material, such as TiN, TaN, WN, and/or MoN. The metallic diffusion barrier material may be deposited as a continuous material layer having a uniform thickness throughout by a conformal deposition process such as a chemical vapor deposition process. The thickness of the metallic diffusion barrier material may be in a range from 3 nm to 60 nm, such as from 6 nm to 30 nm, although lesser and greater thicknesses may also be employed. The metal fill material portion 86F may comprise a metal fill material (such as W, Ti, Ta, Co, Ru, Mo, Cu, etc.).

In summary, each sacrificial tubular structure 81 is replaced with a respective tubular layer contact via structure 86. Each tubular layer contact via structure 86 contacts an annular top surface segment of a respective first electrically conductive layer 461. Each tubular layer contact via structure 86 comprises a metallic barrier liner 86B and a metal fill material portion 86F. The metal fill material portion 86F is embedded within the metallic barrier liner 86B and is spaced from the first electrically conductive layer 461 and from the retro-stepped dielectric material portion 65 by the metallic barrier liner 86B. In one embodiment, the metallic barrier liner 86B of each tubular layer contact via structure 86 contacts an entirety of an outer sidewall of a respective tubular dielectric spacer 82.

Generally, a retro-stepped dielectric material portion 65 having a stepped bottom surface may overlie a region of an alternating stack (32, 46) in which the electrically conductive layers 46 have variable lateral extents that vary (e.g., decrease) with a vertical distance from a horizontal plane including a bottommost surface of the alternating stack (32, 46). A tubular layer contact via structure 86 may vertically extend through the retro-stepped dielectric material portion 65 and may contact an annular top surface segment of a first electrically conductive layer 461 of the electrically conductive layers 46.

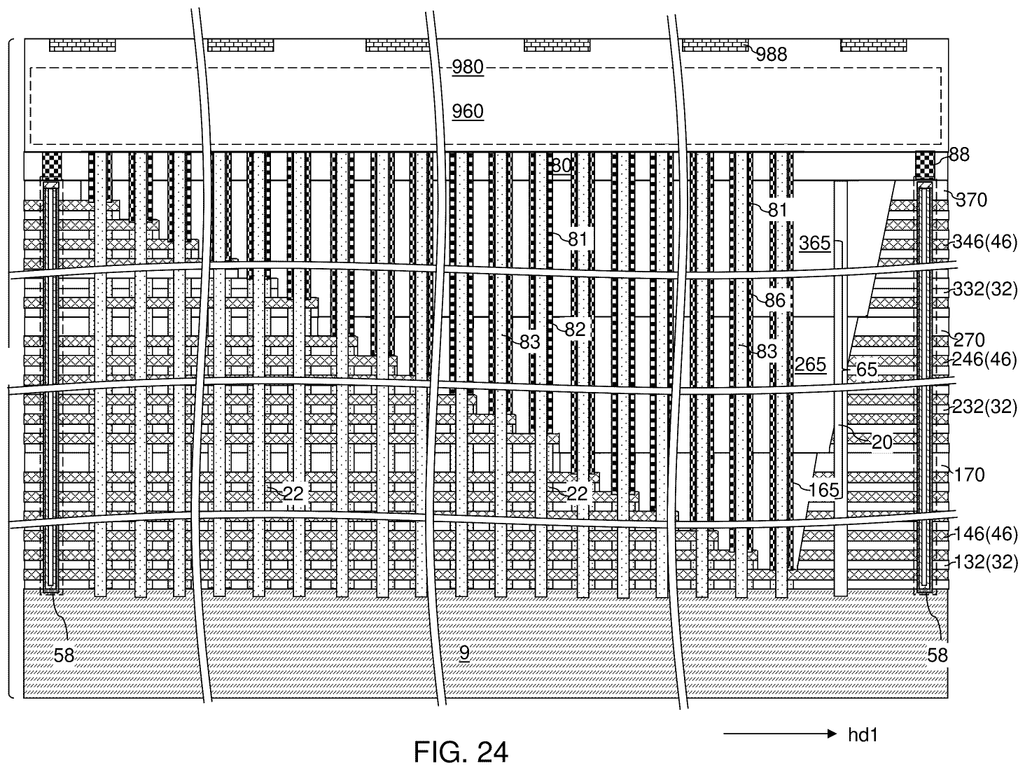

Referring to FIG. 24, drain contact via structures 88 can be formed through the contact-level dielectric layer directly on top surfaces of the drain regions 63. The contact-level dielectric layer 80 overlies the alternating stack (32, 46) and the retro-stepped dielectric material portion 65. Each drain contact via structure 88 vertically extends through the contact-level dielectric layer 80 and contacts a top surface (e.g., top of the drain region 63) of a respective memory opening fill structure 58. In one embodiment, top surfaces of the drain contact via structure 88 and the tubular layer contact via structure 86 can be formed within a horizontal plane including the top surface of the contact-level dielectric layer 80.

Additional dielectric material layers can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the contact-level dielectric layer 80 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

A logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-die bonding process, or by a die-to-wafer bonding process. The logic-side bonding pads 788 within each logic die 700 can be bonded to the memory-side bonding pads 988 within a respective memory die 900.

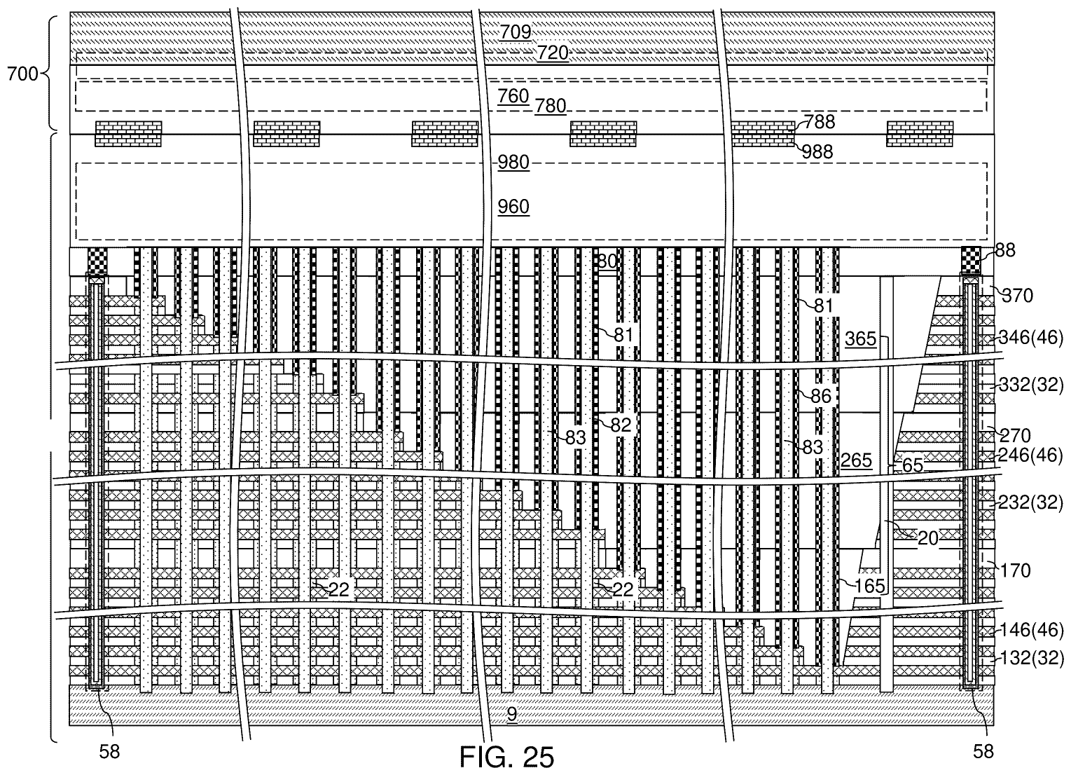

Referring to FIG. 25, the substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (such as a semiconductor material of the substrate 9) selectively to dielectric materials of the memory films 50. In an illustrative example, if the substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures 20 can be physically exposed upon removal of the substrate 9.

An end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selective to the material of the vertical semiconductor channels 60.

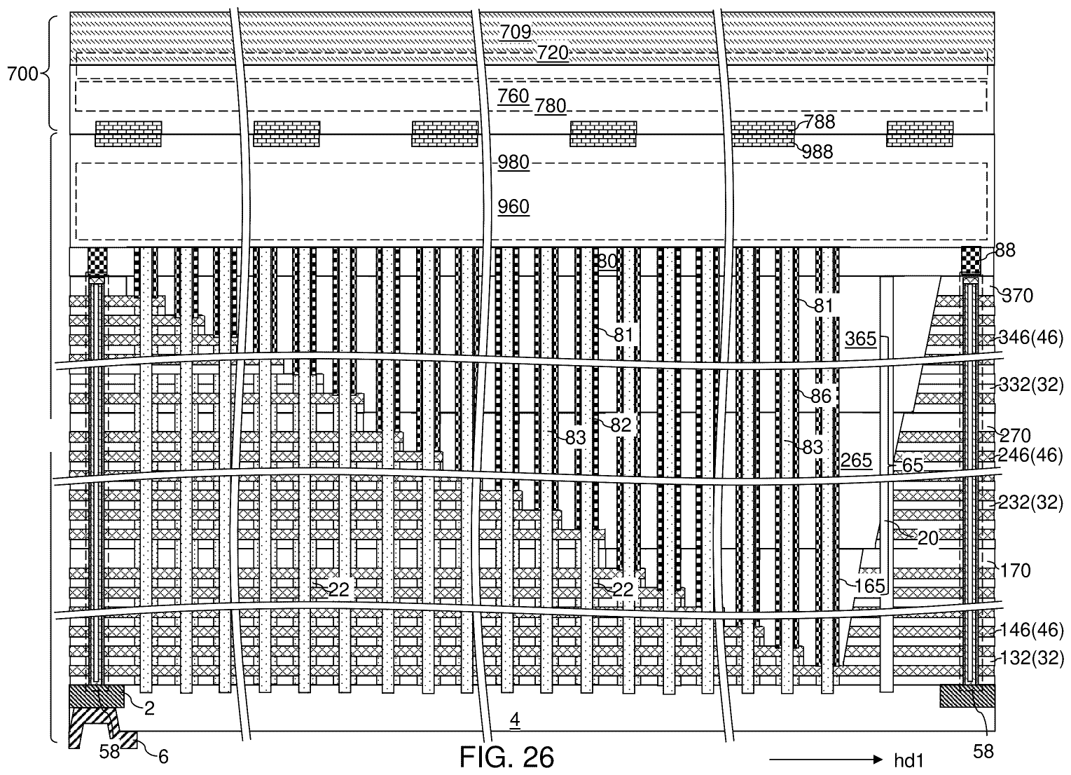

Referring to FIG. 26, at least one source structure 2 (e.g., a source region and/or source line) can be formed in contact vertical semiconductor channels 60. The at least one source structure 2 may comprise a heavily doped semiconductor material and/or a metallic material (e.g., a metal and/or an electrically conductive metal nitride or silicide). A backside dielectric layer 4 and backside contact structures 6 can be subsequently formed.

Referring to all drawings and according to various embodiments of the present disclosure, a device structure is provided, which comprises: an alternating stack (32, 46) of insulating layers 32 and electrically conductive layers 46; a retro-stepped dielectric material portion 65 having a stepped bottom surface and overlying a region of the alternating stack (32, 46) in which the electrically conductive layers 46 have variable lateral extents; a memory stack structure 55 vertically extending through the alternating stack (32, 46) and comprising a vertical stack of memory elements (as embodied as portions of a memory material layer 54); and a tubular layer contact via structure 86 vertically extending through the retro-stepped dielectric material portion 65 and contacting an annular top surface segment of a first electrically conductive layer 461 of the electrically conductive layers 46.

In one embodiment, the device structure comprises a tubular dielectric spacer 82 laterally surrounded by the tubular layer contact via structure 86 and overlying the first electrically conductive layer 461. In one embodiment, the device structure further comprises a dielectric pillar 83 laterally surrounded by the tubular dielectric spacer 82 and vertically extending through an opening in the first electrically conductive layer 461 and a subset of the electrically conductive layers 46 that underlie the first electrically conductive layer 461.

In one embodiment, the dielectric pillar 83 comprises a cylindrical sidewall that vertically extends from a bottommost layer within the alternating stack (32, 46) at least to a horizontal plane including a top surface of the first electrically conductive layer 461. In one embodiment, each electrically conductive layer 46 within the subset of the electrically conductive layers 46 is laterally spaced from the dielectric pillar 83 by a respective outer blocking dielectric layer 44. In one embodiment, the dielectric pillar 83 has a shape of a cylinder and consists of a dielectric fill material.

In one embodiment, the device structure further comprises a vertical stack of annular dielectric spacers 22 located at levels of a subset of the insulating layers 32 that underlie the first electrically conductive layer 461 and laterally surrounding the dielectric pillar 83. In one embodiment, each annular dielectric spacer 22 within the vertical stack of annular dielectric spacers 22 comprises an inner cylindrical sidewall in contact with a respective cylindrical surface segment of the dielectric pillar 83 and an outer cylindrical sidewall in contact with a cylindrical surface of a respective one of the insulating layers 32. In one embodiment, outer cylindrical sidewalls of the annular dielectric spacers 22 and an outer cylindrical sidewall of the tubular layer contact via structure 86 are located within a cylindrical vertical plane (such as a first cylindrical vertical plane CVP1).

In one embodiment, the tubular layer contact via structure 86 comprises a metallic barrier liner 86B and a metal fill material portion 86F that is embedded within the metallic barrier liner 86B and is spaced from the first electrically conductive layer 461 and from the retro-stepped dielectric material portion 65 by the metallic barrier liner 86B. In one embodiment, the metallic barrier liner 86B of the tubular layer contact via structure 86 contacts an entirety of an outer sidewall of the tubular dielectric spacer 82.

In one embodiment, the first electrically conductive layer 461 comprises an opening having a cylindrical sidewall through which the dielectric pillar 183 vertically extends. The tubular layer contact via structure 86 comprises a hollow cylinder which is laterally offset outward from the cylindrical sidewall by a lateral offset distance lod.

In one embodiment, the device structure also comprises: a contact-level dielectric layer 80 overlying the alternating stack (32, 46) and the retro-stepped dielectric material portion 65; and a drain contact via structure 88 vertically extending through the contact-level dielectric layer 80 and contacting a top surface of the memory opening fill structure 58, wherein top surfaces of the drain contact via structure 88 and the tubular layer contact via structure 86 are located within a horizontal plane including a top surface of the contact-level dielectric layer 80.

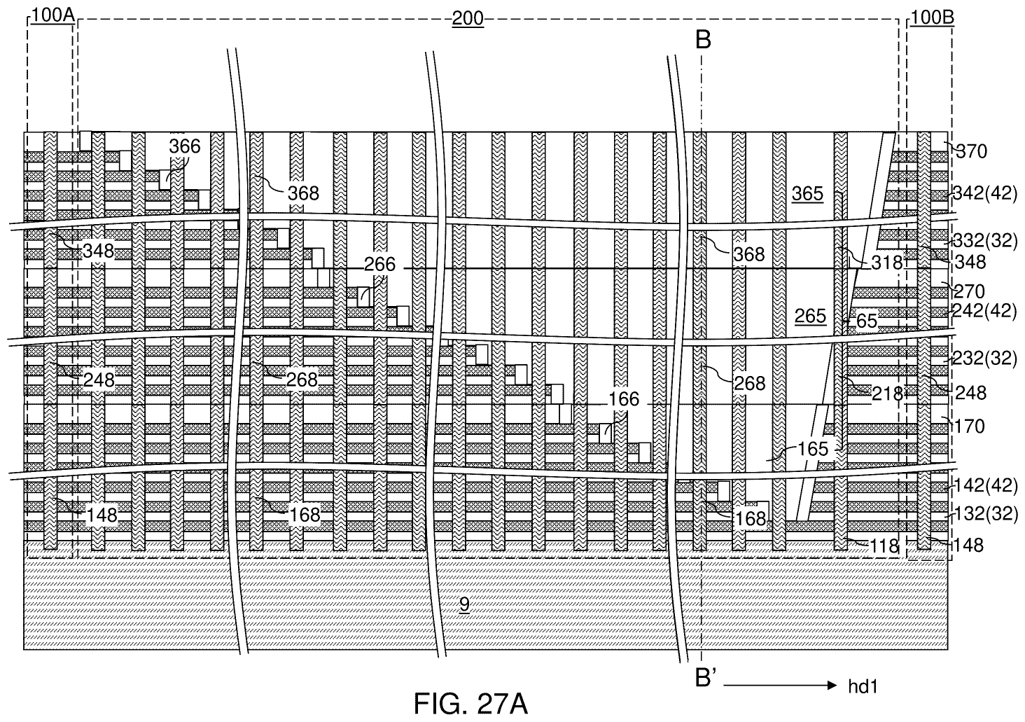

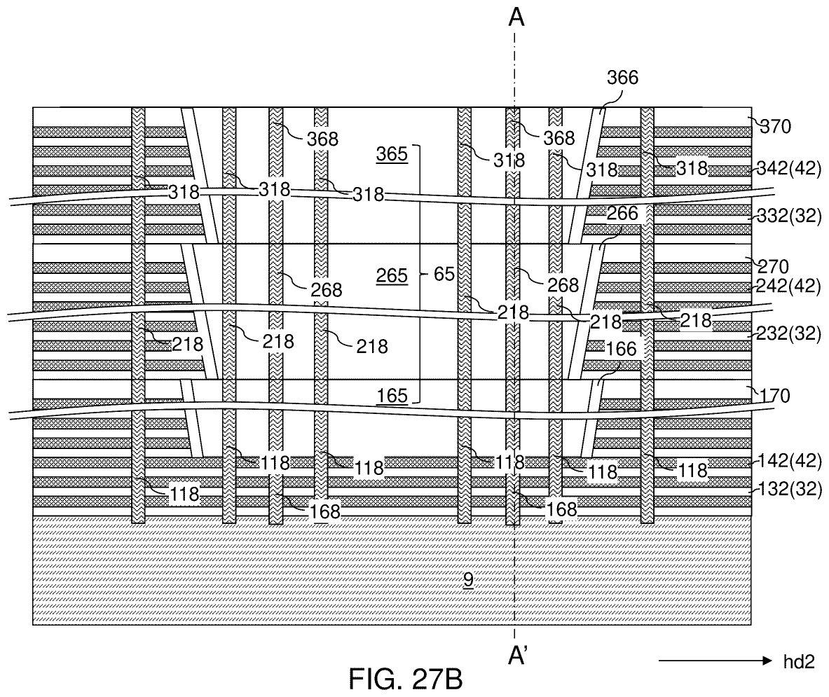

Referring to FIGS. 27A-27C, a second exemplary structure according to a second embodiment of the present disclosure. The second exemplary structure illustrated in FIGS. 27A-27C may be the same as the first exemplary structure illustrated in FIGS. 8A and 8B. Optionally, insulating sidewall spacers (166, 266, 366) may be added to the second exemplary structure. Each of the insulating sidewall spacers (166, 266, 366) can be formed by conformally depositing and anisotropically etching at least one insulating spacer material layer after formation of stepped surfaces and prior to formation of a respective retro-stepped dielectric material portion (165, 265, 365).

Generally, at least one alternating stack (32, 42) of insulating layers 32 and sacrificial material layers 42 is formed over a substrate 9, and at least one set of stepped surfaces can be formed by patterning a respective alternating stack (32, 42) in a respective staircase region. A retro-stepped dielectric material portion 65 can be formed over each set of stepped surfaces. The retro-stepped dielectric material portion(s) 65 and the various openings through the at least one alternating stack (32, 42) for forming memory opening fill structures 58 and the contact via structures may be arranged in the manner described with reference to FIGS. 1A-1E.

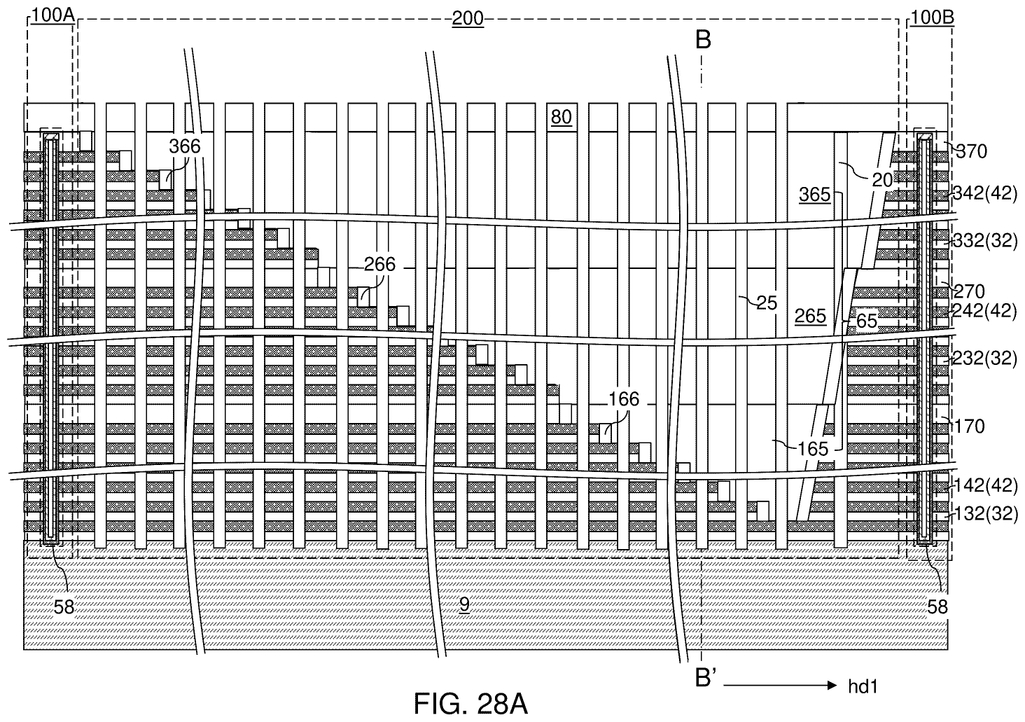

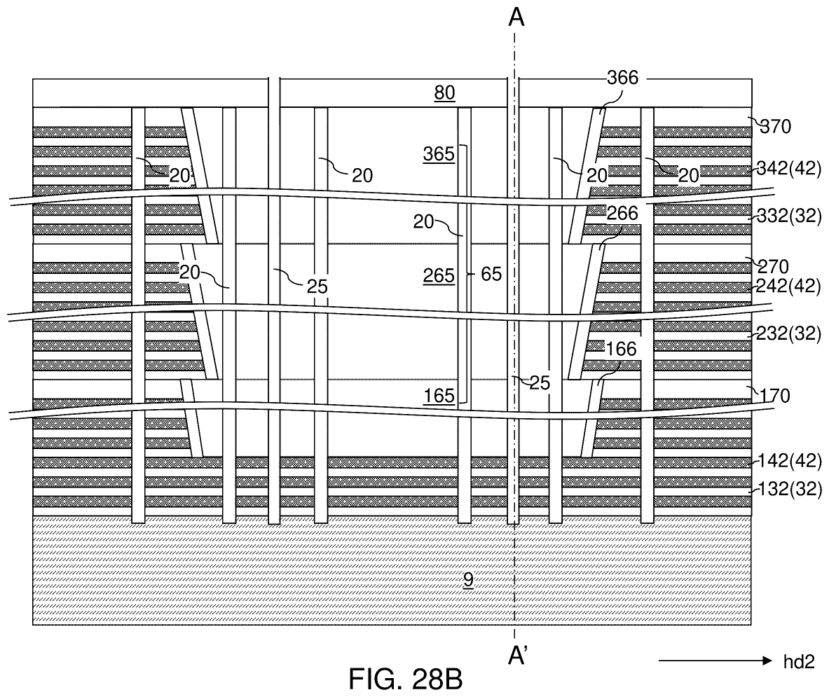

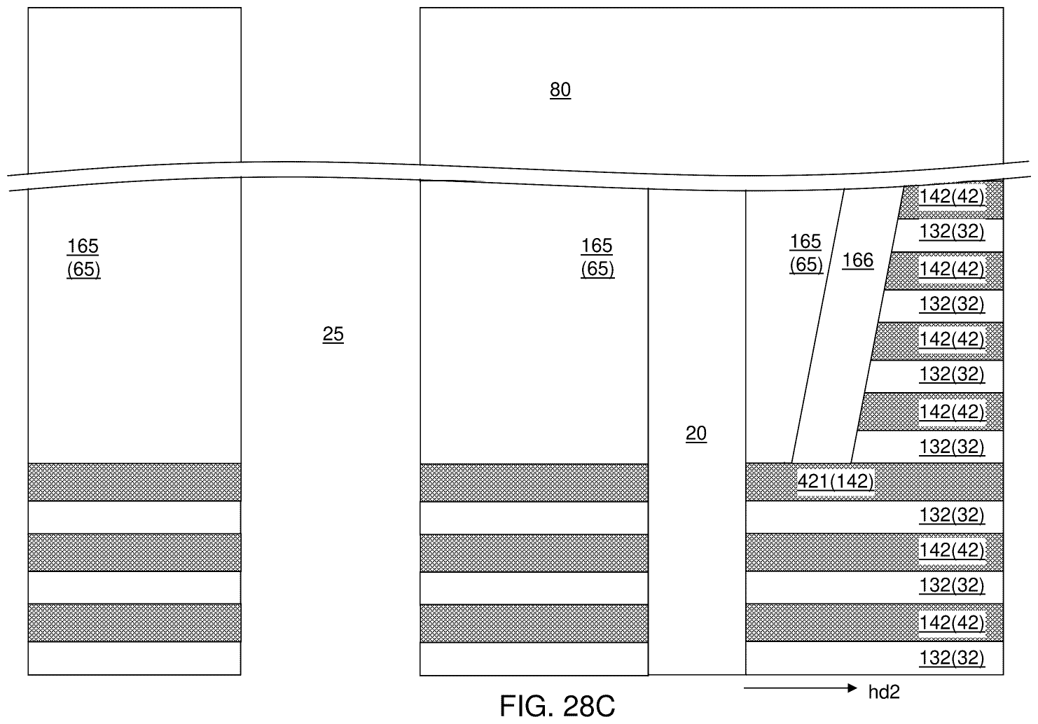

Referring to FIGS. 28A-28C, the processing steps described with reference to FIGS. 9A-14C can be performed to form support pillar structures 20, memory opening fill structures 58, a contact-level dielectric layer 80, and contact via openings 25. The memory opening fill structures 58 comprise memory stack structures 55 which vertically extend through the alternating stack (32, 42). Each of the memory stack structures 55 comprises a respective vertical semiconductor channel 60 and a respective vertical stack of memory elements (comprising portions of a memory material layer 54) located at levels of the sacrificial material layers 42. At least one retro-stepped dielectric material portion 65 having a respective stepped bottom surface overlies a respective region of the alternating stack (32, 42) in which the sacrificial material layers 42 have variable lateral extents. Each contact via opening 25 vertically extends through at least one retro-stepped dielectric material portion 65, a subset of the sacrificial material layers 42 within the alternating stack (32, 42), and a subset of the insulating layers 32 within the alternating stack (32, 42). For each contact via opening 25 that is laterally surrounded by a respective subset of the sacrificial material layers 42, the topmost layer within the subset of the sacrificial material layers 42 comprises a first sacrificial material layer 421.

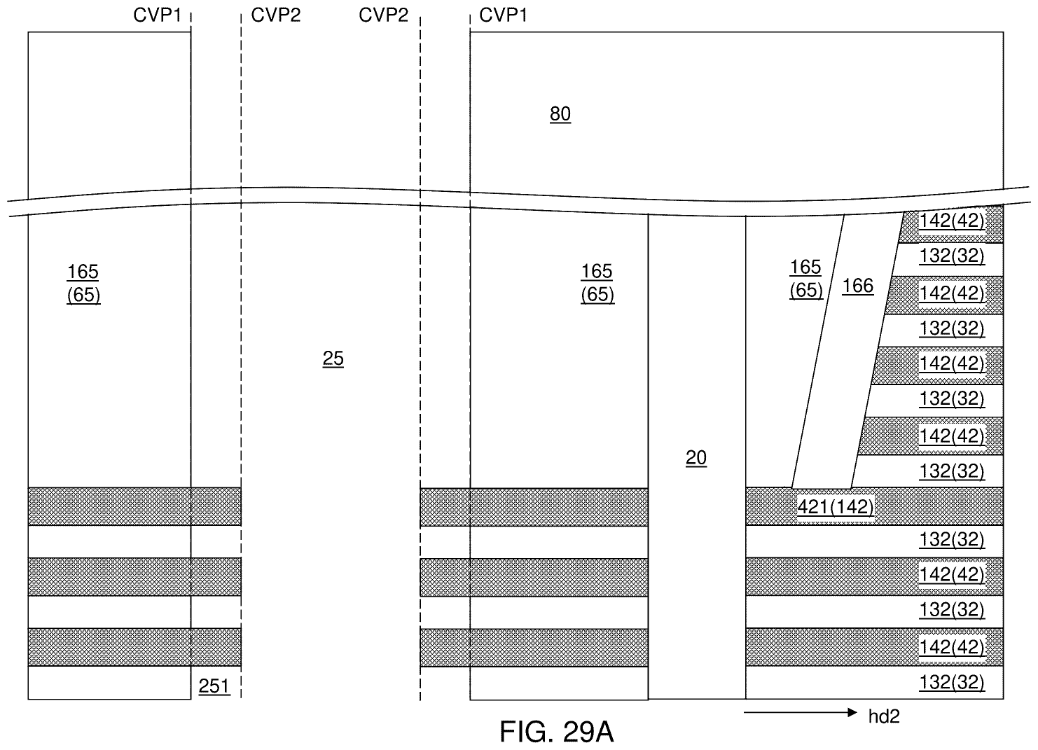

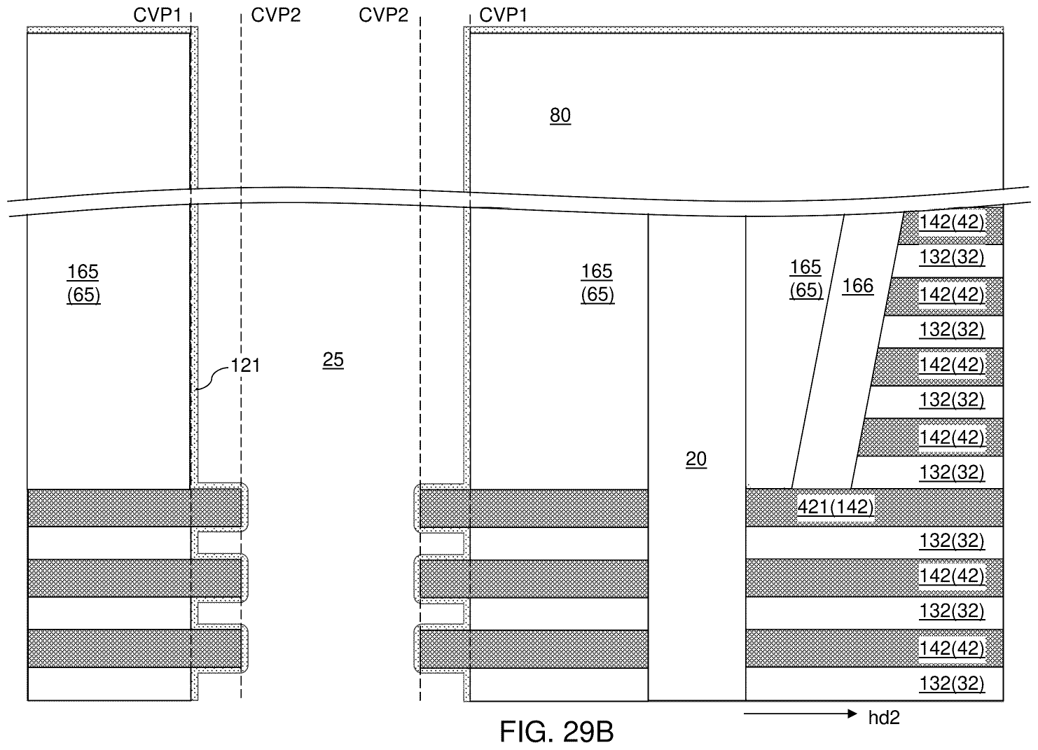

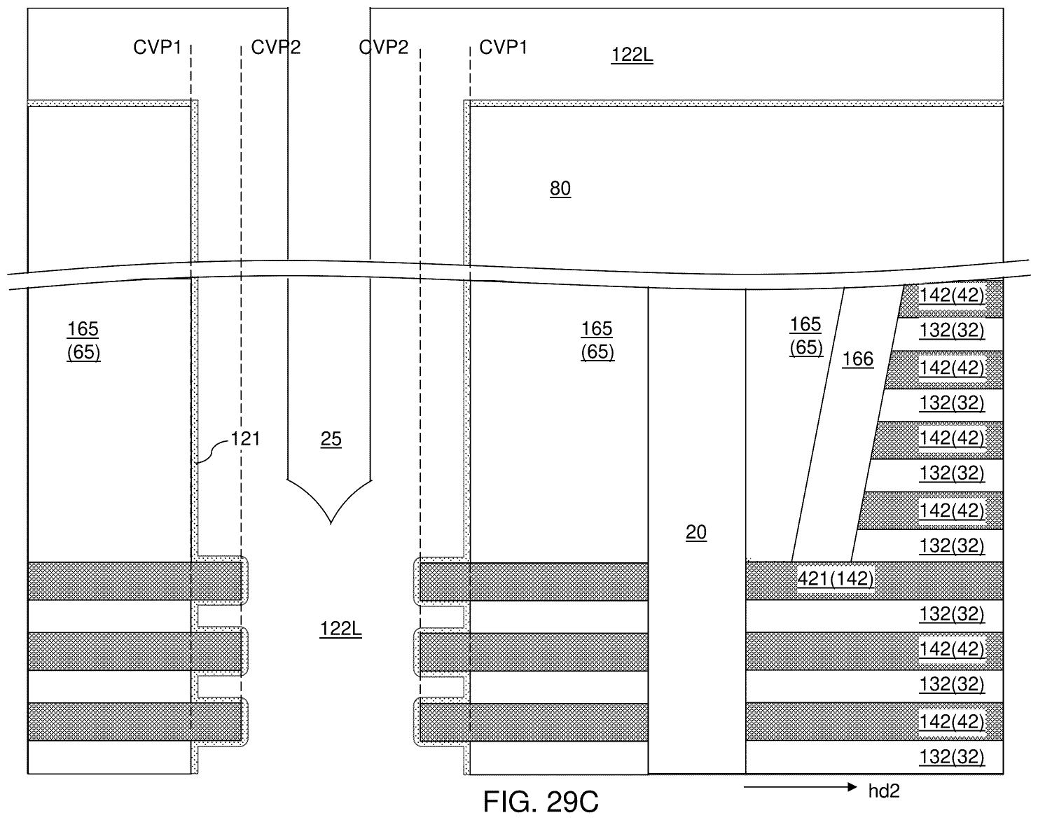

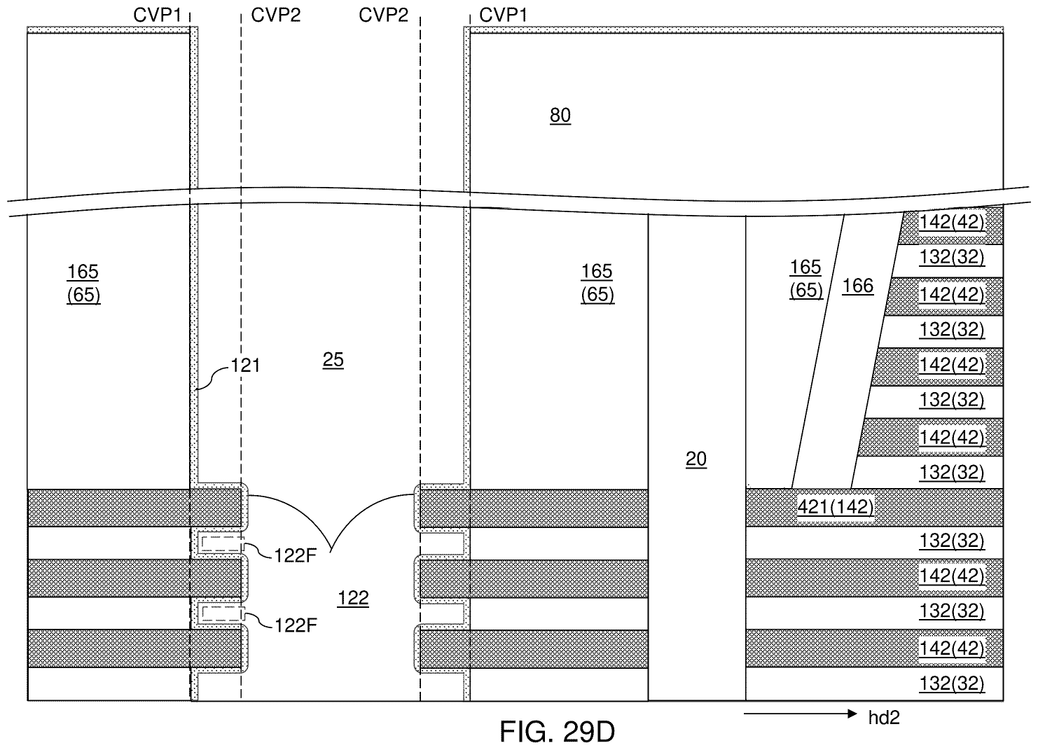

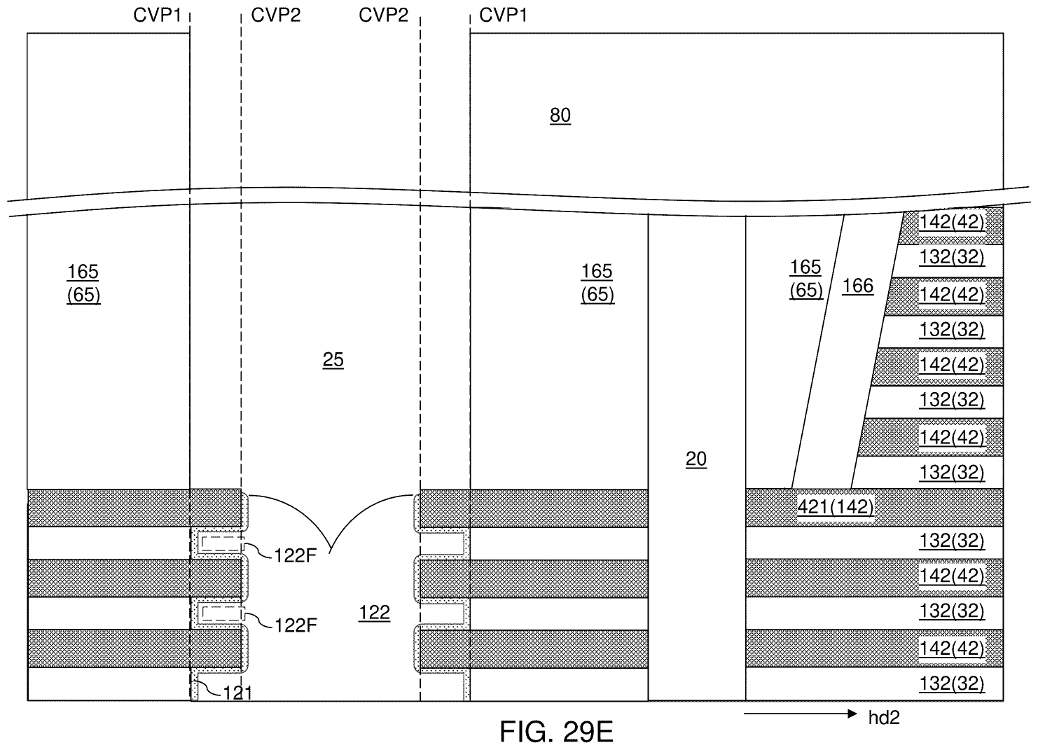

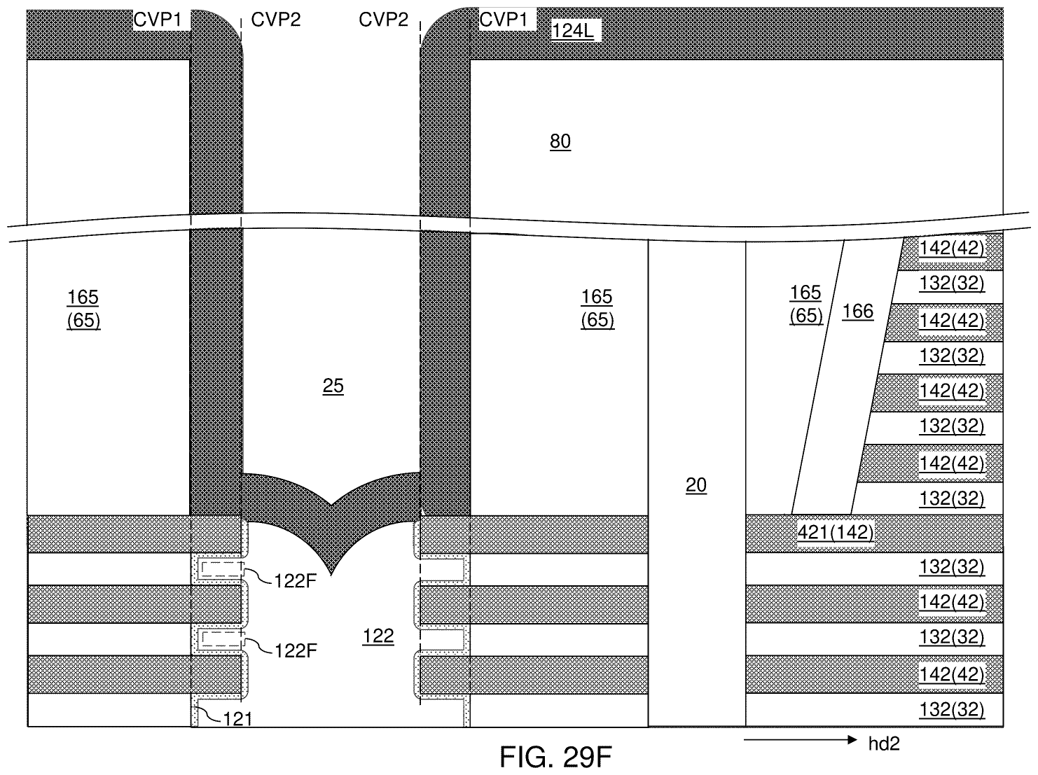

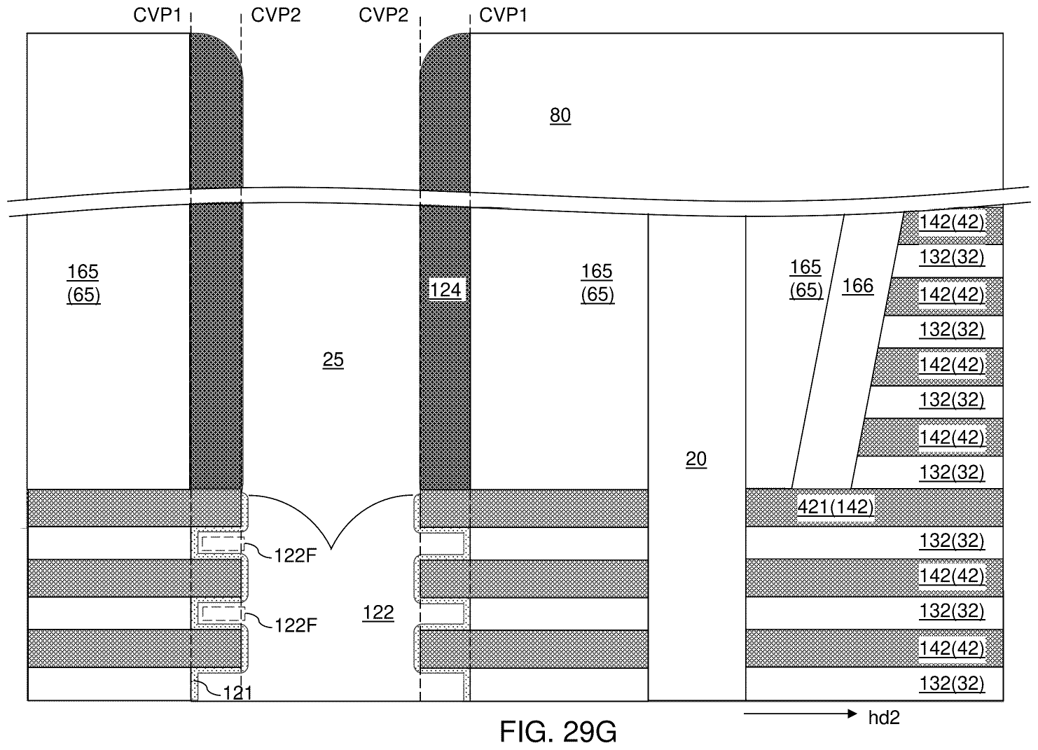

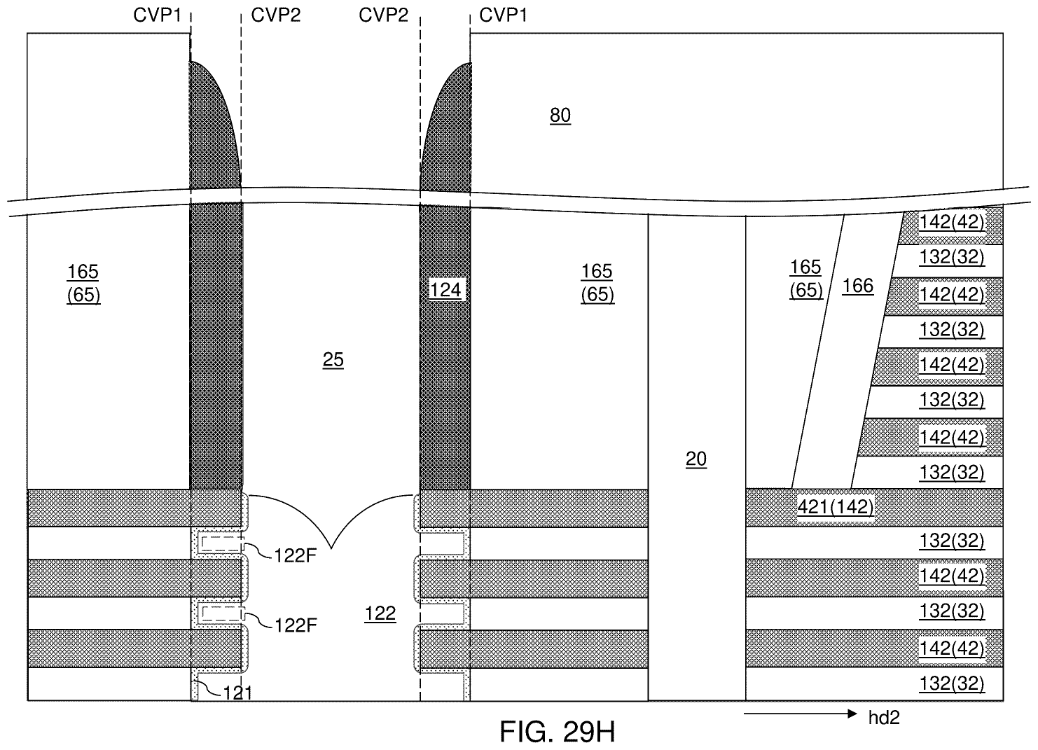

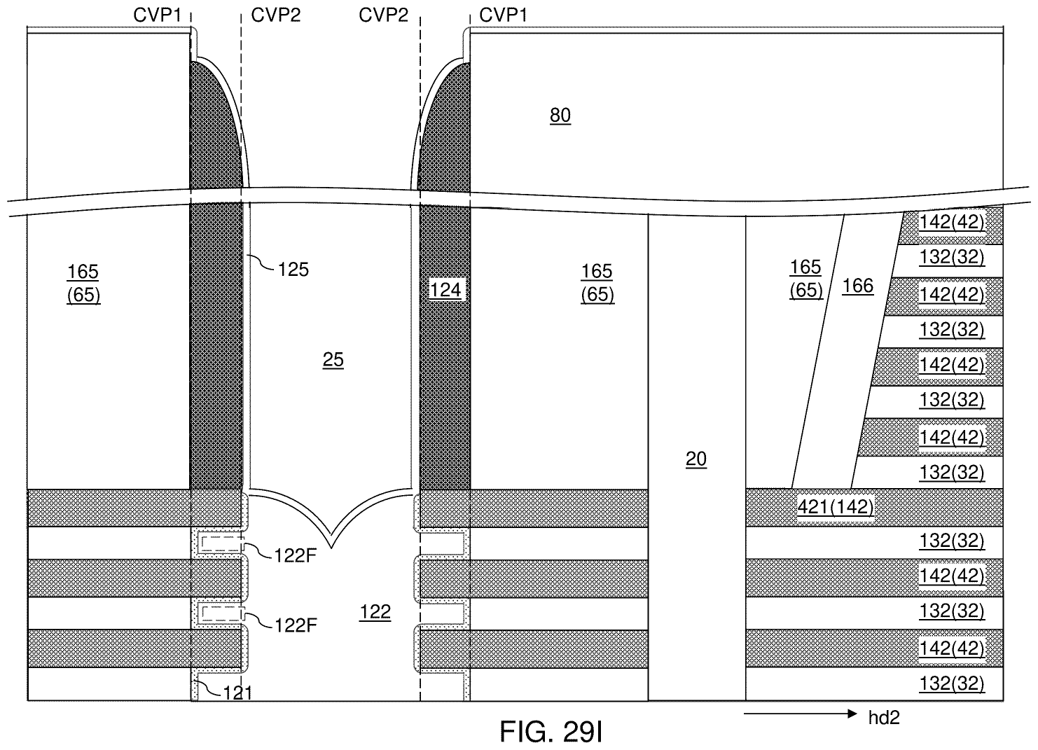

FIGS. 29A-29I are sequential vertical cross-sectional views of a region around a contact via opening 25 in the second exemplary structure during a sequence of processing steps for formation of various structural elements therein according to the second embodiment of the present disclosure.

Referring to FIG. 29A, an isotropic etch process can be performed to laterally recess the sidewalls of the at least one retro-stepped dielectric material portion 65 around the contact via openings 25. For example, the at least one retro-stepped dielectric material portion 65 may comprise a silicate glass material, and the isotropic etch process may comprise a wet etch process employing dilute hydrofluoric acid. In one embodiment, the isotropic etch process may collaterally etch portions of the insulating layers 32 that are proximal to the contact via openings 25. In one embodiment, the isotropic etch process forms a vertical stack of annular cavities 251 by laterally recessing the subset of the insulating layers 32 around the contact via opening 25. Each laterally recessed sidewall of the at least one retro-stepped dielectric material portion 65 may be formed in a respective first cylindrical vertical plane CVP1, which is a vertical plane having a lateral curvature such that a horizontal cross-sectional shape of the vertical plane is a circle. In one embodiment, the insulating layers 32 and the at least one retro-stepped dielectric material portion 65 may comprise a same material (such as undoped silicate glass or a doped silicate glass), and a first cylindrical vertical plane CVP1 may contain a cylindrical sidewall of the at least one retro-stepped dielectric material portion 65 and each cylindrical sidewall of underlying insulating layers 32 around a respective contact via opening 25. Unrecessed cylindrical sidewalls of the subset of the sacrificial material layers 42 around the respective contact via opening 25 may be formed within a respective second cylindrical vertical plane CVP2, which may be laterally offset inward relative to the first cylindrical vertical plane CVP1 by the etch distance of the isotropic etch process. In one embodiment, the etch distance of the isotropic etch process may be in a range from 25 nm to 200 nm, such as 30 nm to 70 nm, although lesser and greater etch distances may also be employed.

Referring to FIG. 29B, a conformal silicon liner 121 can be optionally deposited in peripheral regions of the contact via openings 25 on physically exposed surfaces of the sacrificial material layers 42, the insulating layers 32 (e.g., in the annular cavities 251), and the at least one retro-stepped dielectric material portion 65. The thickness of the conformal silicon liner 121, if employed, is less than one half of the thickness of each insulating layer 32, and may be in a range from 2 nm to 8 nm, although lesser and greater thicknesses may also be employed. Thus, the conformal silicon liner 121 only partially fills the annular cavities 251. The silicon liner 121 may comprise an intrinsic amorphous silicon liner 121.

Referring to FIG. 29C, a dielectric fill material layer 122L can be conformally deposited in the contact via openings 25 over the conformal silicon liner 121. The thickness of the dielectric fill material layer 122L can be selected such that a lower portion of each contact via opening 25 located below a respective horizontal plane including a top surface of a respective first sacrificial material layer 421 is completely filled within the dielectric fill material layer 122L, while an upper portion of each contact via opening 25 located above the respective horizontal plane comprises a void that is not filled with the dielectric fill material layer 122L. The dielectric fill material layer 122L comprises a material that is different from the material of the sacrificial material layers 42. For example, the dielectric fill material layer 122L may comprise undoped silicate glass (i.e., silicon oxide) or a doped silicate glass

Referring to FIG. 29D, the dielectric fill material layer 122L can be etched back employing an isotropic or anisotropic recess etch process. The recess distance for the dielectric fill material layer 122L is greater than the lateral thickness of vertically-extending portions of the dielectric fill material layer 122L. If a conformal silicon layer 121 is present, the etch process may comprise a selective etch process that etches the material of the dielectric fill material layer 122L selectively to the material of the conformal silicon layer 121. In an illustrative example, if the dielectric fill material layer 122L comprises a silicate glass material, the recess etch process may comprise a wet etch process employing dilute hydrofluoric acid. In one embodiment, an annular top surface segment of a respective first sacrificial material layer 421 can be physically exposed within each contact via opening 25 after performing the recess etch process.

A vertically-extending portion of the conformal silicon liner 121 is physically exposed in the upper region of each contact via opening 25. Thus, a cylindrical inner surface of a vertically-extending portion of the conformal silicon liner 121 can be physically exposed around each contact via opening 25 above a horizontal plane including a top surface of a respective first sacrificial material layer 421. Each remaining portion of the dielectric fill material layer 122L that remains within a lower portion of each contact via opening 25 comprises a finned dielectric material portion 122. Each finned dielectric material portion 122 is formed within a lower region of a respective contact via opening 25, and includes a vertical stack of annular dielectric fin portions 122F located in the annular cavities 251 at levels of the subset of the insulating layers 32. Thus, each finned dielectric material portion 122 comprises a vertical stack of annular dielectric fin portions 122F that fill annular cavities 251 formed by laterally recessing the sidewalls of the subset of the insulating layers 32. Each finned dielectric material portion 122 can be formed within a respective contact via opening 25 below a horizontal plane including the top surface of the first sacrificial material layer 421 for the contact via opening 25.

In one embodiment, each finned dielectric material portion 122 may comprise a contoured top surface. In one embodiment, a center point of the contoured top surface may be a lowest point of the contoured top surface, and the vertical distance between any arbitrarily selected point on the contoured top surface and a horizontal plane including a bottommost surface of the alternating stack (32, 42) increases with a radial distance from the center point to the arbitrarily selected point. In one embodiment, the contoured top surface may have an axial symmetry, and may be a vertically-convex and horizontally-concave surface that deviates from a conical surface due to presence of convexity.

Referring to FIG. 29E, a selective etch process can be performed to remove unmasked portions of the conformal silicon layer 121 selectively to the materials of the at least one retro-stepped dielectric material portion 65, the sacrificial material layers 42, and the finned dielectric material portions 122. An annular top surface of a first sacrificial material layer 421 can be physically exposed underneath a void within each contact via opening 25. As discussed above, the first sacrificial material layer 421 for each contact via opening 25 can be defined as the topmost sacrificial material layer 42 of the subset of the sacrificial material layers 42 that laterally surrounds, and defines the lateral boundary of, the contact via opening 25. The outer periphery of the annular top surface of the first sacrificial material layer 421 may be located within a respective first cylindrical vertical plane CVP1, and the inner periphery of the annular top surface of the first sacrificial material layer 421 may be located within a respective second cylindrical vertical plane CVP2.

Referring to FIG. 29F, a sacrificial fill material layer 124L can be conformally deposited in peripheral regions of the unfilled volumes of the contact via openings 25. The sacrificial fill material layer 124L comprises a material that may be subsequently removed selectively to the materials of the at least one retro-stepped dielectric material portion 65 and the insulating layers 32. In one embodiment, the sacrificial fill material layer 124L may comprise the same material as the sacrificial material layers 42. For example, the sacrificial fill material layer 124L and the sacrificial material layers 42 may comprise silicon nitride. The thickness of the sacrificial fill material layer 124L may be less than the lateral distance between an inner periphery and an outer periphery of a physically exposed annular top surface of a sacrificial material layer 42. For example, the thickness of the sacrificial fill material layer 124L may be in a range from 15 nm to 50 nm, such as from 20 nm to 30 nm, although lesser and greater thicknesses may also be employed.

Referring to FIG. 29G, an anisotropic etch process (such as a reactive ion etch process) can be performed to remove horizontally-extending portions of the sacrificial fill material layer 124L. Each remaining vertically-extending cylindrical portion of the sacrificial fill material layer 124L constitutes a sacrificial tubular structure 124. Generally, a sacrificial fill material can be conformally deposited in a peripheral region of each contact via opening 25, and horizontally-extending portions of the sacrificial fill material can be anisotropically etched. Each remaining vertically-extending portion of the sacrificial fill material comprises a sacrificial tubular structure 124. Each sacrificial tubular structure 124 can be formed in a peripheral region of a respective contact via opening 25 on a laterally recessed sidewall of the at least one retro-stepped dielectric material portion 65.

Referring to FIG. 29H, the anisotropic etch process can be continued to vertically recess top portions of the sacrificial tubular structures 124. The etch chemistry of the anisotropic etch process can be selected such that the anisotropic etch process etches the material of the sacrificial tubular structures 124 selectively to the material of the finned dielectric material portions 122. In one embodiment, the contact-level dielectric layer 80 overlies the alternating stack (32, 42) and the at least one retro-stepped dielectric material portion 65, and a topmost surface of each sacrificial tubular structure 124 can be formed below a horizontal plane including a top surface of the contact-level dielectric layer 80 after performing the anisotropic etch process. In one embodiment, a topmost surface of each sacrificial tubular structure 124 may be formed above the horizontal plane including the topmost surface of the at least one retro-stepped dielectric material portion 65.

In one embodiment, each sacrificial tubular structure 124 may comprise a straight outer cylindrical sidewall and a contoured inner cylindrical sidewall. In one embodiment, the lateral distance between the straight outer cylindrical sidewall and the contoured inner cylindrical sidewall may decrease as a function of a vertical distance from a horizontal plane including a bottommost surface of the alternating stack (32, 42) in a top portion of each sacrificial tubular structure 124.

Referring to FIG. 29I, a conformal etch-stop layer 125 can be deposited over the sacrificial tubular structures 124 and the finned dielectric material portions 122. The conformal etch-stop layer 125 comprises a dielectric material, such as silicon oxide or a dielectric metal oxide material. The thickness of the conformal etch-stop layer 125 may be in a range from 2 nm to 30 nm, such as from 5 nm to 20 nm, although lesser and greater thicknesses may also be employed.

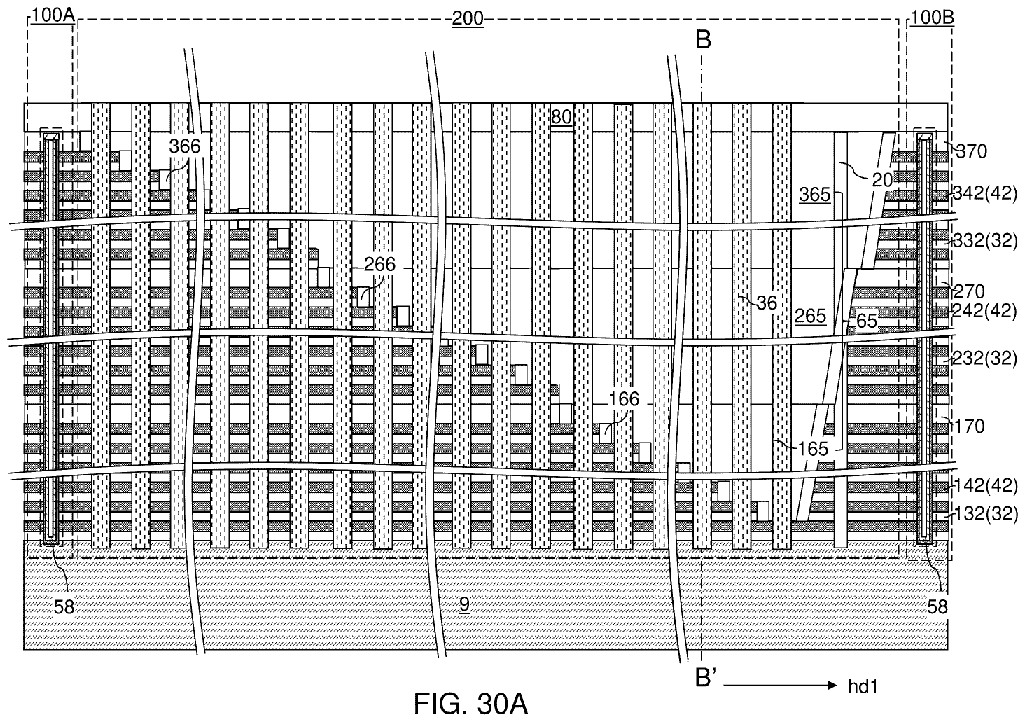

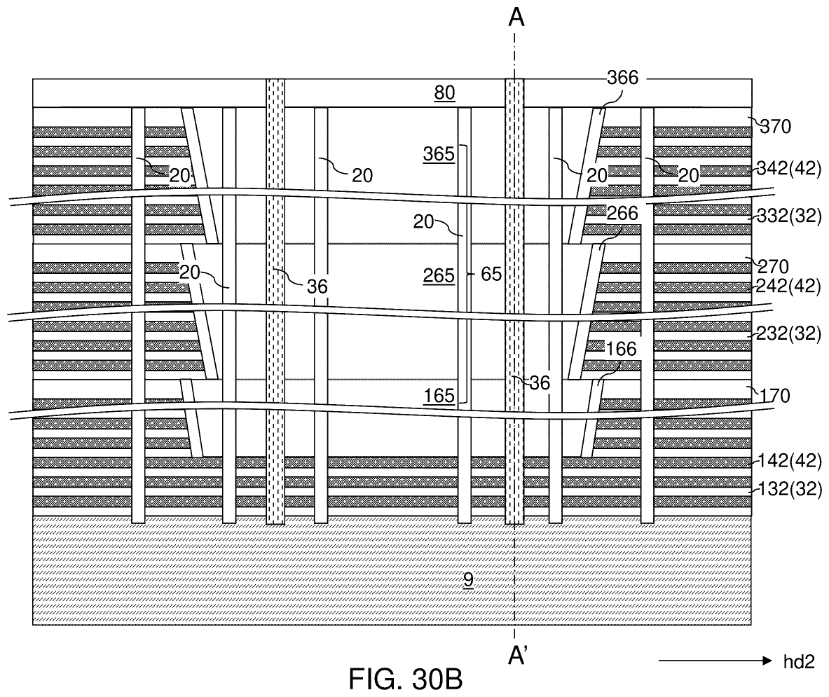

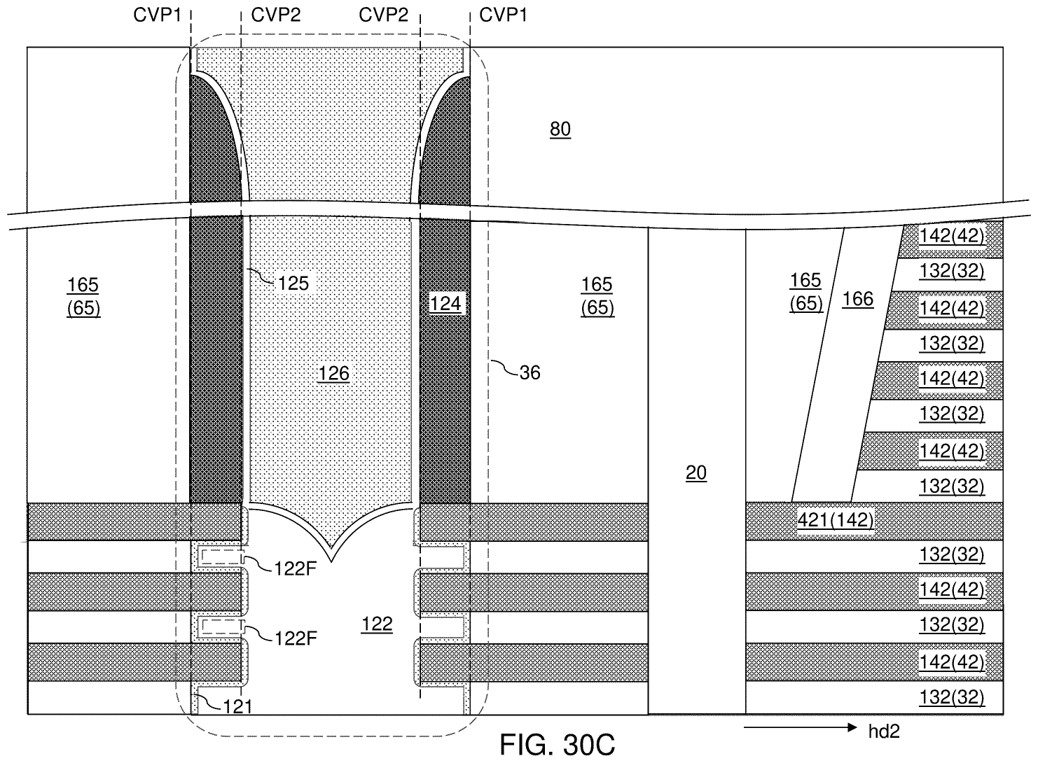

Referring to FIGS. 30A-30C, a sacrificial fill material can be deposited over the conformal etch-stop layer 125 within the voids laterally surrounded by the sacrificial tubular structures 124. The sacrificial fill material comprises a different material than that materials of the insulating layers 32, the sacrificial material layers 42, and the at least one retro-stepped dielectric material portion 65. For example, the sacrificial fill material may comprise a semiconductor material such as silicon (e.g., amorphous silicon), silicon-germanium, or another compound semiconductor material. Excess portions of the sacrificial fill material can be removed from above the horizontal plane including the top surface of the contact-level dielectric layer 80 by performing a planarization process. The planarization process may comprise a chemical mechanical polishing process and/or a recess etch process. Each remaining portion of the sacrificial fill material comprises a sacrificial via fill material portion 126, as shown in FIG. 30C. In one embodiment, the sacrificial via fill material portions 126 may have top surfaces within the horizontal plane including the top surface of the contact-level dielectric layer 80.

Each contiguous combination of material portions that fill the volume of a contact via opening 25 constitutes an in-process contact-via-region assembly 36. In one embodiment, each in-process contact-via-region assembly 36 comprises a finned dielectric material portion 122, an optional conformal silicon liner 121, a sacrificial tubular structure 124, a conformal etch-stop layer 125, and a sacrificial via fill material portion 126. The structure may be annealed to crystallize amorphous silicon conformal silicon liner 121 and sacrificial via fill material portion 126 into intrinsic polysilicon conformal silicon liner 121 and sacrificial via fill material portion 126,

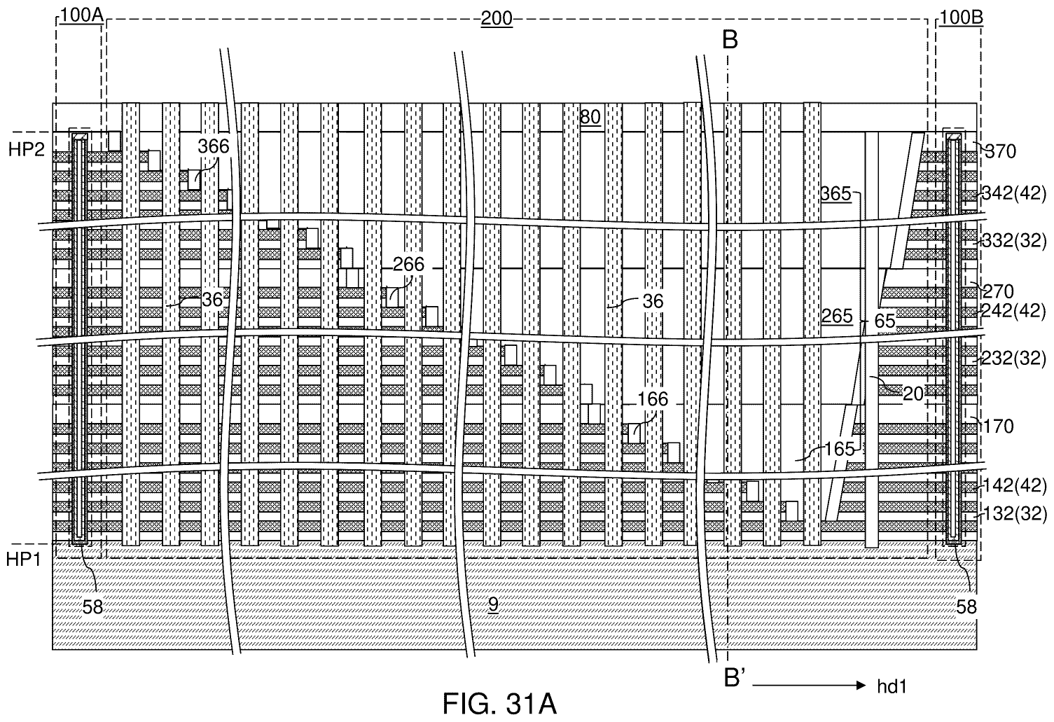

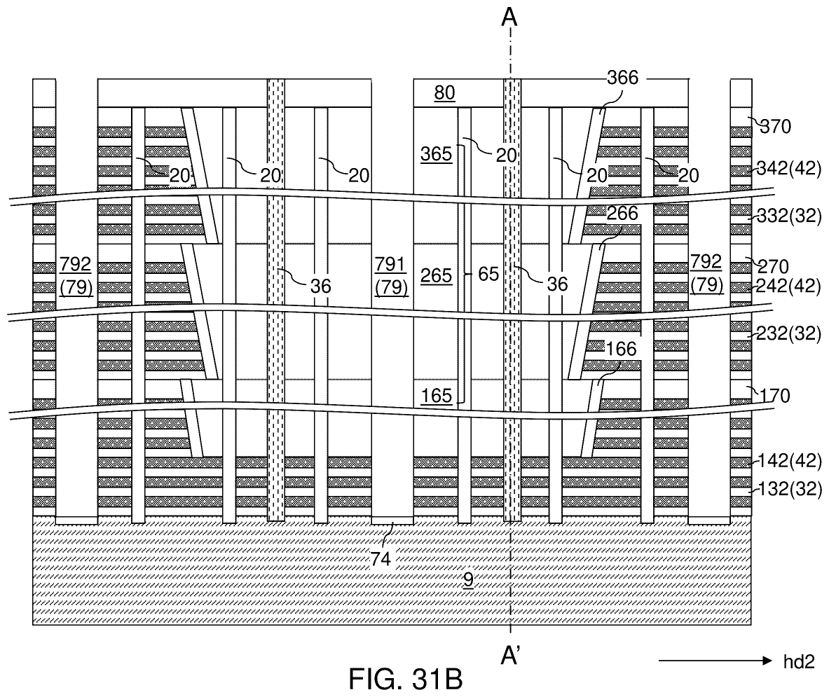

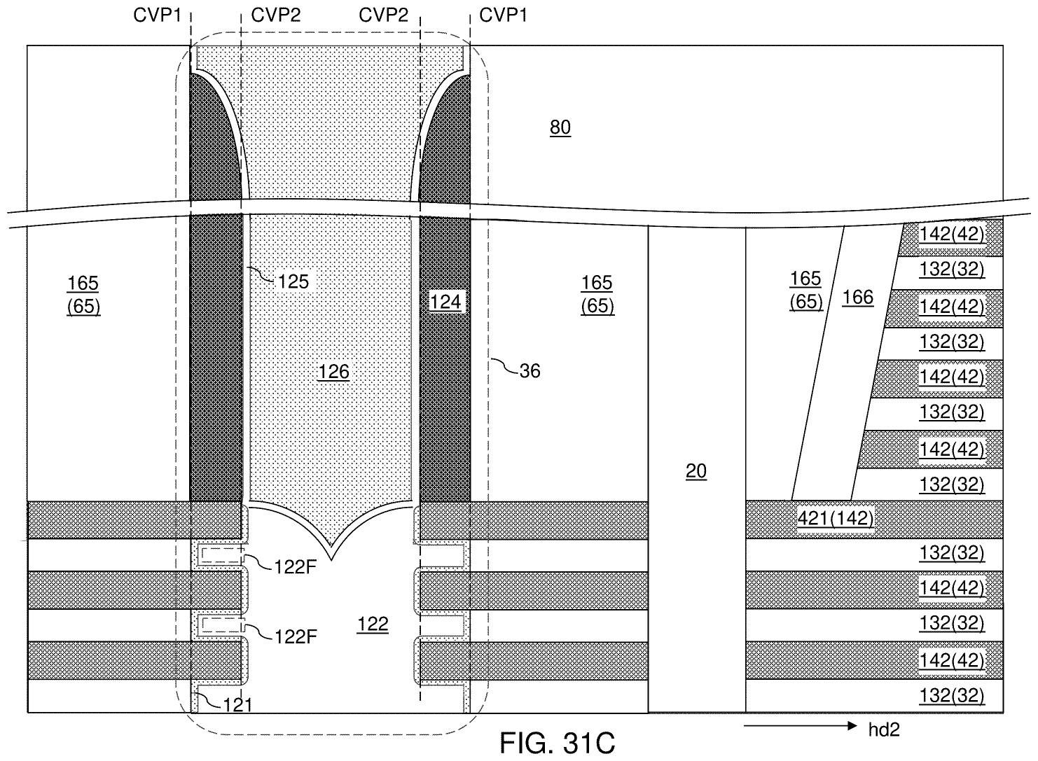

Referring to FIGS. 31A-31C, the processing steps described with respect to FIGS. 18A-18C can be performed to form lateral isolation trenches 79 through the contact-level dielectric layer 80, the alternating stack (32, 42), and the at least one retro-stepped dielectric material portion 65. Semiconductor oxide spacer liners 74 may be formed at the bottom of each lateral isolation trench 79.

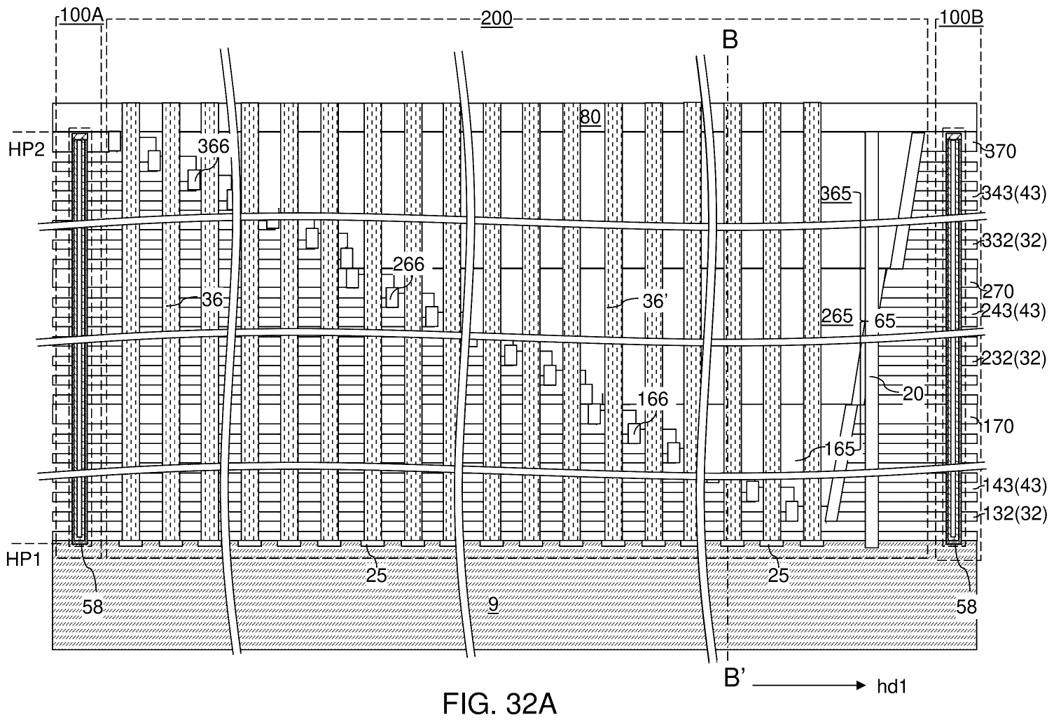

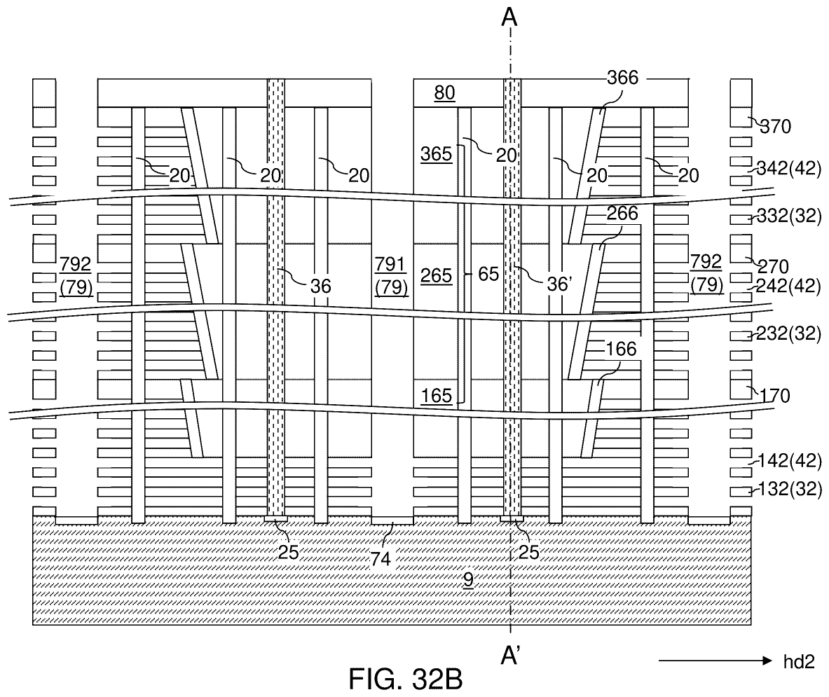

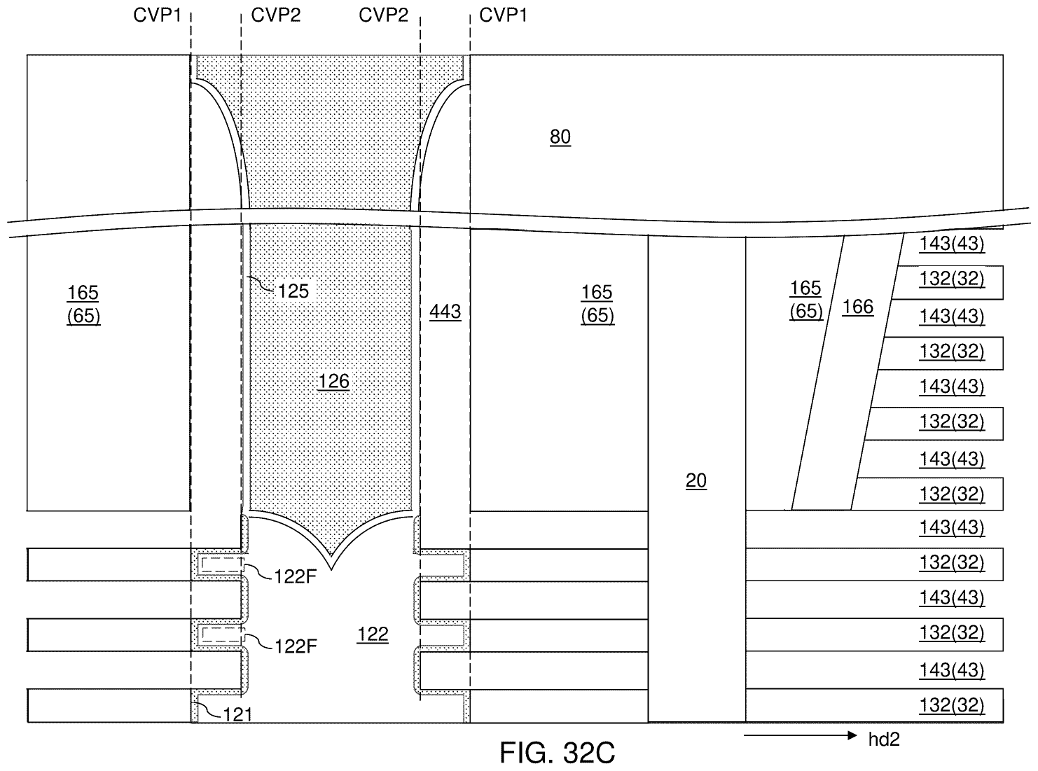

Referring to FIGS. 32A-32C, the processing steps described with respect to FIGS. 19A-19C can be performed to remove the sacrificial material layers 42 and the sacrificial tubular structures 124. Specifically, a selective isotropic etch process can be performed to etch the materials of the sacrificial material layers 42 and the sacrificial tubular structures 124 selectively to the materials of the insulating layers 32, the at least one retro-stepped dielectric material portion 65, the conformal silicon liner 121, and the conformal etch-stop layer 125. If the sacrificial material layers 42 and the sacrificial tubular structures 124 comprise silicon nitride, then the selective isotropic etch process may comprise a hot phosphoric acid etch process which selectively etches silicon nitride relative to intrinsic polysilicon conformal silicon liner 121 and sacrificial via fill material portion 126.

Lateral recesses 43 are formed in the volumes from which the sacrificial material layers 42 are removed, and vertically-extending tubular cavities 443 are formed in the volumes from which the sacrificial tubular structures 124 are removed. Thus, voids (43, 443) are formed in volumes from which the sacrificial material layers 42 and the sacrificial tubular structure 124 are removed. In one embodiment, each sacrificial material layer 42 may be adjoined to a respective sacrificial tubular structure 124, and a void (43, 443) including a contiguous combination of a lateral recess 43 and a vertically-extending tubular cavity 443 can be formed in each volume from which a sacrificial material layer 42 and a sacrificial tubular structure 124 are removed.

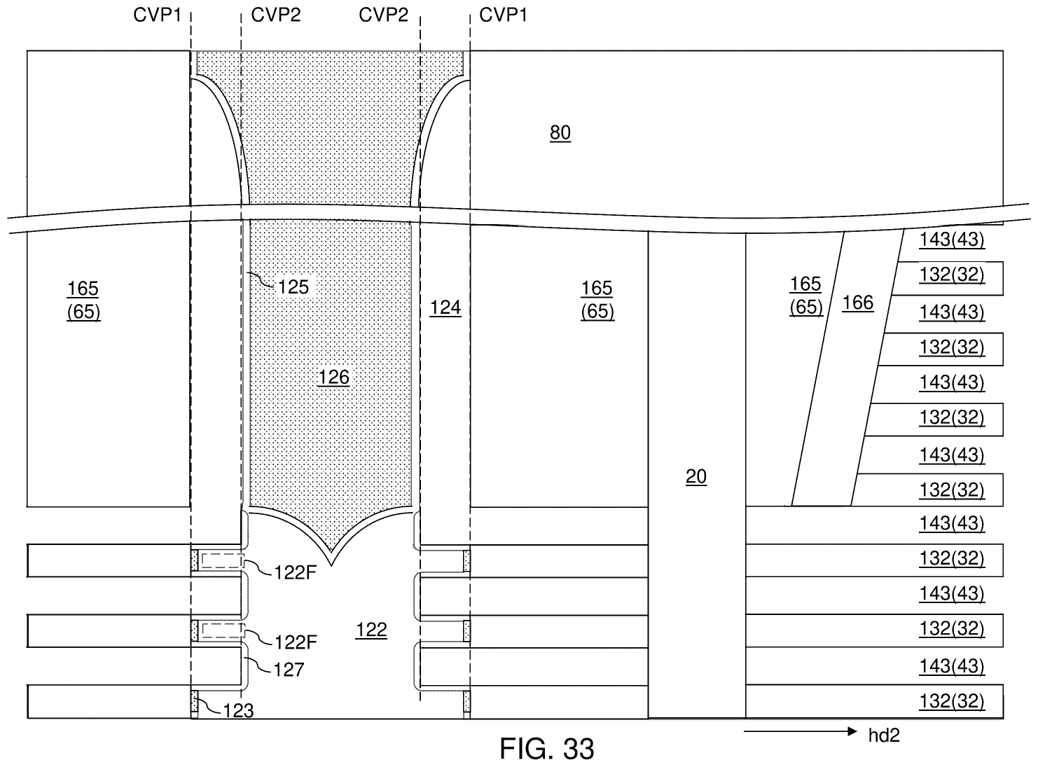

Referring to FIG. 33, a thermal oxidation process can be performed to convert portions of the conformal silicon liner121 that are exposed to the lateral recesses 43 into silicon oxide liners 127. Each of the silicon oxide liners 127 may be formed at a boundary of a respective one of the lateral recesses 43, and laterally surrounds and contacts a respective one of the finned dielectric material portions 122. Each remaining portion of the conformal silicon liner 121 constitutes a tubular silicon portion 123 that contacts a cylindrical sidewall of a respective insulating layer 32. In one embodiment, a vertical stack of tubular silicon portions 123 can be formed at the levels of a subset of the insulating layers 32 around each finned dielectric material portion 122. The vertical stack of tubular silicon portions 123 may be located between the finned dielectric material portion 122 and the subset of the insulating layers 32.

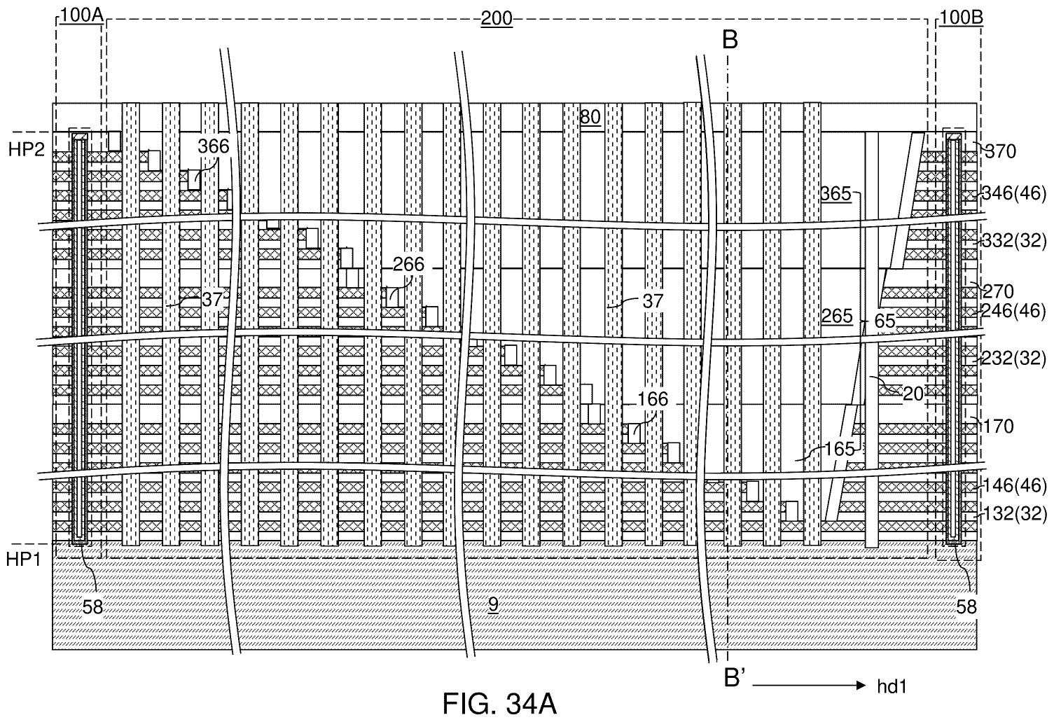

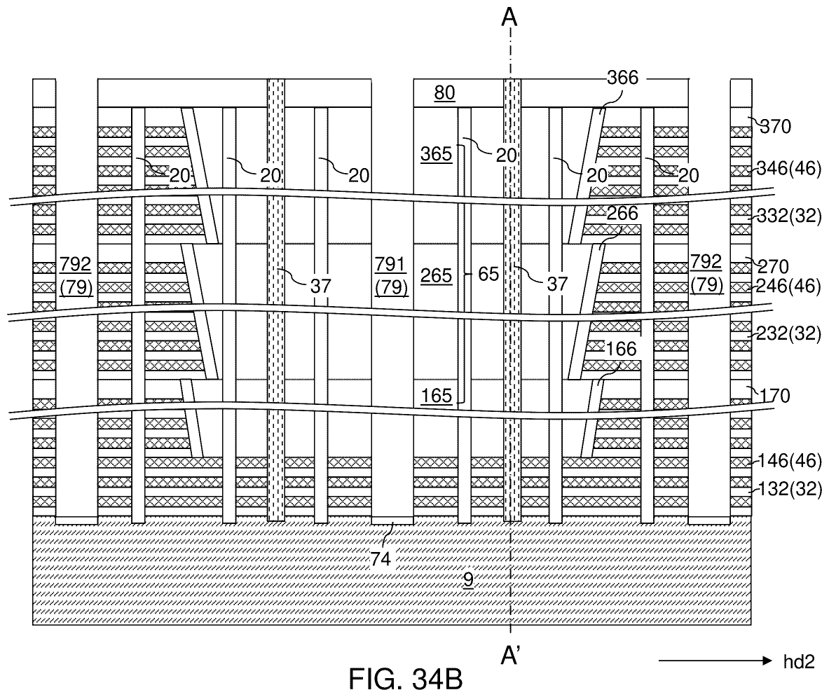

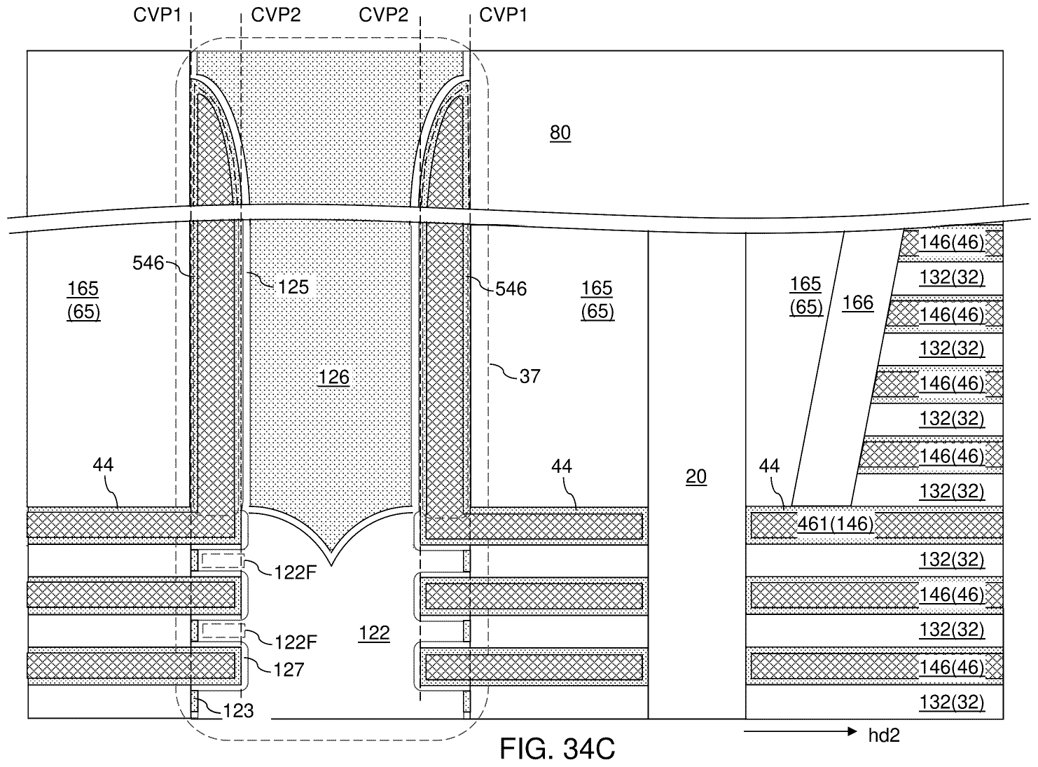

Referring to FIGS. 34A-34C, the processing steps described with reference to FIGS. 20A-20C can be subsequently performed. A combination of an outer blocking dielectric layer 44 and a respective one of the electrically conductive layers 46 can be formed in each of the voids (43, 443). The sacrificial material layers 42 and the sacrificial tubular structure 124 can be replaced with material portions comprising outer blocking dielectric layers 44 and electrically conductive layers 46 containing vertically-extending tubular portions 546. For each contact via opening 25 having a respective first sacrificial material layer 421 and a sacrificial tubular structure 124 thereabout, a combination of the first sacrificial material layer 421 and the sacrificial tubular structure 124 is replaced with material portions comprising a first electrically conductive layer 461 having the vertically-extending tubular portion 546. Each electrically conductive layer 46 can be a first electrically conductive layer 461 for a respective one of the contact via openings 25.

Each contact via opening 25 vertically extends through a respective subset of the electrically conductive layers 46 and a respective subset of the insulating layers 32. A topmost layer within the subset of the electrically conductive layers 46 comprises a first electrically conductive layer 461 for the contact via opening 25. The first electrically conductive layer 461 comprises a horizontally-extending portion that is located outside a volume of the contact via opening 25 and further comprises the vertically-extending tubular portion 546 located in a peripheral region of the contact via opening 25 and adjoined to the horizontally-extending portion. In one embodiment, each of the electrically conductive layers 46 is spaced from a most proximal one of the insulating layers 32 by a respective outer blocking dielectric layer 44.

In one embodiment, the vertically-extending tubular portion 546 of the first electrically conductive layer 461 is laterally spaced from the at least one retro-stepped dielectric material portion 65 by a tubular portion of a first outer blocking dielectric layer 44 of the outer blocking dielectric layers 44. In one embodiment, the vertically-extending tubular portion 546 of each electrically conductive layer 46 comprises a straight outer cylindrical sidewall and a contoured inner cylindrical sidewall. In one embodiment, a lateral distance between the straight outer cylindrical sidewall and the contoured inner cylindrical sidewall decreases as a function of a vertical distance from a horizontal plane including a bottommost surface of the alternating stack (32, 46) in a top portion of the vertically-extending tubular portion 546. Each contiguous combination of material portions that fill the volume of a contact via opening 25 constitutes a contact-via-region assembly 37.

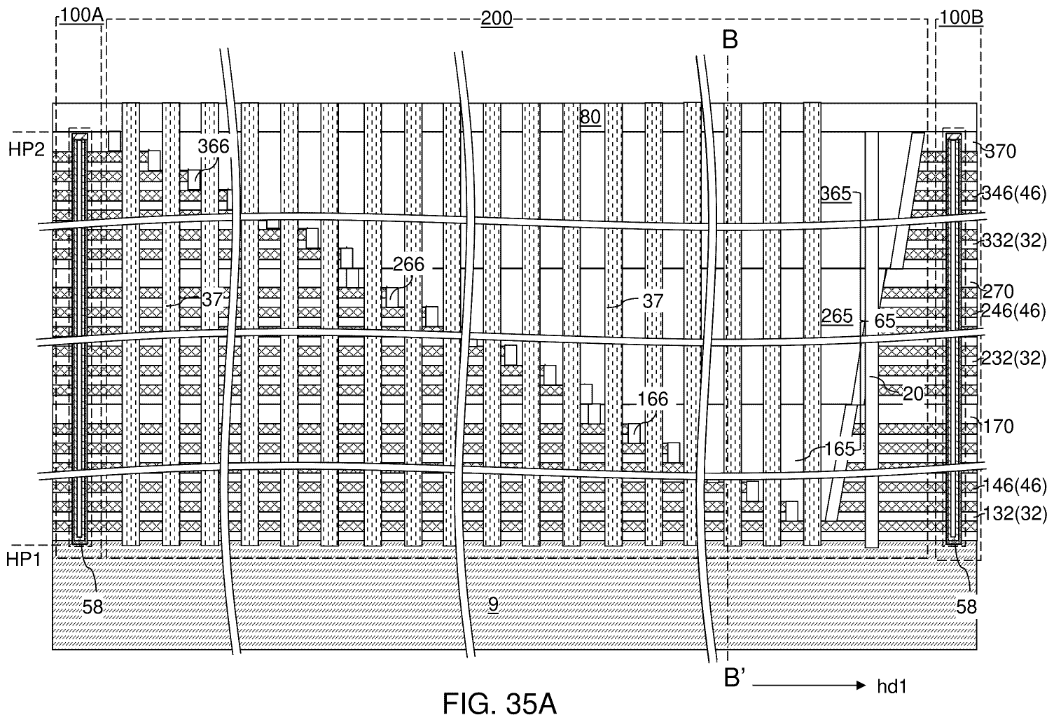

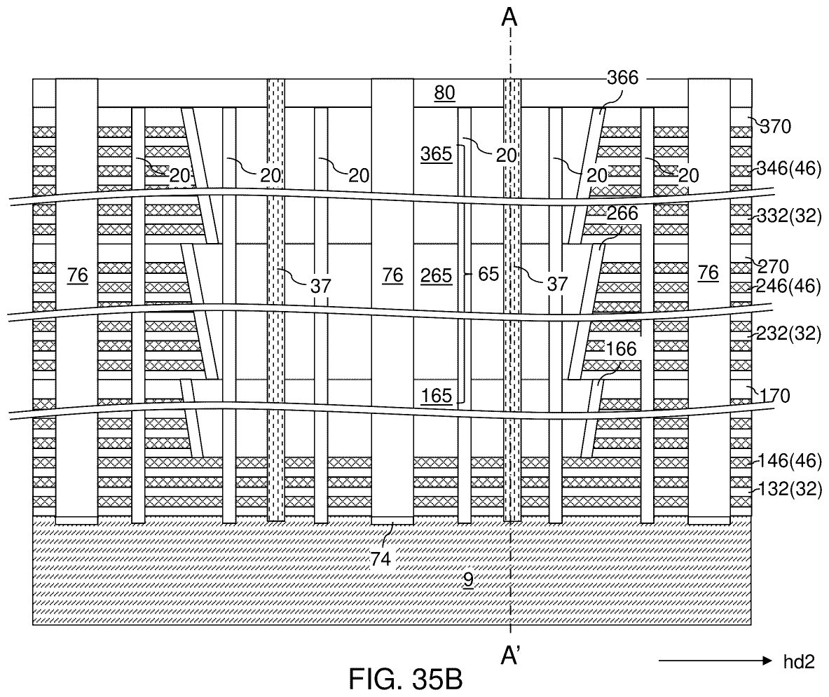

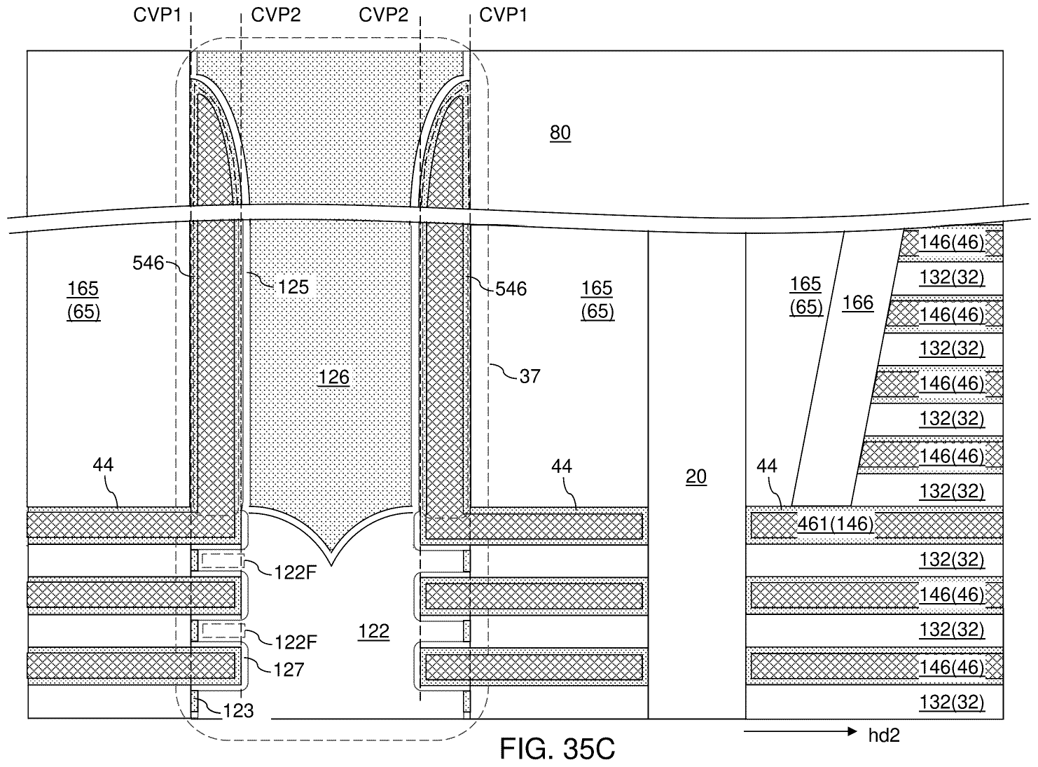

Referring to FIGS. 35A-35C, the processing steps described with reference to FIGS. 21A-21C can be performed to form lateral isolation trench fill structures 76 in the lateral isolation trenches 79.

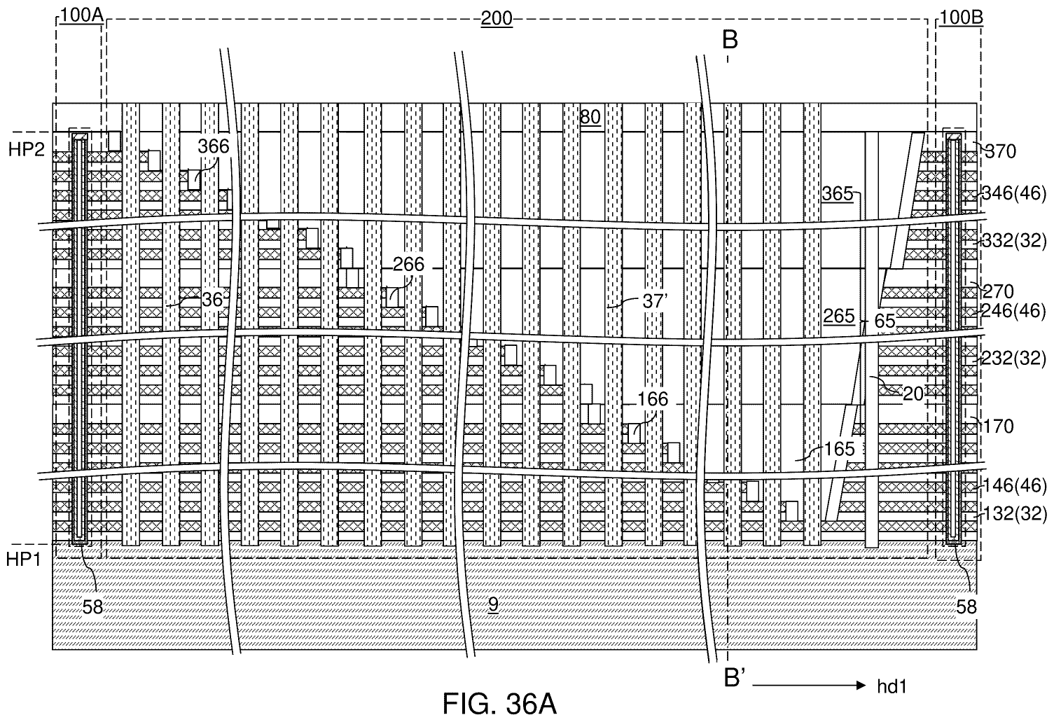

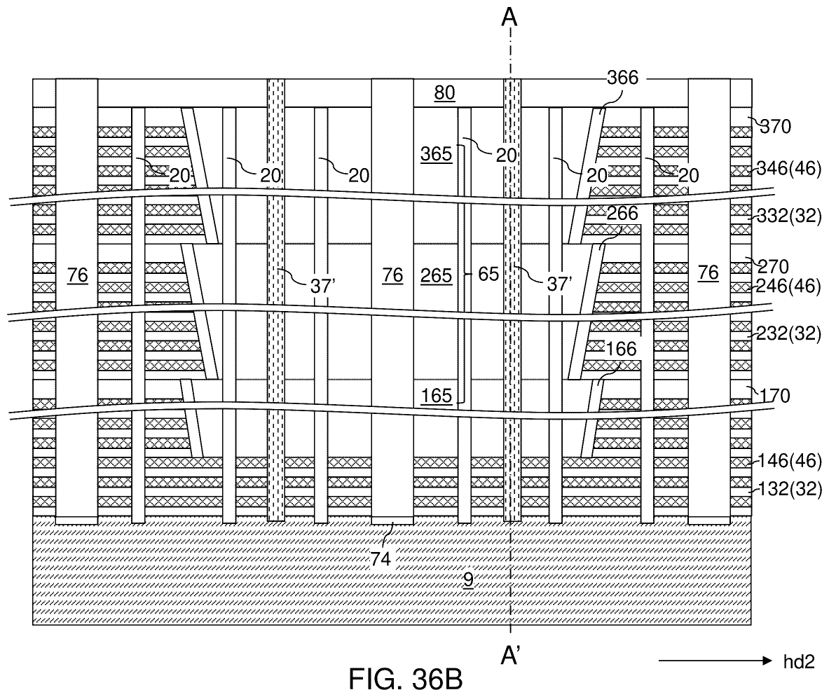

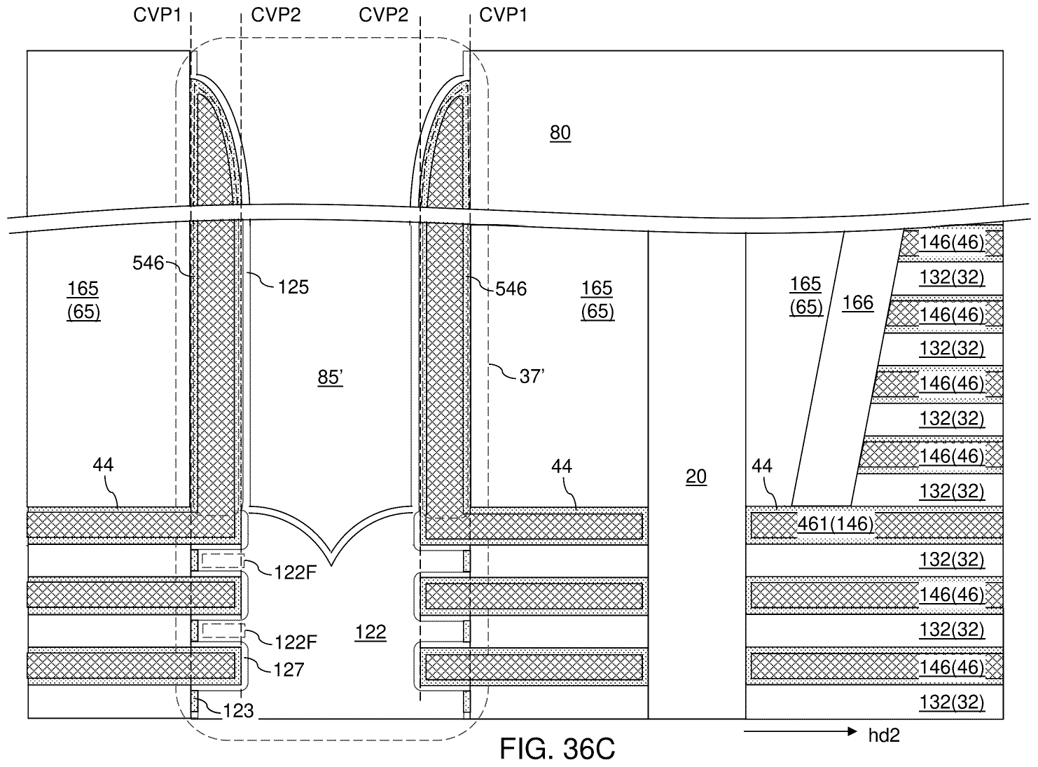

Referring to FIGS. 36A-36C, the sacrificial via fill material portions 126 can be removed selectively to the conformal etch-stop layer 125 by performing a selective etch process. For example, if the sacrificial via fill material portions 126 comprise a semiconductor material such as silicon, a wet etch process using hot trimethyl-2 hydroxyethyl ammonium hydroxide (“hot TMY”) or tetramethyl ammonium hydroxide (TMAH) may be performed to remove the sacrificial via fill material portions 126 selectively to the conformal etch-stop layer 125. Voids 85′ are formed in the volumes from which the sacrificial via fill material portions 126 are removed. Each contiguous combination of material portions that fill the volume of a contact via opening 25 after removal of the sacrificial via fill material portions 126 constitutes a modified contact-via-region assembly 37′.

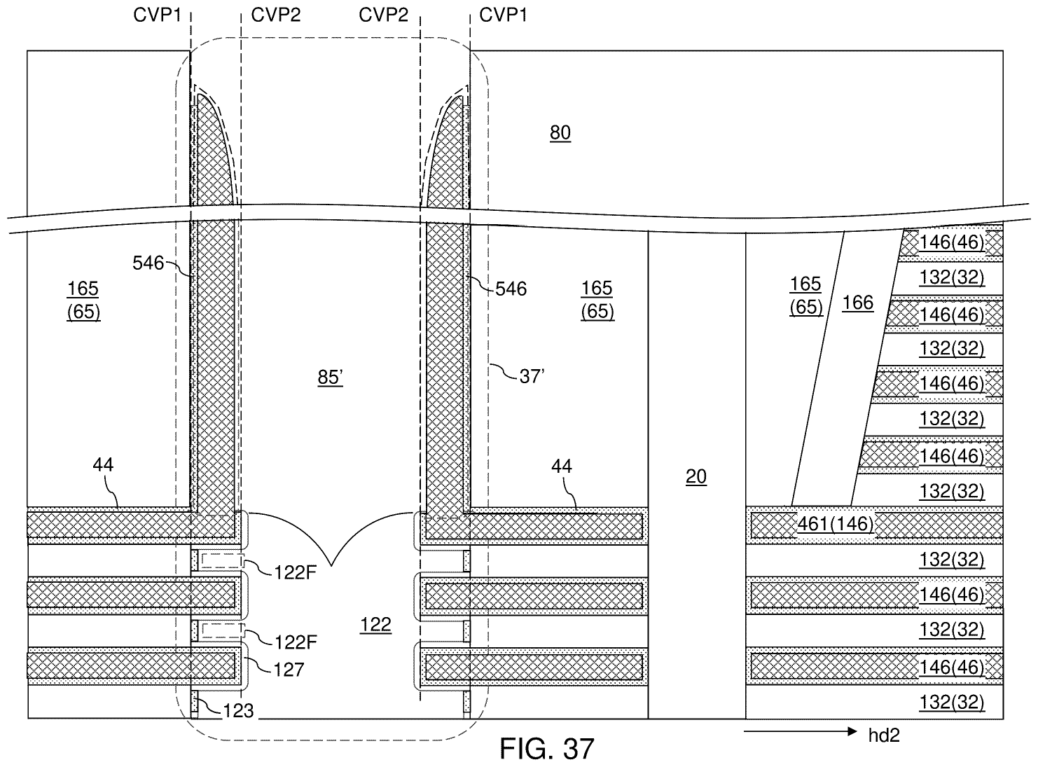

Referring to FIG. 37, the conformal etch-stop layer 125 can be subsequently removed by performing a first selective etch process. Subsequently, physically exposed portions of the outer blocking dielectric layer 44 can be removed by performing a second selective etch process. Each inner cylindrical sidewall of the vertically-extending tubular portions 546 of the electrically conductive layers 46 can be physically exposed around the voids 85′ within the contact via openings 25.

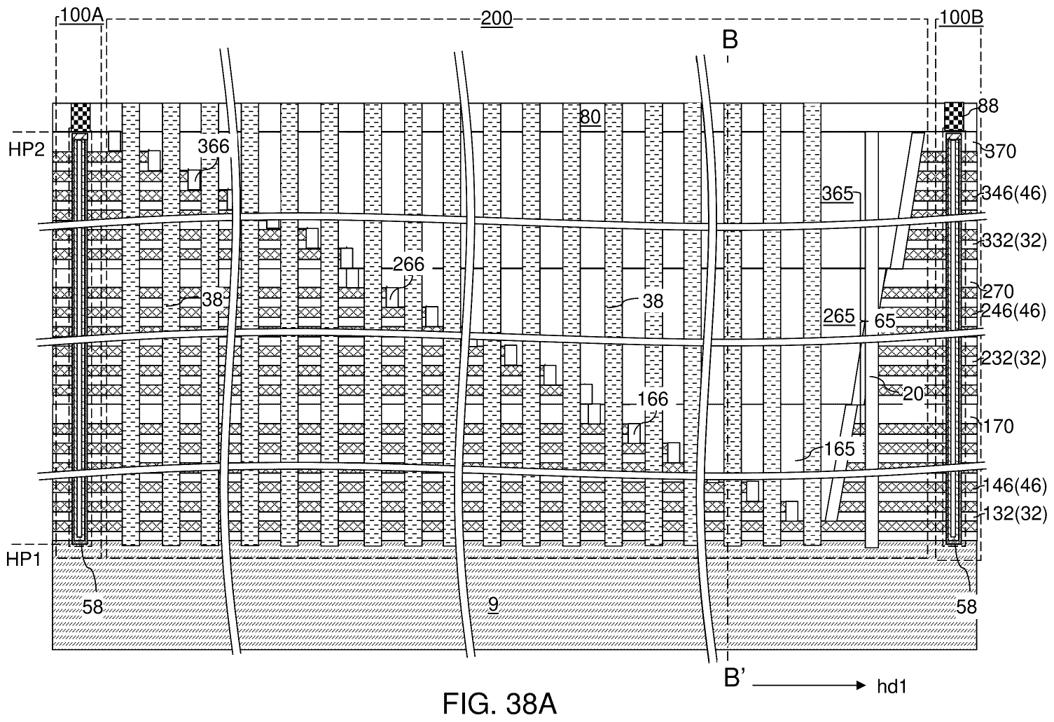

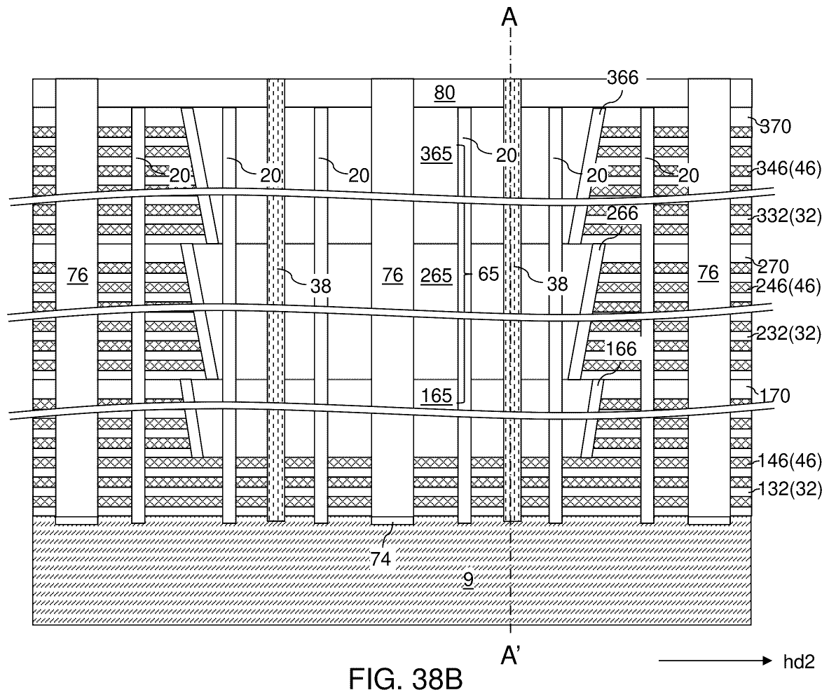

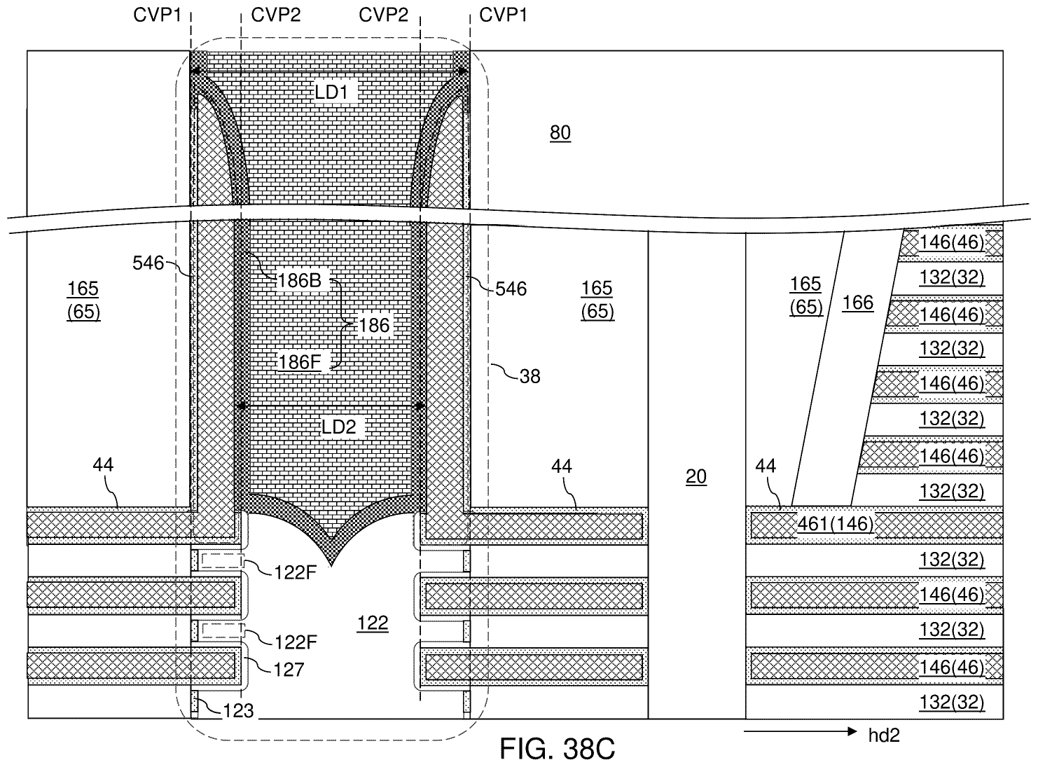

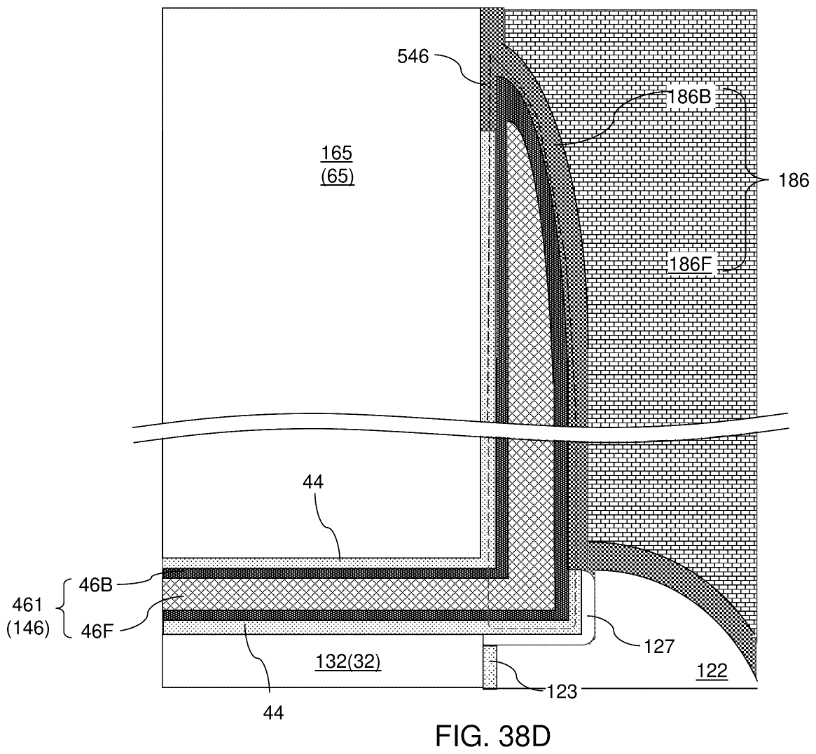

Referring to FIGS. 38A-38D, at least one electrically conductive material can be deposited in the voids 85′ formed by removal of the sacrificial via fill material portions 126, the conformal etch-stop layer 125, and portions of the outer blocking dielectric layer 44. The at least one electrically conductive material can be deposited in the voids 85′ directly on the inner cylindrical sidewalls of the vertically-extending tubular portions 546 of the electrically conductive layers 46. Excess portions of the at least one electrically conductive material can be removed from above the horizontal plane including the top surface of the contact-level dielectric layer 80. Each remaining portion of the at least one electrically conductive material that fills the upper part of the contact via opening 25 constitutes a layer contact via structure 186. Each layer contact via structure 186 contacts the respective first electrically conductive layer 461 of the electrically conductive layers 46.

In one embodiment, the at least one electrically conductive material may comprise a metallic barrier material and a metal fill material. In this case, each tubular layer contact via structure 86 may comprise a metallic barrier liner 86B and a metal fill material portion 86F that is laterally surrounded by the metallic barrier liner 86B. The metallic barrier liner 86B comprises the metallic barrier material. The metallic barrier material comprises a metallic diffusion barrier material. For example, the metallic barrier material comprises a conductive metallic nitride material such as TiN, TaN, WN, and/or MoN. The metallic barrier material may be deposited as a continuous material layer having a uniform thickness throughout by a conformal deposition process such as a chemical vapor deposition process. The thickness of the metallic barrier material may be in a range from 3 nm to 30 nm, such as from 6 nm to 20 nm, although lesser and greater thicknesses may also be employed. In one embodiment, the metallic barrier liner 86B of each tubular layer contact via structure 186 contacts an entirety of an inner sidewall of the vertically-extending tubular portions 546 of an electrically conductive layers 46.

The metal fill material portion 86F is embedded within the metallic barrier liner 86B and is spaced from the first electrically conductive layer 461 and from the retro-stepped dielectric material portion 65 by the metallic barrier liner 86B. The metal fill material portion 86F comprises a metal fill material (such as W, Ti, Ta, Co, Ru, Mo, Cu, etc.)

In summary, a layer contact via structure 186 can be formed on an inner-sidewall of a vertically-extending tubular portion 546 of the first electrically conductive layer 461. In one embodiment, the layer contact via structure 186 can be located in a center region of the contact via opening 25 and contacting an inner sidewall of the vertically-extending tubular portion 546. In one embodiment, the layer contact via structure 186 comprises a tapered portion located between the upper portion and the lower portion and having a variable lateral extent that increases with a vertical distance from a horizontal plane including a bottommost surface of the alternating stack (32, 46). In one embodiment, the layer contact via structure 186 comprises a contoured bottom surface having an inverted concave conical profile.

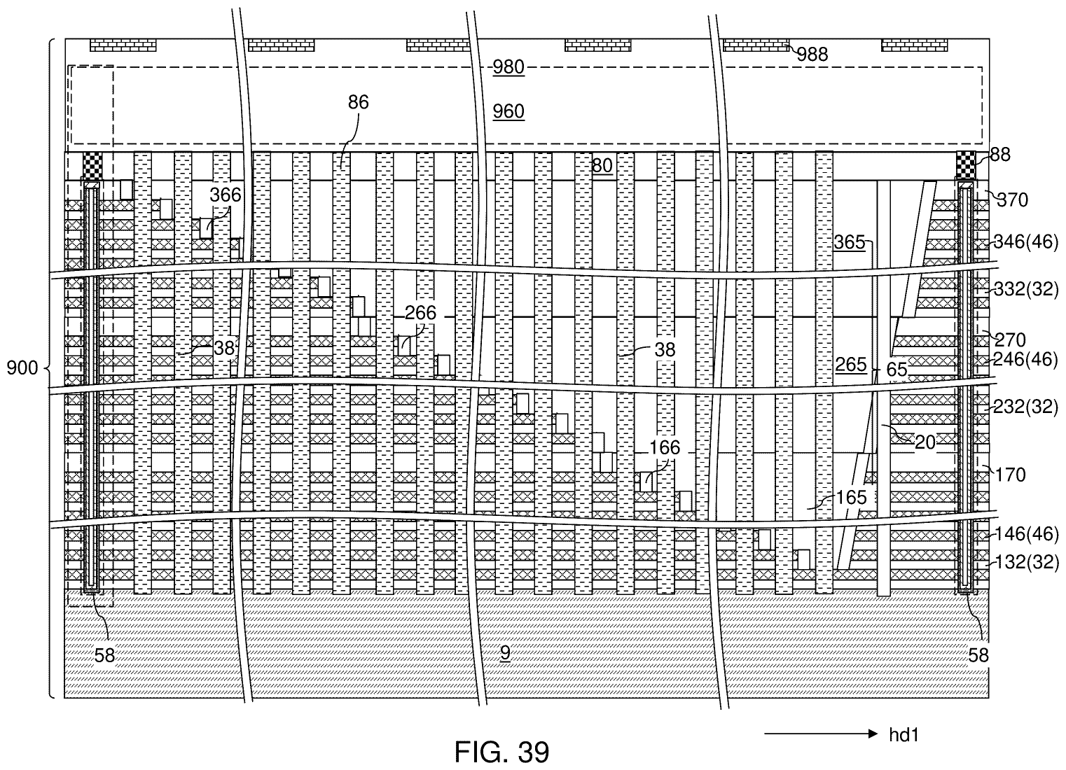

Referring to FIG. 39, the processing steps described with reference to FIG. 24 can be performed to form a memory die.

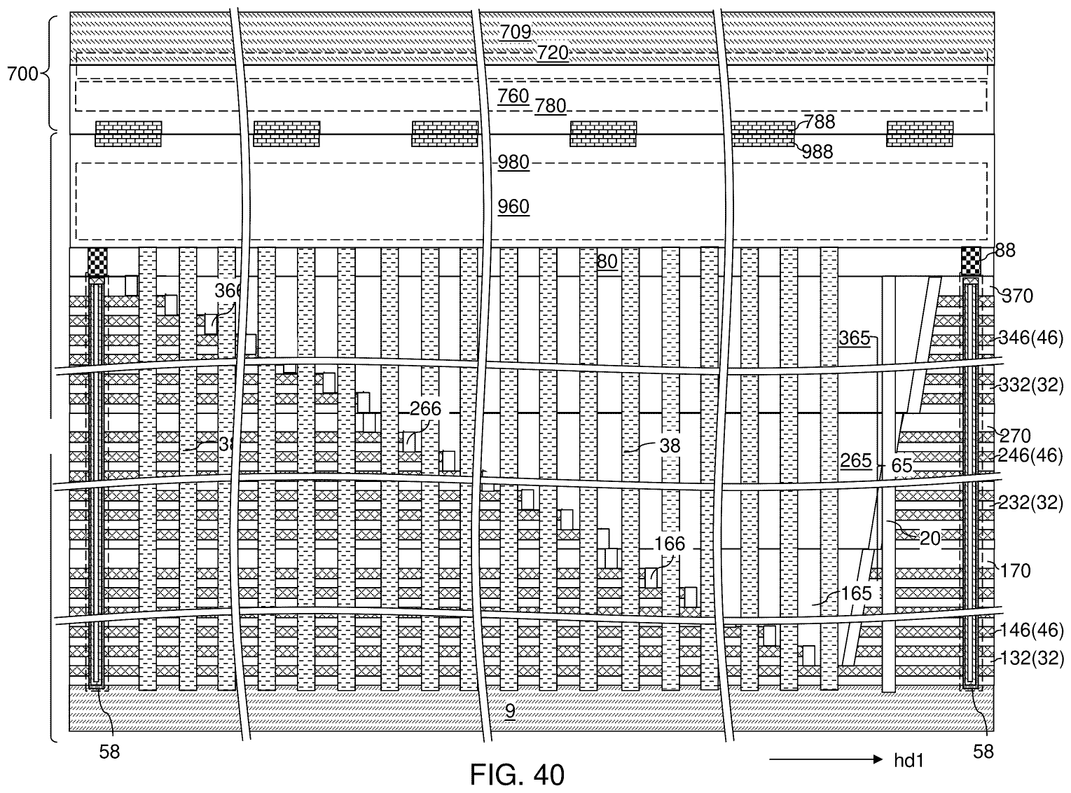

Referring to FIG. 40, the processing steps described with reference to FIG. 25 can be performed to bond the memory die 900 to a logic die 700.

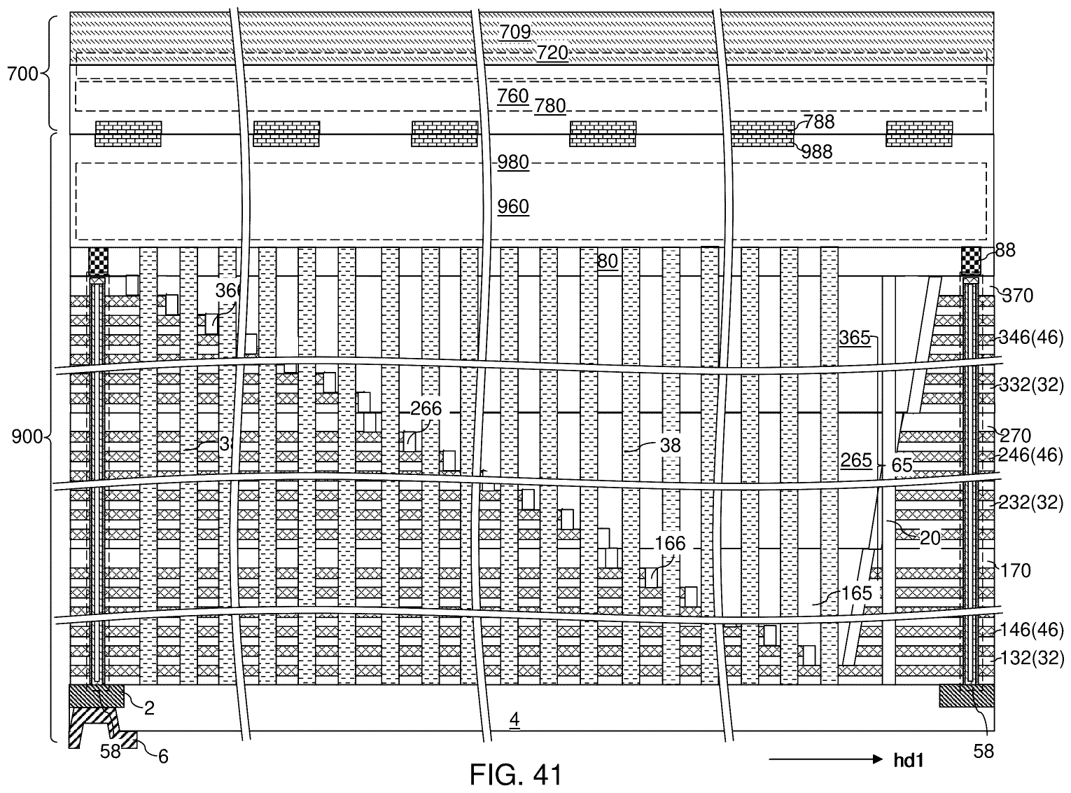

Referring to FIG. 41, the processing steps described with reference to FIG. 26 can be performed to remove a carrier substrate and to form source-side structures.

Referring collectively to FIGS. 27A-41 and related drawings and according to various embodiments of the present disclosure, a device structure comprises: an alternating stack (32, 46) of insulating layers 32 and electrically conductive layers 46; a memory stack structure 55 vertically extending through the alternating stack (32, 46) and comprising a vertical semiconductor channel 60 and a vertical stack of memory elements (comprising portions of a memory material layer 54); a contact via opening 25 vertically extending through a subset of the electrically conductive layers 46 and a subset of the insulating layers 32, wherein a topmost layer within the subset of the electrically conductive layers 46 comprises a first electrically conductive layer 461, and the first electrically conductive layer 461 comprises a horizontally-extending portion that is located outside a volume of the contact via opening 25 and further comprises a vertically-extending tubular portion 546 located in a peripheral region of the contact via opening 25 and adjoined to the horizontally-extending portion; and a layer contact via structure 186 located in a center region of the contact via opening 25 and contacting an inner sidewall of the vertically-extending tubular portion 546.

In one embodiment, the device structure comprises a retro-stepped dielectric material portion 65 having a stepped bottom surface and overlying a region of the alternating stack (32, 46) in which the electrically conductive layers 46 have variable lateral extents, wherein the contact via opening 25 vertically extends through the retro-stepped dielectric material portion 65. In one embodiment, the device structure comprises a contact-level dielectric layer 80 overlying the alternating stack (32, 46) and the retro-stepped dielectric material portion 65, wherein a topmost surface of the vertically-extending tubular portion 546 is located below a horizontal plane including a top surface of the contact-level dielectric layer 80. In one embodiment, a topmost surface of the vertically-extending tubular portion 546 is located above a horizontal plane including a top surface of the retro-stepped dielectric material portion 65.

In one embodiment, each of the electrically conductive layers 46 is spaced from a most proximal one of the insulating layers 32 by a respective outer blocking dielectric layer 44. In one embodiment, the vertically-extending tubular portion of the first electrically conductive layer 461 is laterally spaced from the retro-stepped dielectric material portion 65 by a tubular portion of a first outer blocking dielectric layer 44 of the outer blocking dielectric layers 44.

In one embodiment, the layer contact via structure 186 comprises: an upper portion that overlies the vertically-extending tubular portion 546 and having a first lateral extent; and a lower portion that is laterally surrounded by the vertically-extending tubular portion 546 and having a second lateral extent that is less than the first lateral extent. In one embodiment, the vertically-extending tubular portion 546 comprises a straight outer cylindrical sidewall and a contoured inner cylindrical sidewall; and a lateral distance between the straight outer cylindrical sidewall and the contoured inner cylindrical sidewall decreases as a function of a vertical distance from a horizontal plane including a bottommost surface of the alternating stack (32, 46). In one embodiment, the layer contact via structure 186 comprises a tapered portion located between the upper portion and the lower portion and having a variable lateral extent that increases with a vertical distance from a horizontal plane including a bottommost surface of the alternating stack (32, 46).

In one embodiment, layer contact via structure 186 comprises a contoured bottom surface having an inverted concave conical profile. In one embodiment, the device structure comprises a finned dielectric material portion 122 located within a lower region of the contact via opening 25 and including a vertical stack of annular dielectric fin portions 122F at levels of the subset of the insulating layers 32. In one embodiment, the device structure comprises a vertical stack of silicon oxide liners 127 located at levels of the subset of the electrically conductive layers 46 and laterally surrounding the finned dielectric material portion 122, wherein the subset of the electrically conductive layers 46 is laterally spaced from the finned dielectric material portion 122 by the vertical stack of silicon oxide liners 127.

In one embodiment, the device structure comprises a vertical stack of tubular silicon portions 123 located at the levels of the subset of the insulating layers 32 and interposed between the finned dielectric material portion 122 and the subset of the insulating layers 32. In one embodiment, the finned dielectric material portion 122 comprises a contoured top surface; a center point of the contoured top surface is a lowest point of the contoured top surface; and a vertical distance between any arbitrarily selected point on the contoured top surface and a horizontal plane including a bottommost surface of the alternating stack (32, 46) increases with a radial distance from the center point to the arbitrarily selected point.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
an alternating stack of insulating layers and electrically conductive layers;
a memory stack structure vertically extending through the alternating stack and comprising a vertical semiconductor channel and a vertical stack of memory elements;
a contact via opening vertically extending through a subset of the electrically conductive layers and a subset of the insulating layers, wherein a topmost layer within the subset of the electrically conductive layers comprises a first electrically conductive layer, and the first electrically conductive layer comprises a horizontally-extending portion that is located outside a volume of the contact via opening and further comprises a vertically-extending tubular portion located in a peripheral region of the contact via opening and adjoined to the horizontally-extending portion; and
a layer contact via structure located in a center region of the contact via opening and contacting an inner sidewall of the vertically-extending tubular portion.

2. The device structure of claim 1, further comprising a retro-stepped dielectric material portion having a stepped bottom surface and overlying a region of the alternating stack in which the electrically conductive layers have variable lateral extents, wherein the contact via opening vertically also extends through the retro-stepped dielectric material portion.

3. The device structure of claim 2, further comprising a contact-level dielectric layer overlying the alternating stack and the retro-stepped dielectric material portion, wherein a topmost surface of the vertically-extending tubular portion is located below a horizontal plane including a top surface of the contact-level dielectric layer.

4. The device structure of claim 2, wherein a topmost surface of the vertically-extending tubular portion is located above a horizontal plane including a top surface of the retro-stepped dielectric material portion.

5. The device structure of claim 2, wherein each of the electrically conductive layers is spaced from a most proximal one of the insulating layers by a respective outer blocking dielectric layer.

6. The device structure of claim 5, wherein the vertically-extending tubular portion of the first electrically conductive layer is laterally spaced from the retro-stepped dielectric material portion by a tubular portion of a first outer blocking dielectric layer of the outer blocking dielectric layers.

7. The device structure of claim 1, wherein the layer contact via structure comprises:
an upper portion that overlies the vertically-extending tubular portion and having a first lateral extent; and
a lower portion that is laterally surrounded by the vertically-extending tubular portion and having a second lateral extent that is less than the first lateral extent.

8. The device structure of claim 7, wherein:
the vertically-extending tubular portion comprises a straight outer cylindrical sidewall and a contoured inner cylindrical sidewall; and
a lateral distance between the straight outer cylindrical sidewall and the contoured inner cylindrical sidewall decreases as a function of a vertical distance from a horizontal plane including a bottommost surface of the alternating stack.

9. The device structure of claim 7, wherein the layer contact via structure comprises a tapered portion located between the upper portion and the lower portion and having a variable lateral extent that increases with a vertical distance from a horizontal plane including a bottommost surface of the alternating stack.

10. The device structure of claim 1, wherein the layer contact via structure comprises a contoured bottom surface having an inverted concave conical profile.

11. The device structure of claim 1, further comprising a finned dielectric material portion located within a lower region of the contact via opening and including a vertical stack of annular dielectric fin portions at levels of the subset of the insulating layers.

12. The device structure of claim 11, further comprising a vertical stack of silicon oxide liners located at levels of the subset of the electrically conductive layers and laterally surrounding the finned dielectric material portion, wherein the subset of the electrically conductive layers is laterally spaced from the finned dielectric material portion by the vertical stack of silicon oxide liners.

13. The device structure of claim 11, further comprising a vertical stack of tubular silicon portions located at the levels of the subset of the insulating layers and interposed between the finned dielectric material portion and the subset of the insulating layers.

14. The device structure of claim 11, wherein:
the finned dielectric material portion comprises a contoured top surface;
a center point of the contoured top surface is a lowest point of the contoured top surface; and
a vertical distance between any arbitrarily selected point on the contoured top surface and a horizontal plane including a bottommost surface of the alternating stack increases with a radial distance from the center point to the arbitrarily selected point.

15. A method of forming a device structure, comprising:
forming an alternating stack of insulating layers and sacrificial material layers over a substrate;
forming stepped surfaces by patterning the alternating stack in a staircase region;
forming a retro-stepped dielectric material portion over the stepped surfaces;
forming memory stack structures through the alternating stack, wherein each of the memory stack structures comprises a respective vertical semiconductor channel and a vertical stack of memory elements;
forming a contact via opening through the retro-stepped dielectric material portion, a subset of the sacrificial material layers within the alternating stack, and a subset of the insulating layers within the alternating stack, wherein a topmost layer within the subset of the sacrificial material layers comprises a first sacrificial material layer;
laterally recessing a sidewall of the retro-stepped dielectric material portion around the contact via opening by performing an etch back process;
forming a sacrificial tubular structure in a peripheral region of the contact via opening on the laterally recessed sidewall of the retro-stepped dielectric material portion;
replacing the sacrificial material layers and the sacrificial tubular structure with at least electrically conductive layers, wherein a combination of the first sacrificial material layer and the sacrificial tubular structure is replaced with at least a first electrically conductive layer; and
forming a layer contact via structure on an inner-sidewall of a vertically-extending tubular portion of the first electrically conductive layer.

16. The method of claim 15, wherein:
the etch back process also laterally recesses sidewalls of the subset of the insulating layers to form lateral annular cavities; and
the method further comprises forming a finned dielectric material portion in a lower region of the contact via opening, wherein the finned dielectric material portion comprises a vertical stack of annular dielectric fin portions that fill the lateral annular cavities.

17. The method of claim 16, further comprising:
depositing a conformal silicon liner in a peripheral region of the contact via opening; and
depositing a dielectric fill material layer over the conformal silicon liner, wherein a lower portion of the dielectric fill material layer fills the lower region of the contact via opening, and an upper portion of the dielectric fill material layer is formed in a peripheral portion of an upper region of the contact via opening with a void in a center portion of the upper region of the contact via opening.

18. The method of claim 17, further comprising recessing the dielectric fill material layer, wherein:
a remaining portion of the dielectric fill material layer that remains in the lower region of the contact via opening comprises the finned dielectric material portion; and
a vertically-extending portion of the conformal silicon liner is physically exposed in the upper region of the contact via opening.

19. The method of claim 17, further comprising:
etching materials of the sacrificial material layers and the sacrificial tubular structure selectively to materials of the insulating layers and the conformal silicon liner during a same etching step to form voids in volumes from which the sacrificial material layers and the sacrificial tubular structure are removed;
converting segments of the conformal silicon liner into silicon oxide liners; and
depositing a combination of an outer blocking dielectric layer and a respective one of the electrically conductive layers in each of the voids.

20. The method of claim 15, wherein the sacrificial tubular structure is formed by conformally depositing a sacrificial fill material in a peripheral region of the contact via opening and by anisotropically etching horizontally-extending portions of the sacrificial fill material, wherein a remaining vertically-extending portion of the sacrificial fill material comprises the sacrificial tubular structure.
